(19) United States
(12) Patent Application Publication
(10) Pub. No.: US 2022/0115602 A1
(43) Pub. Date: Apr. 14, 2022

(54) LONG-TERM STABLE OPTOELECTRONIC DEVICE

(71) Applicant: OXFORD UNIVERSITY INNOVATION LIMITED, Oxford (GB)

(72) Inventors: Henry James Snaith, Oxford (GB); Sai Bai, Oxford (GB); Feng Gao, Oxford (GB)

(21) Appl. No.: 17/298,279

(22) PCT Filed: Nov. 27, 2019
(86) PCT No.: PCT/GB2019/053349

§ 371 Date: May 28, 2021

(30) Foreign Application Priority Data
Nov. 28, 2018 (GB) 1819380.5

(51) Int. Cl. H01L 51/00; C07F 7/24; H01G 9/20; H01L 51/42

(52) U.S. Cl. CPC H01L 51/0077; C07F 7/24; H01L 51/424; H01L 51/0035; H01G 9/2009; H01L 51/0047

(57) ABSTRACT

The invention relates to an optoelectronic device comprising: (a) a layer comprising a crystalline A/M/X material, wherein the crystalline A/M/X material comprises a compound of formula: [A]a [M]b [X]c wherein: [A] comprises one or more A cations; [M] comprises one or more M cations which are metal or metalloid cations; [X] comprises one or more X anions; a is a number from 1 to 6; b is a number from 1 to 6; and c is a number from 1 to 18; and (b) an ionic liquid which is a salt comprising an organic cation and a counter anion, wherein the organic cation is present within the layer comprising the crystalline A/M/X material. The invention also relates to processes for producing an ionic liquid-modified film of a crystalline A/M/X material and a process for producing an optoelectronic device comprising an ionic-liquid modified film of a crystalline A/M/X material.

### FIELD OF THE INVENTION

The invention provides an optoelectronic device comprising a layer of an ionic liquid-modified crystalline A/M/X material. Also provided are processes for producing an ionic liquid film of a crystalline A/M/X material and a process for producing an optoelectronic device comprising an ionic-liquid modified film of a crystalline A/M/X material.

### BACKGROUND TO THE INVENTION

When the first report of a perovskite solar cell was made in 2009, the power conversion efficiency stood at 3%. By 2012, perovskite photovoltaic devices achieving 9.2% and 10.9% had been demonstrated. Since then, there has been burgeoning research into the field of perovskite photovoltaics and photovoltaic devise based on other A/M/X materials, with such materials showing the promise to completely transform the energy landscape. Perovskite-based photovoltaic devices have since achieved certified efficiencies of 23%.

Solar cells based on metal halide perovskites are emerging as one of the most promising future photovoltaic (PV) technologies. The certified power conversion efficiency (PCE) has reached to 23.3 percent within only a few years, surpassing multi-crystalline silicon and all other thin film PV technologies. Previous efforts on composition engineering of perovskites, interface engineering of device structures, and encapsulation techniques have significantly advanced the long-term stability of perovskite solar cells over the last few years. However, operational device stability under combined full spectrum sunlight and heat stressing is still a key challenge for practical applications of perovskite solar cells. Among all the factors that affect the device stability, ion migration in the perovskite active layer poses a unique threat.

The ion migration in metal halide perovskites is related to instabilities in the materials and ensuing solar cells, and the presence of mobile defects represent a unique challenge for stabilizing these photovoltaic materials. Previous investigations have demonstrated that the ion migration is thermally activated, and that the activation energy is further decreased under illumination. Furthermore, it is expected that the mobile ionic species are defects such as vacancies or interstitials, and that these defects, which will be primarily located at the surfaces and grain boundaries, are expected to be the source for the onset of degradation to environmental factors. Hence light and heat, especially in the presence of any air, pose a significant threat to the long-term stability of perovskites. Another identified area of instability in perovskite solar cells is the organic p-type hole-conductor, which is usually employed in the most efficient perovskite solar cells. It is therefore very difficult to obtain a perovskite which combines both excellent PCE with good long-term stability for practical applications.

Zhang et al., A Strategy to Produce High-Efficiency, High Stability Perovskite Solar Cells Using Functionalized Ionic Liquid-Dopants, Adv. Mater. 2017, 1702157 describes a fumigation method for producing ionic liquid-doped perovskites. The maximum power output value obtained after 460 hours of light soaking for the devices made using the perovskites were 55% of the initial value, giving a T80 (estimate a lifetime to 80% of the peak cell performance) of less than 400 hours at room temperature. Greater device stability is required for a viable solar cell which must maintain high efficiency for as long as possible.

Yang et al. “Surface optimization to eliminate hysteresis for record efficiency planar perovskite solar cells” Energy & Environmental Science, 2016, 9, 3071 relates to modification of the titanium dioxide electron transport layer by spin coating an ionic liquid solution on top of that layer. PCE is improved with the modified titanium dioxide compared to the unmodified titanium dioxide. However, the solar cells shown in Yang et al. exhibit a 15% degradation PCE after only 240 minutes of illumination at room temperature. For real-world applications, much longer useable lifetimes for solar cell devices are required.

Chen et al., Global Control of CH₃NH₃PBI₃ Formation with Multifunctional Ionic liquid for Perovskite Hybrid Photovoltaics, J. Phys. Chem. 2018 relates to the synthesis of perovskite materials for solar cells with PCEs of up to 15.6%. Chen et al does not discuss how to produce solar cells with simultaneously high PCE and high stability.

There therefore exists a need for perovskite materials which can be incorporated into optoelectronic devices such as photovoltaics, that simultaneously exhibit high PCE as well as long device life time in harsh aging conditions, for example full spectrum sunlight with heat stressing. There also exists a need for a simple method for preparing such a perovskite material which can be used on a large-scale.

### SUMMARY OF THE INVENTION

The present invention provides optoelectronic devices comprising crystalline A/M/X materials that simultaneously exhibit improved performance (e.g. improved efficiency) and excellent long-term stability. This is achieved by incorporating ionic liquids into the perovskite light-harvesting layer, resulting in improved efficiency and stability.

Ion migration is related to instabilities in the A/M/X materials. Ion migration leads to defects which are thought to be the source for the onset of degradation due to environmental factors. Ion migration is heat and light activated, therefore it is important to develop materials that are stable and suppress ion migration in response to combined light and heat stress. The inventors have unexpectedly discovered that ionic liquids inhibit ion migration and reduce the defect density within the A/M/X material, thereby providing materials that do not degrade when used in non-ideal, simulated real-world conditions e.g. full spectrum sunlight at elevated temperature. This represents a key step towards the commercial upscale and deployment of the perovskite photovoltaic technology. For instance, for the encapsulated optoelectronic devices as described herein, negligible degradation is observed under continuous simulated full spectrum sunlight for over 1,800 hours at 70° C., and estimate a lifetime to 80% of the peak cell performance, T₈₀, of over 12,000 hours, significantly larger than that observed for other devices in the literature.

Further, the ionic liquid doped A/M/X materials provide improved energy alignment between the A/M/X material and any adjacent charge transporting layers. This results in improved charge extraction and efficiency for optoelectronic devices employing ionic liquid doped A/M/X materials. For instance, the efficiency of “positive-intrinsic-negative” (p-i-n) planar heterojunction solar cells employing p-type hole conductor such as NiO, and an A/M/X material as described herein can be stabilised at over 20 percent.

Further, the optoelectronic devices according to the present application may be fabricated using solution-based methods. This means that no complex techniques such as sputter-coating, lamination or vacuum deposition are required, making the optoelectronic devices simple to produce.

The advantages described above represent a significant advance towards realizing a commercially viable low-cost, solution-processed PV technology.

Accordingly, the present invention provides an optoelectronic device comprising: (a) a layer comprising (a) a crystalline A/M/X material, wherein the crystalline A/M/X material comprises a compound of formula: [A]ₐ[M]_{b}[X]_{c}, wherein: [A] comprises one or more A cations; [M] comprises one or more M cations which are metal or metalloid cations; [X] comprises one or more X anions; a is a number from 1 to 6; b is a number from 1 to 6; and c is a number from 1 to 18; and (b) an ionic liquid which is a salt comprising an organic cation and a counter anion, wherein the organic cation is present within the layer comprising the crystalline A/M/X material.

The invention also provides a process for producing an ionic liquid-modified film of a crystalline A/M/X material, wherein the crystalline A/M/X material comprises a compound of formula: [A]ₐ[M]_{b}[X]_{c}, wherein: [A] comprises one or more A cations; [M] comprises one or more M cations which are metal or metalloid cations; [X] comprises one or more X anions; wherein a is a number from 1 to 6; b is a number from 1 to 6; and c is a number from 1 to 18, the process comprising: disposing a film-forming solution on a substrate, wherein the film-forming solution comprises a solvent, the one or more A cations, the one or more M cations, the one or more X anions, and an ionic liquid, wherein the ionic liquid comprises an organic cation and a counter-anion.

The invention also provides a process for producing an ionic liquid-modified film of a crystalline A/M/X material, which crystalline A/M/X material comprises a compound of formula: [A]ₐ[M]_{b}[X]_{c}, wherein: [A] comprises one or more A cations; [M] comprises one or more M cations which are metal or metalloid cations; [X] comprises one or more X anions; wherein a is a number from 1 to 6; b is a number from 1 to 6; and c is a number from 1 to 18, the process comprising:
a) disposing a first solution on a substrate wherein the first solution comprises a solvent and one or more M cations, and optionally removing the solvent, to produce a treated substrate;
b) contacting the treated substrate with a second solution comprising a solvent and one or more A cations or with vapour comprising one or more A cations,
wherein: one or more X anions are present in one or both of: (i) the first solution employed in step (a), and (ii) the second solution or vapour employed in step (b); and the first solution employed in step (a) further comprises an ionic liquid or step (b) further comprises contacting the treated substrate with an ionic liquid, wherein the ionic liquid comprises an organic cation and a counter-anion.

The invention also provides a process for producing an ionic liquid-modified film of a crystalline A/M/X material, wherein the crystalline A/M/X material comprises a compound of formula: [A]ₐ[M]_{b}[X]_{c}, wherein: [A] comprises one or more A cations; [M] comprises one or more M cations which are metal or metalloid cations; [X] comprises one or more X anions; a is a number from 1 to 6; b is a number from 1 to 6; and c is a number from 1 to 18; which process comprises treating a film of the crystalline A/M/X material with an ionic liquid which is a salt comprising an organic cation and a counter anion.

The invention also provides a process for producing an optoelectronic device, which process comprises producing, on a substrate, an ionic liquid-modified film of a crystalline A/M/X material, by a process as described herein.

The invention also provides an ionic liquid-modified film of a crystalline A/M/X material which is obtainable by a process as described herein.

The invention also provides an optoelectronic device which
(a) comprises an ionic liquid-modified film of a crystalline A/M/X material obtainable by a process as described herein; or
(b) is obtainable by a process as described herein.

### BRIEF DESCRIPTION OF THE FIGURES

FIGS. 1a-f show device architecture and performance results. FIG. 1a shows a schematic device architecture of the planar heterojunction p-i-n perovskite solar cell. FIG. 1b shows the chemical structure of the 1-butyl-3-methylimidazolium tetrafluoroborate (BMIMBF₄) ionic liquid. FIG. 1c shows the J-V characteristics of perovskite solar cells, with a perovskite absorber layer of (FA_{0.83}MA_{0.17})_{0.95}Cs_{0.05}Pb(I_{0.9}Br_{0.1})₃ composition, without IL (W/O IL, navy, open circles) and with 0.3 mol % BMIMBF₄ (with IL, red, solid circles), measured from forward bias (FB) to short-circuit (SC) scan, under simulated AM1.5 sunlight with the intensity of 100 mW cm⁻² (solid) and in the dark (dashed). FIG. 1d shows the external quantum efficiency (EQE) spectra of the perovskite solar cells, either without (navy) or with the IL (red), and the integrated photocurrent over the AM1.5 solar spectrum of 100 mW cm⁻². The short-circuit current (J_{SC}) values integrated from EQE spectra are 22.2 mA cm⁻² and 22.8 mA cm⁻² for the device without and with the IL, respectively. FIG. 1e shows the stabilised power output (SPO) of the solar cells based on perovskite film without (navy, open circles) and with the IL (red, solid circles), determined at a fixed voltage near the maximum power point (MPP) from the J-V curves for 100 s. FIG. 1f shows the histograms of the device efficiencies of 30 devices without (navy) and with the IL (red).

FIGS. 2a-c show the IL distribution and its impact on the ion migration in (FA_{0.83}MA_{0.17})_{0.95}Cs_{0.05}Pb(I_{0.9}Br_{0.1})₃ perovskite films. FIG. 2a shows the N 1s XPS spectra of perovskite films without and with the IL. The inset shows the F is spectra of the two samples. FIG. 1b shows the ToF-SIMS depth profiles of perovskite film processed from precursor with 0.3 mol % BMIMBF₄ on NiO coated FTO substrates. The depth profile was conducted using a Cs⁺ sputter gun in the positive mode. The CsSnO⁺ peaks which show the best signal to noise ratio is plotted to represent the elemental information from the FTO substrate. FIG. 1c shows the time dependent photoluminescence images of perovskite film without (top) and with IL (bottom) under a constant applied bias (10 V). The perovskite films are excited by a 440 nm light with the excitation power of ˜34 mW cm⁻² and the exposure time is 200 ms. The dark areas represent the Au electrodes, of which the channel is ˜150 μm, and the bright areas are the perovskite films.

FIGS. 3a-e shows the film stability and the interaction between PbI₂ and BMIM-ILs with different anions. FIG. 3a shows the XRD patterns of the pristine (dash) and aged (solid) (FA_{0.83}MA_{0.17})_{0.95}Cs_{0.05}Pb(I_{0.9}Br_{0.1})₃ perovskite films on NiO/FTO substrates without (navy) and with IL (red). The samples are aged for 72 h under constant xenon-lamp simulated full spectrum sunlight at ˜60° C. The inset shows pictures of the aged perovskite films. FIG. 3b shows the device efficiency of perovskite solar cells with different ILs at a same ratio (0.3 mol %). FIG. 3c shows the evolution of the ratio between PbI₂ and perovskite (100) peak intensity in the XRD patterns of perovskite films without and with different ILs during the light aging at 70° C. FIG. 3d shows the XRD patterns of thin films deposited from solution (0.8 M in DMF) of PbI₂ and the equimolar mixtures PbI₂ and BMIM-ILs with different anions. FIG. 3e shows the UV-Vis absorption spectra of the obtained PbI₂ film, and the films from equimolar mixtures of PbI2 and BMIM-ILs with different anions. FIG. 3f shows the ToF-SIMS profile of the perovskite film with BMIMCl (0.3 mol %) on NiO/FTO substrate.

FIGS. 4a-b show the (FA_{0.83}MA_{0.17})_{0.95}Cs_{0.05}Pb(I_{0.9}Br_{0.1})₃ perovskite device operational stability under full spectrum sunlight and heat. FIG. 4a shows the device stability performance of non-encapsulated devices with (red) and without IL (navy) under full spectrum sunlight at ˜60° C. The inset shows the pictures of perovskite solar cells after aging for 120 h. FIG. 4b shows the device stability performance of encapsulated perovskite solar cells with (red) and without the IL (navy) under combined full spectrum sunlight with the aging chamber temperature at 70° C. The PCE values are derived from the forward bias to short-circuit (FB-SC) J-V scan curves, with a scan rate of 200 mV s⁻¹.

FIGS. 5a-f show various results for solar cells fabricated from (FA_{0.83}MA_{0.17})_{0.95}Cs_{0.05}Pb(I_{0.9}Br_{0.1})₃ perovskite precursor with IL at different concentrations. FIGS. 5a-e show device parameters of solar cells fabricated from perovskite precursors with the concentration of BMIMBF₄ in the solution ranging from 0 to 1.2 mol % (with respect to Pb atom). Power conversion efficiency (PCE) (FIG. 5a), stabilized power output (SPO), (FIG. 5b), short-circuit current (J_{SC}) (FIG. 5c), open-circuit voltage (V_{OC}) (FIG. 5d), and fill factor (FF) (FIG. 5e). All device parameters are determined from the forward bias (FB) to short-circuit (SC) J-V scan curves. FIG. 5f shows J-V curves of the solar cell based on perovskite film with the optimal IL concentration of 0.3 mol %, measured from FB to SC and back again with a scan rate of 200 mV s⁻¹.

FIGS. 6a-d show characterization results of the (FA_{0.83}MA_{0.17})_{0.95}Cs_{0.05}Pb(I_{0.9}Br_{0.1})₃ perovskite films without and with the IL. FIG. 6a shows XRD patterns of the perovskite films. FIG. 6b shows a top-view SEM images of the perovskite films. FIG. 6c shows a UV-Vis absorption and steady-state photoluminescence (PL) spectra of the perovskite films. FIG. 6d shows time-resolved PL decay of the perovskite films. The perovskite films are fabricated from precursor without (navy) and with the BMIMBF₄ IL (0.3 mol %).

FIGS. 7a-c show surface work-function and energy level structure of the (FA_{0.83}MA_{0.17})_{0.95}Cs_{0.05}Pb(I_{0.9}Br_{0.1})₃ perovskite films. FIG. 7a shows the photoemission cut off energy and valence band region of the UPS spectra of perovskite films fabricated from precursor with (red) and without the IL (navy) on NiO coated FTO substrates. WF: work function, VBM: valance band maximum, Ef: Fermi level. FIG. 7b shows the energy level diagram of NiO, perovskite films without and with the IL, and PCBM in the solar cells. FIG. 7c shows the surface work-function measurements from Kelvin Probe of the perovskite films on FTO/NiO with different BMIMBF₄ concentrations.

FIG. 8a-b show the (FA_{0.83}MA_{0.17})_{0.95}Cs_{0.05}Pb(I_{0.9}Br_{0.1})₃ perovskite solar cells based on poly-TPD hole-conductor. FIG. 8a shows the device efficiency of perovskite solar cells fabricated from precursor without and with the BMIMBF₄ ionic liquid (0.3 mol %) on poly-TPD coated FTO substrates. FIG. 8b shows the J-V curves of the device fabricated from perovskite precursor with 0.3 mol % BMIMBF₄ IL on poly-TPD/FTO, measured from FB to SC and back again with a scan rate of 200 mV s−1.

FIGS. 9a-b are photographs of the degraded (FA_{0.83}MA_{0.17})_{0.95}Cs_{0.05}Pb(I_{0.9}Br_{0.1})₃ perovskite devices with NiO p-type layers, and the films deposited from mixtures of PbI₂ and different ILs. FIG. 9a shows the non-encapsulated devices without IL and with different ILs after aging for 100 h under combined full-spectrum sunlight at 70° C. FIG. 9b shows images of films deposited from solution (0.8 M in DMF) of PbI₂ and the equimolar mixtures of PbI₂:BMIM-ILs with different anions. All films were spin-coated upon FTO coated glass substrates at 2000 r.p.m for 30 s in glovebox and annealed at 100° C. for 1 h.

FIGS. 10a-b show the initial (FA_{0.83}MA_{0.17})_{0.95}Cs_{0.05}Pb(I_{0.9}Br_{0.1})₃ perovskite device efficiency and film stability on BMIMBF₄ IL modified NiO (no IL added to the perovskite solution). FIG. 10a shows the device efficiency of perovskite solar cells fabricated on bare NiO and BMIMBF₄ modified NiO. FIG. 10b shows XRD patterns of the fresh and aged perovskite films (under full spectrum sunlight at 60° C. in ambient air) without IL on bare NiO and that on BMIMBF₄ modified NiO substrates.

FIG. 11 shows the long-term operational stability of (FA_{0.83}MA_{0.17})_{0.95}Cs_{0.05}Pb(I_{0.9}Br_{0.1})₃ perovskite solar cells under different temperature. The encapsulated perovskite solar cells with (red) and without BMIMBF₄ IL (navy) are aged under full spectrum sunlight with the light-soaking chamber temperature at ˜60 and ˜70° C.

FIG. 12 shows device parameters of the (FA_{0.83}MA_{0.17})_{0.95}Cs_{0.05}Pb(I_{0.9}Br_{0.1})₃ perovskite solar cells under long-term stability test. Evolution of the short-circuit current (J_{SC}), fill factor (FF), open-circuit voltage (V_{OC}) and steady-state power output (SPO) of the perovskite solar cells without (navy) and with the BMIMBF₄ IL (0.3 mol %) (red) in FIG. 4b. The device parameters are determined from the J-V curves scan from FB to SC with a scan rate of 200 mV s−1.

FIG. 13 shows the long-term device operational stability of a large set of (FA_{0.83}MA_{0.17})_{0.95}Cs_{0.05}Pb(I_{0.9}Br_{0.1})₃ perovskite solar cells. The average efficiency (sphere) and the standard deviation (error bar) is calculated from 10 devices on 4 different substrates of each parameter, without any IL (navy), with BMIMBF₄ IL at the perovskite/NiO interface (light blue), and with the BMIMBF₄ IL in the perovskite film (red), under combined full spectrum sunlight and heat stressing with the chamber temperature at ˜70° C.

FIG. 14 shows the device performance of MAPbI₃ perovskite solar cells without and with the BMIMBF₄. a, J-V curves of the solar cells based on MAPbI₃ perovskite without and with the BMIMBF₄ (0.3 mol %). The inset table shows the device parameters of the devices. b, Stabilized power output (SPO) efficiencies of the devices without and with the IL. c, Long term device stability performance of the MAPbI₃ solar cells without and with the BMIMBF₄ IL (0.3 mol %) under full spectrum sunlight at 60° C. During the region (100-115 h) marked as blue, the chamber was set at 70° C. to check the device degradation behaviour under elevated temperature.

FIGS. 15a-b show determination methods of the T80 lifetime. FIG. 15a shows that for the devices with early “burn-in” effect, the stability performance data after the “burn-in” section is fitted to a straight line, and the curve is extrapolated back to zero time to obtain the T=0 efficiency. The lifetime to 80% of the T=0 efficiency is determined as the T80 lifetime (Wang, Z. et al. Efficient and air-stable mixed-cation lead mixed-halide perovskite solar cells with n-doped organic electron extraction layers. Adv. Mater. 29, 1604186, (2017)). FIG. 15b shows that for the devices with positive “light-soaking” effect, the stability data from the peak performance after the “light-soaking” section is fitted to a straight line. The lifetime to 80% of the peak efficiency is calculated and the “light-soaking” time is added to obtain the total T80 lifetime.

FIG. 16 shows device parameters of (FA_{0.83}MA_{0.17})_{0.95}Cs_{0.05}Pb(I_{0.9}Br_{0.1})₃ perovskite solar cells fabricated on NiO and polyTPD p-type layers with or without the 1-butyl-1-methylpiperidinium tetrafluoroborate ionic liquid (referred to by its Sigma Aldrich number code 713082) added to the perovskite layer. (a) short-circuit current (J_{SC}), (b) fill factor (FF), (c) open-circuit voltage (V_{OC}) and (d) power conversion efficiency. The device parameters are determined from the J-V curves scan from FB to SC with a scan rate of 200 mV s−1.

FIG. 17 shows the power conversion efficiency of (FA_{0.83}MA_{0.17})_{0.95}Cs_{0.05}Pb(I_{0.9}Br_{0.1})₃ perovskite solar cells encapsulated with a glass cover slip and thermally stressed at 85° C. in a nitrogen atmosphere, measured over time and fabricated on polyTPD p-type layers with or without the 1-butyl-1-methylpiperidinium tetrafluoroborate ionic liquid (Referred to by its Sigma Aldrich number code 713082) added to the perovskite layer.

### DETAILED DESCRIPTION OF THE INVENTION

### Definitions

The term “crystalline” as used herein indicates a crystalline compound, which is a compound having an extended 3D crystal structure. A crystalline compound is typically in the form of crystals or, in the case of a polycrystalline compound, crystallites (i.e. a plurality of crystals having particle sizes of less than or equal to 1 μm). The crystals together often form a layer. The crystals of a crystalline material may be of any size. Where the crystals have one or more dimensions in the range of from 1 nm up to 1000 nm, they may be described as nano crystals.

The terms “organic compound” and “organic solvent” as used herein have their typical meaning in the art and would readily be understood by the skilled person.

The term “crystalline A/M/X material”, as used herein, refers to a material with a crystal structure which comprises one or more A ions, one or more M ions, and one or more X ions. A ions and M ions are cations. X ions are anions. A/M/X materials typically do not comprise any further types of ions.

The term “perovskite”, as used herein, refers to a material with a three-dimensional crystal structure related to that of CaTiO₃ or a material comprising a layer of material, which layer has a structure related to that of CaTiO₃. The structure of CaTiO₃ can be represented by the formula ABX₃, wherein A and B are cations of different sizes and X is an anion. In the unit cell, the A cations are at (0,0,0), the B cations are at (1/2, 1/2, 1/2) and the X anions are at (1/2, 1/2, 0). The A cation is usually larger than the B cation. The skilled person will appreciate that when A, B and X are varied, the different ion sizes may cause the structure of the perovskite material to distort away from the structure adopted by CaTiO₃ to a lower-symmetry distorted structure. The symmetry will also be lower if the material comprises a layer that has a structure related to that of CaTiO₃. Materials comprising a layer of perovskite material are well known. For instance, the structure of materials adopting the K₂NiF₄-type structure comprises a layer of perovskite material. The skilled person will appreciate that a perovskite material can be represented by the formula [A][B][X]₃, wherein [A] is at least one cation, [B] is at least one cation and [X] is at least one anion. When the perovskite comprises more than one A cation, the different A cations may distribute over the A sites in an ordered or disordered way. When the perovskite comprises more than one B cation, the different B cations may distribute over the B sites in an ordered or disordered way. When the perovskite comprises more than one X anion, the different X anions may distribute over the X sites in an ordered or disordered way. The symmetry of a perovskite comprising more than one A cation, more than one B cation or more than one X cation, will be lower than that of CaTiO₃. For layered perovskites the stoichiometry can change between the A, B and X ions. As an example, the [A]₂[B][X]₄ structure can be adopted if the A cation has too large an ionic radius to fit within the 3D perovskite structure. The term “perovskite” also includes A/M/X materials adopting a Ruddleson-Popper phase. Ruddleson-Popper phase refers to a perovskite with a mixture of layered and 3D components. Such perovskites can adopt the crystal structure, Aₙ₋₁A′₂MₙX₃ₙ₊₁, where A and A′ are different cations and n is an integer from 1 to 8, or from 2 to 6. The term “mixed 2D and 3D” perovskite is used to refer to a perovskite film within which there exists both regions, or domains, of AMX₃ and Aₙ₋₁A′₂MₙX₃ₙ₊₁ perovskite phases.

The term “metal halide perovskite”, as used herein, refers to a perovskite, the formula of which contains at least one metal cation and at least one halide anion.

The term “mixed halide perovskite” as used herein refers to a perovskite or mixed perovskite which contains at least two types of halide anion.

The term “mixed cation perovskite” as used herein refers to a perovskite of mixed perovskite which contains at least two types of A cation.

The term “organic-inorganic metal halide perovskite”, as used herein, refers to a metal halide perovskite, the formula of which contains at least one organic cation.

The term “monocation”, as used herein, refers to any cation with a single positive charge, i.e. a cation of formula A⁺ where A is any moiety, for instance a metal atom or an organic moiety. The term “dication”, as used herein, refers to any cation with a double positive charge, i.e. a cation of formula A²⁺ where A is any moiety, for instance a metal atom or an organic moiety. The term “trication”, as used herein, refers to any cation with a triple positive charge, i.e. a cation of formula A³⁺ where A is any moiety, for instance a metal atom or an organic moiety. The term “tetracation”, as used herein, refers to any cation with a quadruple positive charge, i.e. a cation of formula A⁴⁺ where A is any moiety, for instance a metal atom.

The term “alkyl”, as used herein, refers to a linear or branched chain saturated hydrocarbon radical. An alkyl group may be a C₁₋₂₀ alkyl group, a C₁₋₁₄ alkyl group, a C₁₋₁₀ alkyl group, a C₁₋₆ alkyl group or a C₁₋₄ alkyl group. Examples of a C₁₋₁₀ alkyl group are methyl, ethyl, propyl, butyl, pentyl, hexyl, heptyl, octyl, nonyl or decyl. Examples of C₁₋₆ alkyl groups are methyl, ethyl, propyl, butyl, pentyl or hexyl. Examples of C₁₋₄ alkyl groups are methyl, ethyl, i-propyl, n-propyl, t-butyl, s-butyl or n-butyl. If the term “alkyl” is used without a prefix specifying the number of carbons anywhere herein, it has from 1 to 6 carbons (and this also applies to any other organic group referred to herein).

The term “cycloalkyl”, as used herein, refers to a saturated or partially unsaturated cyclic hydrocarbon radical. A cycloalkyl group may be a C₃₋₁₀ cycloalkyl group, a C₃₋₈ cycloalkyl group or a C₃₋₆ cycloalkyl group. Examples of a C₃₋₈ cycloalkyl group include cyclopropyl, cyclobutyl, cyclopentyl, cyclohexyl, cyclohexenyl, cyclohex-1,3-dienyl, cycloheptyl and cyclooctyl. Examples of a C₃₋₆ cycloalkyl group include cyclopropyl, cyclobutyl, cyclopentyl, and cyclohexyl.

The term “alkenyl”, as used herein, refers to a linear or branched chain hydrocarbon radical comprising one or more double bonds. An alkenyl group may be a C₂₋₂₀ alkenyl group, a C₂₋₁₄ alkenyl group, a C₂₋₁₀ alkenyl group, a C₂₋₆ alkenyl group or a C₂₋₄ alkenyl group. Examples of a C₂₋₁₀ alkenyl group are ethenyl (vinyl), propenyl, butenyl, pentenyl, hexenyl, heptenyl, octenyl, nonenyl or decenyl. Examples of C₂₋₆ alkenyl groups are ethenyl, propenyl, butenyl, pentenyl or hexenyl. Examples of C₂₋₄ alkenyl groups are ethenyl, i-propenyl, n-propenyl, s-butenyl or n-butenyl. Alkenyl groups typically comprise one or two double bonds.

The term “alkynyl”, as used herein, refers to a linear or branched chain hydrocarbon radical comprising one or more triple bonds. An alkynyl group may be a C₂₋₂₀ alkynyl group, a C₂₋₁₄ alkynyl group, a C₂₋₁₀ alkynyl group, a C₂₋₆ alkynyl group or a C₂₋₄ alkynyl group. Examples of a C₂₋₁₀ alkynyl group are ethynyl, propynyl, butynyl, pentynyl, hexynyl, heptynyl, octynyl, nonynyl or decynyl. Examples of C₁₋₆ alkynyl groups are ethynyl, propynyl, butynyl, pentynyl or hexynyl. Alkynyl groups typically comprise one or two triple bonds.

The term “aryl”, as used herein, refers to a monocyclic, bicyclic or polycyclic aromatic ring which contains from 6 to 14 carbon atoms, typically from 6 to 10 carbon atoms, in the ring portion. Examples include phenyl, naphthyl, indenyl, indanyl, anthrecenyl and pyrenyl groups. The term “aryl group”, as used herein, includes heteroaryl groups.

The term “heteroaryl”, as used herein, refers to monocyclic or bicyclic heteroaromatic rings which typically contains from six to ten atoms in the ring portion including one or more heteroatoms. A heteroaryl group is generally a 5- or 6-membered ring, containing at least one heteroatom selected from O, S, N, P, Se and Si. It may contain, for example, one, two or three heteroatoms. Examples of heteroaryl groups include pyridyl, pyrazinyl, pyrimidinyl, pyridazinyl, furanyl, thienyl, pyrazolidinyl, pyrrolyl, oxazolyl, oxadiazolyl, isoxazolyl, thiadiazolyl, thiazolyl, isothiazolyl, imidazolyl, pyrazolyl, quinolyl and isoquinolyl.

The term “substituted”, as used herein in the context of substituted organic groups, refers to an organic group which bears one or more substituents selected from C₁₋₁₀ alkyl, aryl (as defined herein), cyano, amino, nitro, C₁₋₁₀ alkylamino, di(C₁₋₁₀)alkylamino, arylamino, diarylamino, aryl(C₁₋₁₀)alkylamino, amido, acylamido, hydroxy, oxo, halo, carboxy, ester, acyl, acyloxy, C₁₋₁₀ alkoxy, aryloxy, halo(C₁₋₁₀)alkyl, sulfonic acid, thiol, C₁₋₁₀ alkylthio, arylthio, sulfonyl, phosphoric acid, phosphate ester, phosphonic acid and phosphonate ester. Examples of substituted alkyl groups include haloalkyl, perhaloalkyl, hydroxyalkyl, aminoalkyl, alkoxyalkyl and alkaryl groups. When a group is substituted, it may bear 1, 2 or 3 substituents. For instance, a substituted group may have 1 or 2 substitutents.

The term “halide” as used herein indicates the singly charged anion of an element in group VIII of the periodic table. “Halide” includes fluoride, chloride, bromide and iodide.

The term “halo” as used herein indicates a halogen atom. Exemplary halo species include fluoro, chloro, bromo and iodo species.

As used herein, an amino group is a radical of formula —NR₂, wherein each R is a substituent. R is usually selected from hydrogen, alkyl, alkenyl, cycloalkyl, or aryl, wherein each of alkyl, alkenyl, cycloalkyl and aryl are as defined herein. Typically, each R is selected from hydrogen, C₁₋₁₀ alkyl, C₂₋₁₀ alkenyl, and C₃₋₁₀ cycloalkyl. Preferably, each R is selected from hydrogen, C₁₋₆ alkyl, C₂₋₆ alkenyl, and C₃₋₆ cycloalkyl. More preferably, each R is selected from hydrogen and C₁₋₆ alkyl.

A typical amino group is an alkylamino group, which is a radical of formula —NR₂ wherein at least one R is an alkyl group as defined herein. A C₁₋₆ alkylamino group is an alkylamino group wherein at least one R is an C₁₋₆ alkyl group.

As used herein, an imino group is a radical of formula R₂C═N— or —C(R)═NR, wherein each R is a substituent. That is, an imino group is a radical comprising a C═N moiety, having the radical moiety either at the N atom or attached to the C atom of said C═N bond. R is as defined herein: that is, R is usually selected from hydrogen, alkyl, alkenyl, cycloalkyl, or aryl, wherein each of alkyl, alkenyl, cycloalkyl and aryl are as defined herein. Typically, each R is selected from hydrogen, C₁₋₁₀ alkyl, C₂₋₁₀ alkenyl, and C₃₋₁₀ cycloalkyl. Preferably, each R is selected from hydrogen, C₁₋₆ alkyl, C₂₋₆ alkenyl, and C₃₋₆ cycloalkyl. More preferably, each R is selected from hydrogen and C₁₋₆ alkyl.

A typical imino group is an alkylimino group, which is a radical of formula R₂C═N— or —C(R)═NR wherein at least one R is an alkyl group as defined herein. A C₁₋₆ alkylimino group is an alkylimino group wherein the R substituents comprise from 1 to 6 carbon atoms. The term “ester” as used herein indicates an organic compound of the formula alkyl-C(═O)—O-alkyl, wherein the alkyl radicals are the same or different and are as defined herein. The alkyl radicals may be optionally substituted.

The term “ether” as used herein indicates an oxygen atom substituted with two alkyl radicals as defined herein. The alkyl radicals may be optionally substituted, and may be the same or different.

As used herein, the term “ammonium” indicates an organic cation comprising a quaternary nitrogen. An ammonium cation is a cation of formula R¹R²R³R⁴N⁺. R¹, R², R³, and R⁴ are substituents. Each of R¹, R², R³, and R⁴ are typically independently selected from hydrogen, or from optionally substituted alkyl, alkenyl, aryl, cycloalkyl, cycloalkenyl and amino; the optional substituent is preferably an amino or imino substituent. Usually, each of R¹, R², R³, and R⁴ are independently selected from hydrogen, and optionally substituted C₁₋₁₀ alkyl, C₂₋₁₀ alkenyl, C₃₋₁₀ cycloalkyl, C₃₋₁₀ cycloalkenyl, C₆₋₁₂ aryl and C₁₋₆ amino; where present, the optional substituent is preferably an amino group; particularly preferably C₁₋₆ amino. Preferably, each of R¹, R², R³, and R⁴ are independently selected from hydrogen, and unsubstituted C₁₋₁₀ alkyl, C₂₋₁₀ alkenyl, C₃₋₁₀ cycloalkyl, C₃₋₁₀ cycloalkenyl, C₆₋₁₂ aryl and C₁₋₆ amino. In a particularly preferred embodiment, R¹, R², R³, and R⁴ are independently selected from hydrogen, C₁₋₁₀ alkyl, and C₂₋₁₀ alkenyl and C₁₋₆ amino. Further preferably, R¹, R², R³, and R⁴ are independently selected from hydrogen, C₁₋₆ alkyl, C₂₋₆ alkenyl and C₁₋₆ amino.

As used herein, the term “iminium” indicates an organic cation of formula (R¹R²C═NR³R⁴)⁺, wherein R¹, R², R³, and R⁴ are as defined in relation to the ammonium cation. Thus, in a particularly preferred embodiment, of the iminium cation, R¹, R², R³, and R⁴ are independently selected from hydrogen, C₁₋₁₀ alkyl, C₂₋₁₀ alkenyl and C₁₋₆ amino. In a further preferable embodiment of the iminium cation, R¹, R², R³, and R⁴ are independently selected from hydrogen, C₁₋₆ alkyl, C₂₋₆ alkenyl and C₁₋₆ amino. Often, the iminium cation is formamidinium, i.e. R¹ is NH₂ and R², R³ and R⁴ are all H.

The term “optoelectronic device”, as used herein, refers to devices which source, control or detect light. Light is understood to include any electromagnetic radiation. Examples of optoelectronic devices include photovoltaic devices, photodiodes (including solar cells), phototransistors, photomultipliers, photoresistors, and light emitting diodes.

The term “consisting essentially of” refers to a composition comprising the components of which it consists essentially as well as other components, provided that the other components do not materially affect the essential characteristics of the composition. Typically, a composition consisting essentially of certain components will comprise greater than or equal to 95 wt % of those components or greater than or equal to 99 wt % of those components.

The terms “disposing on” or “disposed on”, as used herein, refers to the making available or placing of one component on another component. The first component may be made available or placed directly on the second component, or there may be a third component which intervenes between the first and second component. For instance, if a first layer is disposed on a second layer, this includes the case where there is an intervening third layer between the first and second layers. Typically, “disposing on” refers to the direct placement of one component on another.

The term “layer”, as used herein, refers to any structure which is substantially laminar in form (for instance extending substantially in two perpendicular directions, but limited in its extension in the third perpendicular direction). A layer may have a thickness which varies over the extent of the layer. Typically, a layer has approximately constant thickness. The “thickness” of a layer, as used herein, refers to the average thickness of a layer. The thickness of layers may easily be measured, for instance by using microscopy, such as electron microscopy of a cross section of a film, or by surface profilometry for instance using a stylus profilometer.

The term “band gap”, as used herein, refers to the energy difference between the top of the valence band and the bottom of the conduction band in a material. The skilled person of course is readily able to measure the band gap of a semiconductor (including that of a perovskite) by using well-known procedures which do not require undue experimentation. For instance, the band gap of a semiconductor can be estimated by constructing a photovoltaic diode or solar cell from the semiconductor and determining the photovoltaic action spectrum. Alternatively the band gap can be estimated by measuring the light absorption spectra either via transmission spectrophotometry or by photo thermal deflection spectroscopy. The band gap can be determined by making a Tauc plot, as described in Tauc, J., Grigorovici, R. & Vancu, a. Optical Properties and Electronic Structure of Amorphous Germanium. Phys. Status Solidi 15, 627-637 (1966) where the square of the product of absorption coefficient times photon energy is plotted on the Y-axis against photon energy on the x-axis with the straight line intercept of the absorption edge with the x-axis giving the optical band gap of the semiconductor. Alternatively, the optical band gap may be estimated by taking the onset of the incident photon-to-electron conversion efficiency, as described in [Barkhouse DAR, Gunawan O, Gokmen T, Todorov T K, Mitzi D B. Device characteristics of a 10.1% hydrazineprocessed Cu2ZnSn(Se,S)4 solar cell. Progress in Photovoltaics: Research and Applications 2012; published online DOI: 10.1002/pip.1160.]

The term “semiconductor” or “semiconducting material”, as used herein, refers to a material with electrical conductivity intermediate in magnitude between that of a conductor and a dielectric. A semiconductor may be a negative (n)-type semiconductor, a positive (p)-type semiconductor or an intrinsic (i) semiconductor. A semiconductor may have a band gap of from 0.5 to 3.5 eV, for instance from 0.5 to 2.5 eV or from 1.0 to 2.0 eV (when measured at 300 K).

The term “n-type region”, as used herein, refers to a region of one or more electron-transporting (i.e. n-type) materials. Similarly, the terms “n-type layer” refers to a layer of an electron-transporting (i.e. an n-type) material. An electron-transporting (i.e. an n-type) material could be a single electron-transporting compound or elemental material, or a mixture of two or more electron-transporting compounds or elemental materials. An electron-transporting compound or elemental material may be undoped or doped with one or more dopant elements.

The term “p-type region”, as used herein, refers to a region of one or more hole-transporting (i.e. p-type) materials. Similarly, the term “p-type layer” refers to a layer of a hole-transporting (i.e. a p-type) material. A hole-transporting (i.e. a p-type) material could be a single hole-transporting compound or elemental material, or a mixture of two or more hole-transporting compounds or elemental materials. A hole-transporting compound or elemental material may be undoped or doped with one or more dopant elements.

The term “electrode material”, as used herein, refers to any material suitable for use in an electrode. An electrode material will have a high electrical conductivity. The term “electrode” as used herein indicates a region or layer consisting of, or consisting essentially of, an electrode material.

The term “ionic liquid”, as used herein, refers to a salt which is in the liquid state at a temperature of less than or equal to 100° C. Preferably it is in the liquid state at room temperature. Usually, it refers to a salt which is in the liquid state at room temperature.

As the skilled person will appreciate, when an ionic liquid is incorporated or impregnated into a solid material (for instance a crystalline material, such as a polycrystalline material), it may no longer be in the liquid state. Rather, its cations and anions may be situated on or within the solid material to form an ionic-liquid-modified material which is itself solid.

### Optoelectronic Device

The present invention provides an optoelectronic device comprising:
(a) a layer comprising a crystalline A/M/X material, wherein the crystalline A/M/X material comprises a compound of formula:

[A]ₐ[M]_{b}[X]_{c}

wherein: [A] comprises one or more A cations; [M] comprises one or more M cations which are metal or metalloid cations; [X] comprises one or more X anions; a is a number from 1 to 6; b is a number from 1 to 6; and c is a number from 1 to 18; and

(b) an ionic liquid which is a salt comprising an organic cation and a counter anion, wherein the organic cation is present within the layer comprising the crystalline A/M/X material.

The organic cation is present within the layer comprising the crystalline A/M/X material typically means that the organic cation is present not just at the outer edges of the layer comprising the crystalline A/M/X material but also exists throughout the bulk of the layer comprising the crystalline A/M/X material.

Typically, the organic cation is present within the crystalline A/M/X material. Typically, the crystalline A/M/X material is a polycrystalline A/M/X material comprising crystallites of the A/M/X material and grain boundaries between the crystallites. Thus, the layer comprising a crystalline A/M/X material may comprise multiple crystallites of the A/M/X material with grain boundaries between the crystallites.

When the crystalline A/M/X material is a polycrystalline A/M/X material comprising crystallites of the A/M/X material and grain boundaries between the crystallites, typically the organic cation is present at grain boundaries between the crystallites. For instance, the organic cation may be present throughout the bulk of the layer comprising the crystalline A/M/X material at grain boundaries between the crystallites.

### Ionic Liquid

Typically, the counter anion is other than a halide anion, or the organic cation is other than an unsubstituted or substituted imidazolium cation. Thus, in one embodiment the counter anion is other than a halide anion. In another embodiment the organic cation is other than an unsubstituted or substituted imidazolium cation.

Thus, in one embodiment the ionic liquid comprises an organic cation other than a unsubstituted or substituted imidazolium cation and counter-anion which is a halide anion. In another embodiment, the ionic liquid comprises an organic cation which is an unsubstituted or substituted imidazolium cation and a counter-anion that is other than a halide anion. In one embodiment the organic cation is other than unsubstituted or substituted imidazolium cation and the counter-anion is other than a halide anion.

Counter anions other than halide anions are well known to the skilled person. For instance the counter-anion may be a hydroxide, a chalcogenide, a borate, a phosphate, a nitrate, a nitrite, a carborane anion, a carbonate, a sulphate, a polyatomic anion comprising a halogen, a thiocyanate anion, a triflate, an oxyanion of a transition metal, a negatively charged metal complex or an organic anion.

Examples of chalcogenides include sulphide, selenide, and telluride. Examples of polyatomic anions comprising a halogen include hypofluorite, hypochorite, chlorite, chlorate, perchlorate, hypobromite, bromite, bromate, perbromate, hypoiodite, hypoioidite, iodate and periodiate. Oxyanions of a transition metal include manganite ([MnO₄]⁻), chromate ([CrO₄]²⁻) and dichromate ([Cr₂O₇]²⁻). Examples of negatively charged metal complexes include [Al(OC(CF₃)₃)₄)]⁻.

Typically, the counter-anion is a polyatomic anion. In other words, the counter-anion may be a molecule comprising two or more atoms that carries a negative charge. Preferably the polyatomic anion is a non-coordinating anion. Examples of non-coordinating anions include borates, chlorates, triflates, carborane anions (e.g. CB₁₁H₁₂⁻), phosphates and [Al(OC(CF₃)₃)₄)].

Examples of phosphates include hexahalophosphates such as hexafluorophosphate ([PF₆]⁻). Thus, in one embodiment, the counter-anion is hexafluorophosphate ([PF₆]⁻).

Typically, the counter-anion is a borate anion. Typically, the borate anion is an anion of the formula [BX₄]⁻, wherein each X is independently selected from hydrogen, halo, unsubstituted or substituted alkyl, unsubstituted or substituted alkeynyl, unsubstituted or substituted alkynyl, unsubstituted or substituted aryl, or unsubstituted or substituted heteroaryl. For instance, each X may be independently selected from halo or unsubstituted or substituted aryl, typically pentafluorophenyl or 3,5-bis(trifluoromethyl)phenyl.

Typically, all four X atoms are halo. Thus, preferably the counter-anion is tetrafluoroborate (BF₄⁻).

Alternatively, all four X groups may be substituted aryl. For instance all four X groups may be pentafluorophenyl or 3 5-bis(trifluoromethyl)phenyl. Thus, the counter-anion may be tetrakis(pentafluorophenyl)borate ([B(C₆F₅)₄]⁻) or tetrakis[3,5-bis(trifluoromethyl)phenyl]borate ([B(3,5-(CF₃)₂C₆H₃)₄]⁻).

In one embodiment, the organic cation is an unsubstituted or substituted imidazolium cation. Typically, the unsubstituted or substituted imidazolium cation is an imidazolium cation of formula I:

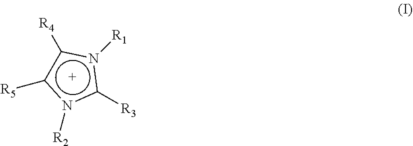

wherein each of R₁, R₂, R₃, R₄ and R₅ is independently selected from hydrogen, unsubstituted or substituted C₁₋₁₀ alkyl, unsubstituted or substituted C₂₋₁₀ alkenyl, unsubstituted or substituted C₂₋₁₀ alkynyl, unsubstituted or substituted C₆₋₁₂ aryl, unsubstituted or substituted C₃₋₁₀ cycloalkyl, unsubstituted or substituted C₃₋₁₀ cycloalkenyl, amino, unsubstituted or substituted (C₁₋₆ alkyl)amino and unsubstituted or substituted di(C₁₋₆ alkyl)amino.

Typically, each of R₁, R₂, R₃, R₄ and R₅ is independently selected from hydrogen, unsubstituted or substituted C₁₋₁₀ alkyl, unsubstituted C₂₋₁₀ alkenyl, unsubstituted C₂₋₁₀ alkynyl, unsubstituted C₆₋₁₂ aryl, unsubstituted C₃₋₁₀ cycloalkyl, unsubstituted C₃₋₁₀ cycloalkenyl, amino, unsubstituted (C₁₋₆ alkyl)amino and unsubstituted di(C₁₋₆ alkyl)amino;

Preferably, R₃, R₄ and R₅ are hydrogen and each of R₁ and R₂ is independently selected from unsubstituted C₁₋₁₀ alkyl and C₁₋₁₀ alkyl substituted with a phenyl group.

Thus, in one embodiment R₃, R₄ and R₅ are hydrogen, R₁ is unsubstituted C₁₋₁₀ alkyl and R₂ is benzyl. Thus, the organic cation may be 1-benzyl-3-methyl-1H-imidazol-3-ium.

In another embodiment, R₃, R₄ and R₅ are hydrogen and both R₁ and R₂ are unsubstituted C₁₋₁₀ alkyl. For instance, R₁ may be methyl whilst R₂ is selected from methyl, ethyl, propyl, butyl, pentyl, hexyl, heptyl, octyl, nonyl or decyl, preferably methyl, ethyl, propyl and butyl. Thus, the organic cation may be 1-butyl-3-methylimidazolium or 1-ethyl-3-methylimidazolium.

Thus, the ionic liquid may comprise an organic cation that is an unsubstituted or substituted imidazolium cation, and a counter-anion that is a polyatomic anion. For instance, the ionic liquid may comprise an organic cation that is an imidazolium cation of formula I and a counter-anion that is a non-coordinating polyatomic anion, for instance a borate, chlorate, triflate, carborane (e.g. CB₁₁H₁₂⁻), phosphate or [Al(OC(CF₃)₃)₄)]⁻ anion. Typically, the ionic liquid comprises an organic cation that is an imidazolium cation of formula I and a counter-anion that is a borate anion, typically BF₄⁻, or a phosphate anion, typically PF₆⁻. Preferably, the organic cation is 1-benzyl-3-methyl-1H-imidazol-3-ium, 1-butyl-3-methylimidazolium or 1-ethyl-3-methylimidazolium and the counter-anion is BF₄⁻.

Hence, in one embodiment the organic cation is 1-butyl-3-methylimidazolium and the counter anion is BF₄⁻. In another embodiment the organic cation is 1-ethyl-3-methylimidazolium and the counter anion is BF₄⁻. In another embodiment the organic cation is 1-benzyl-3-methylimidazolium and the counter anion is BF₄⁻.

As discussed above, the organic cation may be other than an unsubstituted or substituted imidazolium cation as described herein. For instance, the organic cation may be other than an unsubstituted or substituted imidazolium cation and the counter-anion may be a halide, or any of the anions other than halide described herein.

Typically, the organic cation is an unsubstituted or substituted heteroaryl cation or an unsubstituted or substituted heterocyclyl cation. Typically, the organic cation is an unsubstituted or substituted heteroaryl cation, such as an unsubstituted or substituted pyridinium cation, or an unsubstituted or substituted heterocyclyl cation, such as an unsubstituted or substituted piperidinium cation or an unsubstituted or substituted pyrrolidinium cation. Thus the organic cation is typically an unsubstituted or substituted pyridinium cation, an unsubstituted or substituted piperidinium cation or an unsubstituted or substituted pyrrolidinium cation.

The unsubstituted or substituted pyridinium cation may be a pyridinium cation of formula II:

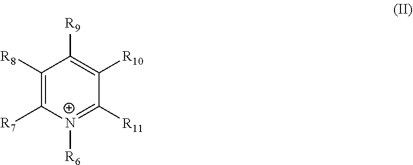

wherein each of R₆, R₇, R₈, R₉, R₁₀ and R₁₁ is independently selected from hydrogen, unsubstituted or substituted C₁₋₁₀ alkyl, unsubstituted or substituted C₂₋₁₀ alkenyl, unsubstituted or substituted C₂₋₁₀ alkynyl, unsubstituted or substituted C₆₋₁₂ aryl, unsubstituted or substituted C₃₋₁₀ cycloalkyl, unsubstituted or substituted C₃₋₁₀ cycloalkenyl, amino, unsubstituted or substituted (C₁₋₆ alkyl)amino and unsubstituted or substituted di(C₁₋₆ alkyl)amino.

Typically, each of R₆, R₇, R₈, R₉, R₁₀ and R₁₁ is independently selected from hydrogen, unsubstituted or substituted C₁₋₁₀ alkyl, unsubstituted C₂₋₁₀ alkenyl, unsubstituted C₂₋₁₀ alkynyl, unsubstituted C₆₋₁₂ aryl, unsubstituted C₃₋₁₀ cycloalkyl, unsubstituted C₃₋₁₀ cycloalkenyl, amino, unsubstituted (C₁₋₆ alkyl)amino and unsubstituted di(C₁₋₆ alkyl)amino.

Often R₇, R₈, R₁₀ and R₁₁ are hydrogen and each of R₆ and R₉ is independently selected from unsubstituted C₁₋₁₀ alkyl and C₁₋₁₀ alkyl substituted with a phenyl group. For instance, R₇, R₈, R₁₀ and R₁₁ may be hydrogen and R₆ and R₉ are unsubstituted C₁₋₁₀ alkyl, preferably C₁₋₆ alkyl. Thus, R₇, R₈, R₁₀ and R₁₁ may be hydrogen, R₉ may be methyl and R₆ may be selected from methyl, ethyl, propyl, butyl, pentyl and hexyl, preferably butyl. Thus the pyridinium cation may be 1-butyl-4-methylpyridin-1-ium.

The unsubstituted or substituted piperidinium cation may be a piperidinium cation of formula III:

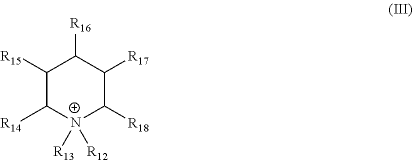

wherein each of R₁₂, R₁₃, R₁₄, R₁₅, R₁₆, R₁₇ and R₁₈ is independently selected from hydrogen, unsubstituted or substituted C₁₋₁₀ alkyl, unsubstituted or substituted C₂₋₁₀ alkenyl, unsubstituted or substituted C₂₋₁₀ alkynyl, unsubstituted or substituted C₆₋₁₂ aryl, unsubstituted or substituted C₃₋₁₀ cycloalkyl, unsubstituted or substituted C₃₋₁₀ cycloalkenyl, amino, unsubstituted or substituted (C₁₋₆ alkyl)amino and unsubstituted or substituted di(C₁₋₆ alkyl)amino.

Typically, each of R₁₂, R₁₃, R₁₄, R₁₅, R₁₆, R₁₇ and R₁₈ is independently selected from hydrogen, unsubstituted or substituted C₁₋₁₀ alkyl, unsubstituted C₂₋₁₀ alkenyl, unsubstituted C₂₋₁₀ alkynyl, unsubstituted C₆₋₁₂ aryl, unsubstituted C₃₋₁₀ cycloalkyl, unsubstituted C₃₋₁₀ cycloalkenyl, amino, unsubstituted (C₁₋₆ alkyl)amino and unsubstituted di(C₁₋₆ alkyl)amino. Often, R₁₄, R₁₅, R₁₆, R₁₇ and R₁₈ are hydrogen and each of R₁₂ and R₁₃ is independently selected from unsubstituted C₁₋₁₀ alkyl and C₁₋₁₀ alkyl substituted with a phenyl group.

Typically, R₁₄, R₁₅, R₁₆, R₁₇ and Ris are hydrogen and each of R₁₂ and R₁₃ is independently selected from unsubstituted C₁₋₁₀ alkyl, preferably unsubstituted C₁₋₆ alkyl. For instance, R₁₄, R₁₅, R₁₆, R₁₇ and R₁₈ may be hydrogen, R₁₃ may be methyl and R₁₄ may be selected from methyl, ethyl, propyl, butyl, pentyl or hexyl, preferably butyl. Thus, the piperidinium cation may be 1-butyl-1-methylpiperidin-1-ium.

The unsubstituted or substituted pyrrolidinium cation may be a pyrrolidinium cation of formula IV:

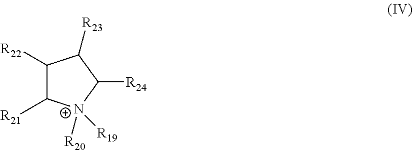

wherein each of R₁₉, R₂₀, R₂₁, R₂₂, R₂₃ and R₂₄ is independently selected from hydrogen, unsubstituted or substituted C₁₋₁₀ alkyl, unsubstituted or substituted C₂₋₁₀ alkenyl, unsubstituted or substituted C₂₋₁₀ alkynyl, unsubstituted or substituted C₆₋₁₂ aryl, unsubstituted or substituted C₃₋₁₀ cycloalkyl, unsubstituted or substituted C₃₋₁₀ cycloalkenyl, amino, unsubstituted or substituted (C₁₋₆ alkyl)amino and unsubstituted or substituted di(C₁₋₆ alkyl)amino.

Typically each of R₁₉, R₂₀, R₂₁, R₂₂, R₂₃ and R₂₄ is independently selected from hydrogen, unsubstituted or substituted C₁₋₁₀ alkyl, unsubstituted C₂₋₁₀ alkenyl, unsubstituted C₂₋₁₀ alkynyl, unsubstituted C₆₋₁₂ aryl, unsubstituted C₃₋₁₀ cycloalkyl, unsubstituted C₃₋₁₀ cycloalkenyl, amino, unsubstituted (C₁₋₆ alkyl)amino and unsubstituted di(C₁₋₆ alkyl)amino.

Often, R₂₁, R₂₂, R₂₃ and R₂₄ are hydrogen and each of Rig and R₂₀ is independently selected from unsubstituted C₁₋₁₀ alkyl and C₁₋₁₀ alkyl substituted with a phenyl group.

Typically, R₂₁, R₂₂, R₂₃ and R₂₄ are hydrogen and each of Rig and R₂₀ is independently selected from unsubstituted C₁₋₁₀ alkyl, preferably unsubstituted C₁₋₆ alkyl. For instance, R₂₁, R₂₂, R₂₃ and R₂₄ may be hydrogen, Rig may be methyl and R₂₀ may be selected from methyl, ethyl, propyl, butyl, pentyl or hexyl, preferably butyl. Thus, the pyrrolidinium cation may be 1-butyl-1-methylpyrrolidin-1-ium.

In one embodiment, the organic cation is an unsubstituted or substituted pyridinium cation, an unsubstituted or substituted piperidinium cation or an unsubstituted or substituted pyrrolidinium cation as described above and the counter-anion is a halide anion.

For instance, the organic cation may be an unsubstituted or substituted pyridinium cation of formula (II), preferably 1-butyl-4-methylpyridin-1-ium, and the counter-anion may be a halide anion. The organic cation may be an unsubstituted or substituted piperidinium cation of formula (III), preferably 1-butyl-1-methylpiperidin-1-ium, and the counter-anion may be a halide anion. The organic cation may be an unsubstituted or substituted pyrrolidinium cation of formula (IV), preferably 1-butyl-1-methylpyrrolidin-1-ium, and the counter-anion may be a halide anion.

In another embodiment, the organic cation is an unsubstituted or substituted pyridinium cation, an unsubstituted or substituted piperidinium cation or an unsubstituted or substituted pyrrolidinium cation as described above and the counter-anion is a polyatomic anion as described herein. Typically, the counter-anion is a borate anion, preferably BF₄⁻.

For instance, the organic cation may be an unsubstituted or substituted pyridinium cation of formula (II), preferably 1-butyl-4-methylpyridin-1-ium, and the counter-anion may be a borate anion, preferably BF₄⁻. The organic cation may be an unsubstituted or substituted piperidinium cation of formula (III), preferably 1-butyl-1-methylpiperidin-1-ium, and the counter-anion may be a borate anion, preferably BF₄⁻. The organic cation may be an unsubstituted or substituted pyrrolidinium cation of formula (IV), preferably 1-butyl-1-methylpyrrolidin-1-ium, and the counter-anion may be a borate anion, preferably BF₄⁻.

Typically, the ionic liquid is present in an amount of less than 50 mol %, for instance less than 10 mol %, particularly less than 1.0 mol % with respect to the number of moles of the one or more metal or metalloid cations M in the crystalline A/M/X material. For instance, the ionic liquid may be present in an amount of from 0.1 mol % to 0.9 mol % with respect to the number of moles of the one or more metal or metalloid cations M in the crystalline A/M/X material, for instance from 0.2 mol % to 0.8 mol %, from 0.2 mol % to 0.7 mol % or less than 0.5 mol %, or from 0.2 mol % to 0.5 mol %.

### Further Layers

Often, the optoelectronic device further comprises a layer comprising a charge-transporting material. Typically, the layer comprising the crystalline A/M/X material is disposed on the layer comprising the charge-transporting material. Preferably, the layer comprising the crystalline A/M/X material is disposed directly on the layer comprising the charge-transporting material, such that the layer comprising the crystalline A/M/X material and the layer comprising the charge-transporting material are in physical contact.

In one embodiment, the layer comprising a charge transporting material is a layer of an electron transporting (n-type) material (an n-type layer). In another embodiment, the layer comprising a charge transporting material is a layer of a hole transporting (p-type) material (a p-type layer). Typically, the layer comprising a charge transporting material is a layer of a hole transporting (p-type) material. Thus, typically the charge-transporting material is a hole-transporting (p-type) material.

Typically, the layer comprising a charge transporting material has a thickness of less than 1000 nm, or less than 500 nm, or less than 250 nm, preferably less than 100 nm. For instance, the layer comprising a charge transporting material may have a thickness of from 1 to 500 nm, for instance from 5 to 250 nm, or from 10 to 75 nm. In some embodiments, the layer of a charge transporting material may have a thickness of from 20 to 50 nm or from 30 to 40 nm.

Examples of electron transporting (n-type) materials are known to the skilled person. A suitable n-type material may be an organic or inorganic material. A suitable inorganic n-type material may be selected from a metal oxide, a metal sulphide, a metal selenide, a metal telluride, a perovskite, amorphous Si, an n-type group IV semiconductor, an n-type group III-V semiconductor, an n-type group II-VI semiconductor, an n-type group I-VII semiconductor, an n-type group IV-VI semiconductor, an n-type group V-VI semiconductor, and an n-type group II-V semiconductor, any of which may be doped or undoped. More typically, the n-type material is selected from a metal oxide, a metal sulphide, a metal selenide, and a metal telluride.

Thus, the n-type layer may comprise an inorganic material selected from oxide of titanium, tin, zinc, niobium, tantalum, tungsten, indium, gallium, neodymium, palladium, or cadmium, or an oxide of a mixture of two or more of said metals. For instance, the n-type layer may comprise TiO₂, SnO₂, ZnO, Nb₂O₅, Ta₂O₅, WO₃, W₂O₅, In₂O₃, Ga₂O₃, Nd₂O₃, PbO, or CdO. Other suitable n-type materials that may be employed include sulphides of cadmium, tin, copper, or zinc, including sulphides of a mixture of two or more of said metals. For instance, the sulphide may be FeS₂, CdS, ZnS, SnS, BiS, SbS, or Cu₂ZnSnS₄.

The n-type layer may for instance comprise a selenide of cadmium, zinc, indium, or gallium or a selenide of a mixture of two or more of said metals; or a telluride of cadmium, zinc, cadmium or tin, or a telluride of a mixture of two or more of said metals. For instance, the selenide may be Cu(In,Ga)Se₂. Typically, the telluride is a telluride of cadmium, zinc, cadmium or tin. For instance, the telluride may be CdTe.

The n-type layer may for instance comprise an inorganic material selected from oxide of titanium (e.g. TiO₂), tin (e.g. SnO₂), zinc (e.g. ZnO), niobium, tantalum, tungsten, indium, gallium, neodymium, palladium, cadmium, or an oxide of a mixture of two or more of said metals; a sulphide of cadmium, tin, copper, zinc or a sulphide of a mixture of two or more of said metals; a selenide of cadmium, zinc, indium, gallium or a selenide of a mixture of two or more of said metals; or a telluride of cadmium, zinc, cadmium or tin, or a telluride of a mixture of two or more of said metals.

Examples of other semiconductors that may be suitable n-type materials, for instance if they are n-doped, include group IV elemental or compound semiconductors; amorphous Si; group III-V semiconductors (e.g. gallium arsenide); group II-VI semiconductors (e.g. cadmium selenide); group I-VII semiconductors (e.g. cuprous chloride); group IV-VI semiconductors (e.g. lead selenide); group V-VI semiconductors (e.g. bismuth telluride); and group II-V semiconductors (e.g. cadmium arsenide).

Other n-type materials may also be employed, including organic and polymeric electron-transporting materials, and electrolytes. Suitable examples include, but are not limited to a fullerene or a fullerene derivative (for instance C₆₀, C₇₀, phenyl-C₆₁-butyric acid methyl ester (PCBM), PC₇₁BM (i.e. phenyl C₇₁ butyric acid methyl ester), bis[C₆₀]BM (i.e. bis-C₆₀ butyric acid methyl ester), and 1′,1″,4′,4″-Tetrahydro-di[1,4]methanonaphthaleno[1,2:2′,3′,56,60:2″,3″][5,6]fullerene-C₆₀ (ICBA)), an organic electron transporting material comprising perylene or a derivative thereof, poly {[N,N0-bis(2-octyldodecyl)-naphthalene-1,4,5,8-bis(dicarboximide)-2,6-diyl]-alt-5,50-(2,20-bithiophene)} (P(NDI2OD-T2)) or bathocuproine (BCP).

Typically, the n-type material is phenyl-C61-butyric acid methyl ester (PCBM).

Examples of hole transporting (p-type) materials are known to the skilled person. The p-type material may be a single p-type compound or elemental material, or a mixture of two or more p-type compounds or elemental materials, which may be undoped or doped with one or more dopant elements.

The p-type material may comprise an inorganic or an organic p-type material. For instance, the p-type material may be an organic p-type material.

Suitable p-type materials may be selected from polymeric or molecular hole transporters. The p-type material may for instance comprise spiro-OMeTAD (2,2′,7,7′-tetrakis-(N,N-di-p-methoxyphenylamine)9,9′-spirobifluorene)), P3HT (poly(3-hexylthiophene)), PCPDTBT (Poly[2,1,3-benzothiadiazole-4,7-diyl[4,4-bis(2-ethylhexyl)-4H-cyclopentax[2,1-b:3,4-b′]dithiophene-2,6-diyl]]), PVK (poly(N-vinylcarbazole)), HTM-TFSI (1-hexyl-3-methylimidazolium bis(trifluoromethylsulfonyl)imide), Li-TFSI (lithium bis(trifluoromethanesulfonyl)imide), Spiro-OMETAD⁺-bis(trifluoromethanesulfonyl)imide⁻(spiro(TFSI)₂), tBP (tert-butylpyridine), m-MTDATA (4,4′,4″-tris(methylphenylphenylamino)triphenylamine), MeOTPD (N,N,N′,N′-tetrakis(4-methoxyphenyl)-benzidine), BP2T (5,5′-di(biphenyl-4-yl)-2,2′-bithiophene), Di-NPB (N,N′-Di-[(1-naphthyl)-N,N′-diphenyl]-1,1′-biphenyl)-4,4′-diamine), α-NPB (N,N′-di(naphthalen-1-yl)-N,N′-diphenyl-benzidine), TNATA (4,4′,4″-tris-(N-(naphthylen-2-yl)-N-phenylamine)triphenylamine), BPAPF (9,9-bis[4-(N,N-bis-biphenyl-4-yl-amino)phenyl]-9H-fluorene), spiro-NPB (N2,N7-Di-1-naphthalenyl-N2,N7-diphenyl-9,9′-spirobi[9H-fluorene]-2,7-diamine), 4P-TPD (4,4-bis-(N,N-diphenylamino)-tetraphenyl), polyTPD (i.e. Poly[N,N′-bis(4-butylphenyl)-N,N′-bisphenylbenzidine]), PTAA (i.e. poly(triaryl amine), also known as poly[bis(4-phenyl)(2,4,6-trimethylphenyl)amine]) or PEDOT:PSS. The p-type material may comprise carbon nanotubes. Usually, the p-type material is selected from spiro-OMeTAD, P3HT, PCPDTBT, polyTPD, spiro(TFSI)₂ and PVK. In one embodiment, the p-type material is polyTPD.

Suitable p-type materials also include molecular hole transporters, polymeric hole transporters and copolymer hole transporters. The p-type material may for instance be a molecular hole transporting material, a polymer or copolymer comprising one or more of the following moieties: thiophenyl, phenelenyl, dithiazolyl, benzothiazolyl, diketopyrrolopyrrolyl, ethoxydithiophenyl, amino, triphenyl amino, carbozolyl, ethylene dioxythiophenyl, dioxythiophenyl, or fluorenyl.

The p-type material may be doped, for instance with tertbutyl pyridine and LiTFSI. The p-type material may be doped to increase the hole-density. The p-type material may for instance be doped with NOBF₄ (Nitrosonium tetrafluoroborate), to increase the hole-density.

Typically, the hole-transporting material (p-type material) is a solid state inorganic hole transporting material. For instance, the p-type layer may comprise an inorganic hole transporter comprising an oxide of nickel (e.g. NiO), vanadium, copper or molybdenum; CuI, CuBr, CuSCN, Cu₂O, CuO or CIS; a perovskite; amorphous Si; a p-type group IV semiconductor, a p-type group III-V semiconductor, a p-type group II-VI semiconductor, a p-type group I-VII semiconductor, a p-type group IV-VI semiconductor, a p-type group V-VI semiconductor, and a p-type group II-V semiconductor, which inorganic material may be doped or undoped. The p-type layer may be a compact layer of said inorganic hole transporter.

The p-type material may be an inorganic p-type material, for instance a material comprising an oxide of nickel, vanadium, copper or molybdenum; CuI, CuBr, CuSCN, Cu₂O, CuO or CIS; amorphous Si; a p-type group IV semiconductor, a p-type group III-V semiconductor, a p-type group II-VI semiconductor, a p-type group I-VII semiconductor, a p-type group IV-VI semiconductor, a p-type group V-VI semiconductor, and a p-type group II-V semiconductor, which inorganic material may be doped or undoped. The p-type material may for instance comprise an inorganic hole transporter selected from CuI, CuBr, CuSCN, Cu₂O, CuO and CIS.

Typically, the layer of a hole transporting (p-type) material is a solid state inorganic hole transporting material comprising an oxide of nickel, vanadium, copper or molybdenum. The solid state inorganic hole transporting material is typically present as a compact layer. Preferably, the solid state inorganic hole transporting material comprises nickel oxide. For instance, the optoelectronic device may comprise a compact layer of nickel oxide. Typically, the layer comprising a crystalline A/M/X material is disposed directly on the layer of a hole transporting (p-type) material, for instance the layer comprising solid state inorganic hole transporting material comprising nickel oxide, preferably the compact layer of nickel oxide

Hence, the optoelectronic device of the present invention may comprise the following layers in the following order:
Layer of a charge transporting material (typically an p-type material as described herein, but this may alternatively be a n-type material);
Layer of a crystalline A/M/X material, modified with an ionic liquid as described herein.

In one embodiment, the optoelectronic device comprises two layers of a charge transporting material as described herein. Hence, the optoelectronic device of the present invention may comprise the following layers in the following order:
Layer of a charge transporting material (typically an p-type material as described herein, but this may alternatively be a n-type material);
Layer of a crystalline A/M/X material, modified with an ionic liquid as described herein;
Layer of a charge transporting material (typically an n-type material as described herein, but this may alternatively be a p-type material)

The optoelectronic device of the present invention may further comprise a first electrode and a second electrode.

The first electrode may comprise a metal (for instance silver, gold, aluminium or tungsten), an organic conducting material such as PEDOT:PSS, or a transparent conducting oxide (for instance fluorine doped tin oxide (FTO), aluminium doped zinc oxide (AZO) or indium doped tin oxide (ITO)). Typically the first electrode is a transparent electrode. Thus, the first electrode typically comprises a transparent conducting oxide, preferably FTO, ITO or AZO. The thickness of the layer of a first electrode is typically from 10 nm to 1000 nm, more typically from 40 to 400 nm.

The second electrode may be as defined above for the first electrode, for instance, the second electrode may comprise a metal (for instance silver, gold, aluminium or tungsten), an organic conducting material such as PEDOT:PSS, or a transparent conducting oxide (for instance fluorine doped tin oxide (FTO), aluminium doped zinc oxide (AZO) or indium doped tin oxide (ITO)). Typically, the second electrode comprises, or consists essentially of, a metal for instance an elemental metal. Examples of metals which the second electrode material may comprise, or consist essentially of, include silver, gold, copper, aluminium, platinum, palladium, or tungsten. The second electrode may be disposed by vacuum evaporation. The thickness of the layer of a second electrode material is typically from 10 to 1000 nm, preferably from 50 nm to 150 nm.

The second electrode may optionally include a further layer comprising a metal/metal oxide, typically a layer comprising mixture of chromium and chromium (III) oxide (Cr/Cr₂O₃). The thickness of the Cr/Cr₂O₃ layer is typically between 1 to 10 nm.

Typically, the optoelectronic device comprises one or more layers of a charge transporting material as described herein. As described herein, typically the layer comprising the crystalline A/M/X material is disposed on the layer comprising the hole-transporting material. Thus, the optoelectronic device of the present invention may comprise the following layers in the following order:
First electrode (typically comprises a transparent conducting oxide);
Layer of a charge transporting material (typically an p-type material as described herein, but this may alternatively be a n-type material);
Layer of a crystalline A/M/X material as described herein, modified with an ionic liquid as described herein;
Layer of a charge transporting material (typically an n-type material as described herein, but this may alternatively be a p-type material)
Second electrode (typically comprises an elemental metal).

The optoelectronic device of the present invention may have a positive-intrinsic-negative (p i-n) structure or an negative-intrinsic-positive (n-i-p) structure. In a positive-intrinsic-negative (p-i-n) structure, the layer of a crystalline A/M/X material is deposited upon the p-type layer, and the n-type layer is deposited on top of the layer of a crystalline A/M/X material. Typically, light enters the device from the side where the p-type layer is. However, if the second electrode in the p-i-n structured device is a transparent electrode, then light can enter from the n-type layer. In a negative-intrinsic-positive (n-i-p) structure, the layer of a crystalline A/M/X material is deposited upon the n-type layer, with the p-type layer deposited on top of the layer of a crystalline A/M/X material. Typically, light enters the n-i-p device from the side where the n-type layer is. However, in the instance where the second electrode is semi-transparent, then light can be incident through the p-type layer in an n-i-p cell structure. Typically, the optoelectronic device of the present invention has a positive-intrinsic-negative (p-i-n) structure.

Hence, the optoelectronic device may comprise a layer comprising the hole-transporting (p-type) material as described herein, wherein the layer comprising the crystalline A/M/X material is disposed on the layer comprising the hole-transporting material, and may further comprise:
a first electrode comprising a transparent conducting oxide, wherein the layer comprising the hole-transporting material is disposed between the layer comprising the crystalline A/M/X material and the first electrode;
a layer comprising an electron-transporting (n-type) material as described herein; and
a second electrode which comprises a metal in elemental form, wherein the layer comprising the electron-transporting material is disposed between the layer comprising the crystalline A/M/X material and the second electrode.

It should be appreciated that the optoelectronic devices described above may comprise one or more additional layers disposed between the layers described above. For instance, the optoelectronic device may comprise one or more additional layers disposed between the first electrode and the layer of a charge transporting material. The optoelectronic device may comprise one or more additional layers disposed between the either of the layers of a charge transporting material and the layer of the crystalline A/M/X material. The optoelectronic device may comprise one or more additional layers disposed between the layer of a charge transporting material and the second electrode.

For instance, the optoelectronic device may comprise one or more additional layers that comprise an electron transporting (n-type) material. Typically such layers are disposed between the layer comprising a charge transporting material (typically an electron transporting material) and the second electrode. In this instance, the additional layers comprising an electron transport material may comprise an electron transporting material as described herein. Typically, the electron transporting material is an organic electron transporting material, for instance fullerene or a fullerene derivative (for instance C₆₀, C₇₀, phenyl-C₆₁-butyric acid methyl ester (PCBM), PC₇₁BM (i.e. phenyl C₇₁ butyric acid methyl ester), bis[C₆₀]BM (i.e. bis-C₆₀ butyric acid methyl ester), and 1′,1″,4′,4″-Tetrahydro-di[1,4]methanonaphthaleno[1,2:2′,3′,56,60:2″,3″][5,6]fullerene-C₆₀ (ICBA)), an organic electron transporting material comprising perylene or a derivative thereof, poly {[N,N0-bis(2-octyldodecyl)-naphthalene-1,4,5,8-bis(dicarboximide)-2,6-diyl]-alt-5,50-(2,20-bithiophene)} (P(NDI2OD-T2)) or bathocuproine (BCP), preferably bathocuproine (BCP).

Thus, the present invention typically employs two n-type layers in between the second electrode and the layer of the crystalline A/M/X material. Hence, in on embodiment, the optoelectronic device of the present invention comprises the following layers in the following order:
First electrode, preferably comprising a transparent conducting oxide as described herein;
Layer of a hole transporting (n-type) material, preferably a compact layer of nickel oxide;
Layer of a crystalline A/M/X material as described herein, typically comprising a compound of Formula IA or ID as described below, modified with an ionic liquid as described herein;
Layer of an electron transporting (p-type) material, preferably PCBM;
Additional layer of an electron transporting material, preferably comprising bathocuproine;
Second electrode, preferably comprising an elemental metal, optionally comprising a layer comprising a mixture of chromium and chromium (III) oxide (Cr/Cr₂O₃).

In one embodiment the optoelectronic device of the present invention comprises the following layers in the following order:
First electrode comprising a transparent conducting oxide as described herein, preferably FTO, ITO or AZO;
Compact layer of nickel oxide;
Layer of an ionic-liquid modified crystalline A/M/X comprising a compound of Formula IA or ID as described below, modified with an ionic liquid as described herein, preferably an ionic liquid comprising an unsubstituted or substituted imidazolium cation and a borate anion, preferably 1-butyl-3-methylimidazolium tetrafluoroborate;
Layer of PCBM;
Additional layer of a material comprising bathocuproine;
Second electrode comprising an elemental metal, preferably gold, and a layer comprising a mixture of chromium and chromium (III) oxide (Cr/Cr₂O₃).

The optoelectronic device of the present invention may be a photovoltaic device, a photodiode (including solar cells), a phototransistor, a photomultiplier, a photoresistor, or a light emitting device. Typically, the optoelectronic device of the present invention is a photovoltaic device or a light-emitting device. Preferably, the photovoltaic device is a positive-intrinsic-negative (p-i-n) planar heterojunction photovoltaic device.

### Location of Counter Anion

The counter-anion may be present (a) within the layer comprising the crystalline A/M/X material, (b) between the layer comprising the crystalline A/M/X material and the layer comprising the charge-transporting material, and/or (c) within the layer comprising the charge-transporting material.

In one embodiment, the counter-anion is present within the layer comprising the crystalline A/M/X material. In another embodiment the counter-anion is present between the layer comprising the crystalline A/M/X material and the layer comprising the charge-transporting material. In another embodiment the counter-anion is present within the layer comprising the charge-transporting material.

For instance, the counter-anion may be present: (a) within the layer comprising the crystalline A/M/X material and (b) between the layer comprising the crystalline A/M/X material and the layer comprising the charge-transporting material. The counter-anion may be present: (a) within the layer comprising the crystalline A/M/X material and (c) within the layer comprising the charge-transporting material. The counter-anion may be present: (b) between the layer comprising the crystalline A/M/X material and (c) within the layer comprising the charge-transporting material. The counter-anion may be present (a) within the layer comprising the crystalline A/M/X material, (b) between the layer comprising the crystalline A/M/X material and the layer comprising the charge-transporting material and (c) within the layer comprising the charge-transporting material.

Typically, some or all of the counter-anion is present: (b) between the layer comprising the crystalline A/M/X material and the layer comprising the charge-transporting material and (c) within the layer comprising the charge-transporting material. Some of the counter-anion may be present: (b) between the layer comprising the crystalline A/M/X material and the layer comprising the charge-transporting material and (c) within the layer comprising the charge-transporting material. All of the counter-anion may be present: (b) between the layer comprising the crystalline A/M/X material and the layer comprising the charge-transporting material and (c) within the layer comprising the charge-transporting material.

Typically, some or all of the counter-anion is present within the layer comprising the charge-transporting material. For instance, some of the counter-anion may be present within the layer comprising the charge-transporting material. For instance, all of the counter-anion may be present within the layer comprising the charge-transporting material.

Typically, some or all of the counter-anion is not present within the crystalline A/M/X material. For instance, at least some of the counter-anion may be present on an outer surface of the crystalline A/M/X material. For instance, all of the counter-anion may be present on an outer surface of the crystalline A/M/X material. Therefore, the counter-anion may not be present in the bulk material of the layer comprising the crystalline A/M/X material and may, for instance, be present at the interface with the charge transporting material.

As discussed above, the layer comprising the charge-transporting material may be a layer of an electron transporting (n-type) material, as described herein, or a layer of a hole transporting (p-type) material, as described herein. Typically, the layer comprising a charge transporting material is a layer of a hole transporting (p-type) material. Thus, typically the charge-transporting material is a hole-transporting (p-type) material. Typically, the layer comprising the charge-transporting material comprises nickel oxide and is preferably a compact layer of nickel oxide. Typically, the layer comprising the crystalline A/M/X material is directly disposed on the layer comprising the charge transporting material, such that the layer comprising the crystalline A/M/X material and the layer comprising the charge-transporting material are in physical contact. Thus, the layer comprising the crystalline A/M/X material may be directly disposed on a layer comprising nickel oxide (preferably a compact layer of nickel oxide).

Hence, the counter-anion may be present (a) within the layer comprising the crystalline A/M/X material, (b) between the layer comprising the crystalline A/M/X material and the layer of hole transporting (p-type) material, preferably a compact layer of nickel oxide, and/or (c) within the layer of hole transporting (p-type) material, preferably a compact layer of nickel oxide. It is thought that the ionic liquid provides improved interaction at the interface between the layer of the crystalline A/M/X material and the compact layer of nickel oxide, thereby enhancing V_{OC}, fill factor (FF) and efficiency (PCE).

### A/M/X Material

The optoelectronic device of the present invention comprises a layer comprising a crystalline A/M/X material, the crystalline A/M/X material comprising a compound of formula: [A]ₐ[M]_{b}[X]_{c}, wherein: [A] comprises one or more A cations; [M] comprises one or more M cations which are metal or metalloid cations; [X] comprises one or more X anions; a is a number from 1 to 6; b is a number from 1 to 6; and c is a number from 1 to 18. a is often a number from 1 to 4, b is often a number from 1 to 3, and c is often a number from 1 to 8.

Each of a, b and c may or may not be an integer. For instance, a, b or c may not be an integer where the compound adopts a structure having vacancies such that the crystal lattice is not completely filled. The method of the invention provides very good control over stoichiometry of the product and so is well-suited for forming structures where a, b or c is not an integer (for instance a structure having vacancies in one or more of the A, M or X sites). Accordingly, in some embodiments, one or more of a, b and c is a non-integer value. For example, one of a, b and c may be a non-integer value. In one embodiment, a is a non-integer value. In another embodiment, b is a non-integer value. In yet another embodiment, c is a non-integer value.

In other embodiments, each of a, b and c are integer values. Thus, in some embodiments, a is an integer from 1 to 6; b is an integer from 1 to 6; and c is an integer from 1 to 18. a is often an integer from 1 to 4, b is often an integer from 1 to 3, and c is often an integer from 1 to 8.

In the compound of formula [A]ₐ[M]_{b}[X]_{c}, generally: [A] comprises one or more A cations, which A cations may for instance be selected from alkali metal cations or organic monocations; [M] comprises one or more M cations which are metal or metalloid cations selected from Pd⁴⁺, Re⁴⁺, Os⁴⁺, Ir⁴, Pt⁴⁺, Sn⁴⁺, Pb⁴⁺, Ge⁴⁺, Te⁴⁺, Bi³⁺, Sb³⁺, Ca²⁺, Sr²⁺, Cd²⁺, Cu²⁺, Ni²⁺, Mn²⁺, Fe²⁺, Co²⁺, Pd²⁺, Ge²⁺, Sn²⁺, Pb²⁺, Yb²⁺ and Eu²⁺, preferably Sn²⁺, Pb²⁺, Cu²⁺, Ge²⁺, and Ni²⁺; particularly preferably Pb²⁺ and Sn²⁺; [X] comprises one or more X anions selected from halide anions (e.g. Cl⁻, Br⁻, and I⁻), O²⁻, S²⁻, Se²⁻, and Te²⁻; a is a number from 1 to 4; b is a number from 1 to 3; and c is a number from 1 to 8.

Preferably the compound of formula [A]ₐ[M]_{b}[X]_{c} comprises a perovskite. The compound of formula [A]ₐ[M]_{b}[X]_{c} often comprises a metal halide perovskite.

[M] comprises one or more M cations which are metal or metalloid cations. [M] may comprise two or more different M cations. [M] may comprise one or more monocations, one or more dications, one or more trications or one or more tetracations.

Typically, the one or more M cations are selected from Ca²⁺, Sr²⁺, Cd²⁺, Cu²⁺, Ni²⁺, Mn²⁺, Fe²⁺, Co²⁺, Pd²⁺, Ge²⁺, Sn²⁺, Pb²⁺, Yb²⁺, Eu²⁺, Bi³⁺, Sb³⁺, Pd⁴⁺, W⁺, Re⁴⁺, Os⁴⁺, Ir⁴⁺, Pt⁴⁺, Sn⁴⁺, Pb⁴⁺, Ge⁴⁺ or Te⁴⁺. Preferably, the one or more M cations are selected from Cu²⁺, Pb²⁺, Ge²⁺ or Sn²⁺.

Typically, [M] comprises one or more metal or metalloid dications. For instance, each M cation may be selected from Ca²⁺, Sr²⁺, Cd²⁺, Cu²⁺, Ni²⁺, Mn²⁺, Fe²⁺, Co²⁺, Pd²⁺, Ge²⁺, Sn²⁺, Pb²⁺, Yb²⁺, and Eu²⁺, preferably Sn²⁺, Pb²⁺, Cu²⁺, Ge²⁺, and Ni²⁺; preferably Sn²⁺ and Pb²⁺. In some embodiments, [M] comprises two different M cations, typically where said cations are Sn²⁺ and Pb²⁺, preferably Pb²⁺.

In general, said one or more A cations are monocations. [A] typically comprises one or more A cations which may be organic and/or inorganic monocations. Typically, [A] comprises two or more different A cations.

For instance, [A] may comprise at least two A cations which may be organic and/or inorganic monocations, or at least three A cations which may be organic and/or inorganic monocations. Thus, the compound of formula [A]ₐ[M]_{b}[X]_{c} may be a mixed cation perovskite. [A] may comprise at least one A cation which is an organic cation and at least one A cation which is an inorganic cation. [A] may comprise at least two A cations which are both organic cations. [A] may comprise at least two A cations which are both inorganic cations. In one embodiment, [A] comprises two A cations which are both organic cations and an A cation which is an inorganic cation.

Where an A species is an inorganic monocation, A is typically an alkali metal monocation (that is, a monocation of a metal found in Group 1 of the periodic table), for instance Li⁺, Na⁺, K⁺, Rb⁺, Cs⁺, for example Cs⁺ or Rb⁺. Typically, [A] comprises at least one organic monocation. Where an A species is an organic monocation, A is typically an ammonium cation, for instance methylammonium, or an iminium cation, for instance formamidimium.

Thus, typically each A cation is selected from: an alkali metal cation, for instance Li+, Na+, K+, Rb+, Cs+; a cation of the formula [R₁R₂R₃R₄N]⁺, wherein each of R₁, R₂, R₃, R₄ is independently selected from hydrogen, unsubstituted or substituted C₁₋₂₀ alkyl, and unsubstituted or substituted C₆₋₁₂ aryl, and at least one of R₁, R₂, R₃ and R₄ is not hydrogen; a cation of the formula [R₅R₆N═CH—NR₇R₈]⁺, wherein each of R₅, R₆, R₇ and R₈ is independently selected from hydrogen, unsubstituted or substituted C₁₋₂₀ alkyl, and unsubstituted or substituted C₆₋₁₂ aryl; and C₁₋₁₀ alkylamammonium, C₂₋₁₀ alkenylammonium, C₁₋₁₀ alkyliminium, C₃₋₁₀ cycloalkylammonium and C₃₋₁₀ cycloalkyliminium, each of which is unsubstituted or substituted with one or more substituents selected from amino, C₁₋₆ alkylamino, imino, C₁₋₆ alkylimino, C₁₋₆ alkyl, C₂₋₆ alkenyl, C₃₋₆ cycloalkyl and C₆₋₁₂ aryl.

For instance, each A cation is selected from Cs⁺, Rb⁺, methylammonium [(CH₃NH₃)⁺], ethylammonium [(CH₃CH₂NH₃)⁺], propylammonium [(CH₃CH₂CH₂NH₃)⁺]. Butylammonium [(CH₃CH₂CH₂CH₂NH₃)⁺], pentylammoium [(CH₃CH₂CH₂CH₂CH₂NH₃)⁺], hexylammonium [(CH₃CH₂CH₂CH₂CH₂CH₂NH₃)⁺], heptylammonium [(CH₃CH₂CH₂CH₂CH₂CH₂CH₂NH₃)⁺], octylammonium [(CH₃CH₂CH₂CH₂CH₂CH₂CH₂CH₂NH₃)⁺], tetramethylammonium [(N(CH₃)₄)⁺], formamidinium [(H₂N—C(H)═NH₂)⁺], 1-aminoethan-1-iminium [(H₂N—C(CH₃)═NH₂)⁺] and guanidinium [(H₂N—C(NH₂)═NH₂)⁺]. Preferably each A cation is selected from Cs⁺, Rb⁺, methylammonium, ethylammonium, propylammonium. butylammonium, pentylammoium, hexylammonium, heptylammonium, octylammonium, formamidinium and guanidinium.

[A] usually comprises one, two or three A monocations. [A] may comprises a single cation selected from methylammonium [(CH₃NH₃)⁺], ethylammonium [(CH₃CH₂NH₃)⁺], propylammonium [(CH₃CH₂CH₂NH₃)+], dimethylammonium [(CH₃)₂NH⁺], tetramethylammonium [(N(CH₃)₄)⁺], formamidinium [(H₂N—C(H)═NH2)+], 1-aminoethan-1-iminium [(H₂N—C(CH₃)═NH₂)⁺], guanidinium [(H₂N—C(NH₂)═NH₂)⁺], Cs⁺ and Rb⁺. For instance [A] may comprise a single cation that is methylammonium [(CH₃NH₃)⁺].

Alternatively, [A] may comprise two cations selected from this group, for instance Cs⁺ and formamidinium [(H₂N—C(H)═NH₂)⁺], or for instance Cs⁺ and Rb⁺, or for instance methylammonium [(CH₃NH₃)⁺] and formamidinium [(H₂N—C(H)═NH₂)⁺], preferably Cs⁺ and formamidinium [(H₂N—C(H)═NH₂)⁺].

Alternatively, [A] may comprise three cations selected from this group, for instance methylammonium [(CH₃NH₃)⁺], formamidinium [(H₂N—C(H)═NH₂)⁺] and Cs⁺.

[X] comprises one or more X anions. Typically, [X] comprises one or more halide anions, i.e. an anion selected from F⁻, Br⁻, Cl⁻ and I⁻. Typically, each X anion is a halide. [X] typically comprises one, two or three X anions and these are generally selected from Br⁻, Cl⁻ and I⁻.

X may comprise two more different X anions. Typically, [X] comprises two or more different halide anions. [X] may for instance consist of two X anions, such as Cl and Br, or Br and I, or Cl and I. Therefore, the compound of formula [A]ₐ[M]_{b}[X]_{c} often comprises a mixed halide perovskite. When [A] comprises one or more organic cations, the compound of formula [A]ₐ[M]_{b}[X]_{c} may be an organic-inorganic metal halide perovskite.

Typically, said one or more A cations are monocations, said one or more M cations are dications, and said one or more X anions are one or more halide anions.

Often, [A] comprises at least two different A cations as described herein and [X] comprises at least two different X anions as described herein. In some embodiments, [A] comprises at least three different A cations as described herein and [X] comprises at least two different X anions as described herein.

Typically, a=1, b=1 and c=3. Thus, the compound of formula [A]ₐ[M]_{b}[X]_{c} may be a compound of formula [A][M][X]₃, wherein [A], [M] and [X] are as described herein. Typically, the crystalline A/M/X material comprises: a perovskite of formula (I):

[A][M][X]₃ (I)

wherein: [A] comprises one or more A cations which are monocations; [M] comprises one or more M cations which are metal or metalloid dications; and [X] comprises one or more anions which are halide anions.

In some embodiments, the perovskite of formula (I) comprises a single A cation, a single M cation and a single X cation. i.e., the perovskite is a perovskite of the formula (IA):

AMX₃ (IA)

wherein A, M and X are as defined above. In a preferred embodiment, A is selected from (CH₃NH₃)⁺, (CH₃CH₂NH₃)⁺, (CH₃CH₂CH₂NH₃)⁺, (N(CH₃)₄)⁺, (H₂N—C(H)═NH₂)⁺, (H₂N—C(CH₃)═NH₂)⁺, (H₂N—C(NH₂)═NH₂)⁺, Cs⁺ and Rb⁺; M is Pb²⁺ or Sn²⁺ and X is selected from Br⁻, Cl⁻ and I⁻.

For instance, the crystalline A/M/X material may comprise, or consist essentially of, a perovskite compound of formula (IA) selected from APbI₃, APbBr₃, APbCl₃, ASnI₃, ASnBr₃ and ASnCl₃, wherein A is a cation as described herein.

For instance, the crystalline A/M/X material may comprise, or consist essentially of, a perovskite compound of formula (IA) selected from CH₃NH₃PbI₃, CH₃NH₃PbBr₃, CH₃NH₃PbCl₃, CH₃NH₃SnI₃, CH₃NH₃SnBr₃, CH₃NH₃SnCl₃, CsPbI₃, CsPbBr₃, CsPbCl₃, CsSnI₃, CsSnBr₃, CsSnC₁₃, (H₂N—C(H)═NH₂)PbI₃, (H₂N—C(H)═NH₂)PbBr₃, (H₂N—C(H)═NH₂)PbCl₃, (H₂N—C(H)═NH₂)SnI₃, (H₂N—C(H)═NH₂)SnBr₃ and (H₂N—C(H)═NH₂)SnCl₃, in particular CH₃NH₃PbI₃ or CH₃NH₃PbBr₃, preferably CH₃NH₃PbI₃.

In one embodiment, the perovskite is a perovskite of the formula (IB):

[A^{I}ₓA^{II}₁₋ₓ]MX₃ (IB)

wherein A^{I} and A^{II} are as defined above with respect to A, wherein M and X are as defined above and wherein x is greater than 0 and less than 1. In a preferred embodiment, A^{I} and A^{II} are each selected from (CH₃NH₃)⁺, (CH₃CH₂NH₃)⁺, (CH₃CH₂CH₂NH₃)⁺, (N(CH₃)₄)⁺, (H₂N—C(H)═NH₂)⁺, (H₂N—C(CH₃)═NH₂)⁺, (H₂N—C(NH₂)═NH₂)⁺, Cs⁺ and Rb⁺; M is Pb²⁺ or Sn²⁺ and X is selected from Br⁻, Cl⁻ and I⁻. A^{I} and A^{II} may for instance be (H₂N—C(H)═NH₂)⁺ and Cs⁺ respectively, or they may be (CH₃NH₃)⁺ and (H₂N—C(H)═NH₂)⁺ respectively. Alternatively, they may be Cs⁺ and Rb⁺ respectively. Preferably, A^{I} and A^{II} are (H₂N—C(H)═NH₂)⁺ and Cs⁺ respectively

For instance, the crystalline A/M/X material may comprise, or consist essentially of, a perovskite compound of formula (IB) selected from (CsₓRb₁₋ₓ)PbBr₃, (CsₓRb₁₋ₓ)PbCl₃, (CsₓRb₁₋ₓ)PbI₃, [(CH₃NH₃)ₓ(H₂N—C(H)═NH₂)₁₋ₓ]PbCl₃, [(CH₃NH₃)ₓ(H₂N—C(H)═NH₂)₁₋ₓ]PbBr₃, [(CH₃NH₃)ₓ(H₂N—C(H)═NH₂)₁₋ₓ]PbI₃, [(CH₃NH₃)ₓCs₁₋ₓ]PbCl₃, [(CH₃NH₃)ₓCs₁₋ₓ]PbBr₃, [(CH₃NH₃)ₓCs₁₋ₓ]PbI₃, [(H₂N—C(H)═NH₂)ₓCs₁₋ₓ]PbCl₃, [(H₂N—C(H)═NH₂)ₓCs₁₋ₓ]PbBr₃, [(H₂N—C(H)═NH₂)ₓCs₁₋ₓ]PbI₃, [(CH₃NH₃)ₓ(H₂N—C(H)═NH₂)₁₋ₓ]SnCl₃, [(CH₃NH₃)ₓ(H₂N—C(H)═NH₂)₁₋ₓ]SnBr₃, [(CH₃NH₃)ₓ(H₂N—C(H)═NH₂)₁₋ₓ]SnI₃, [(CH₃NH₃)ₓCs₁₋ₓ]SnCl₃, [(CH₃NH₃)ₓCs₁₋ₓ]SnBr₃, [(CH₃NH₃)ₓCs₁₋ₓ]SnI₃, [(H₂N—C(H)═NH₂)ₓCs₁₋ₓ]SnCl₃, [(H₂N—C(H)═NH₂)ₓCs₁₋ₓ]SnBr₃, and [(H₂N—C(H)═NH₂)ₓCs₁₋ₓ]SnI₃, where x is greater than 0 and less than 1, for instance x may be from 0.01 to 0.99 or from 0.05 to 0.95 or 0.1 to 0.9.

In one embodiment, the perovskite is a perovskite compound of the formula (IC):

AM[X^{I}_{y}X^{II}_{1-y}]₃ (IC)

wherein A and M are as defined above, wherein X^{I} and X^{II} are as defined above in relation to X and wherein y is greater than 0 and less than 1. In a preferred embodiment, A is selected from (CH₃NH₃)⁺, (CH₃CH₂NH₃)⁺, (CH₃CH₂CH₂NH₃)⁺, (N(CH₃)₄)⁺, (H₂N—C(H)═NH₂)⁺, (H₂N—C(CH₃)═NH₂)⁺, (H₂N—C(NH₂)═NH₂)⁺, Cs⁺ and Rb⁺; M is Pb²⁺ or Sn²⁺; and X^{I} and X^{II} are each selected from Br⁻, Cl⁻ and I⁻.

For instance, the crystalline A/M/X material may comprise, or consist essentially of, a perovskite compound of formula (IC) selected from APb[Br_{y}I_{1-y}]₃, APb[Br_{y}Cl_{1-y}]₃, APb[I_{y}Cl_{1-y}]₃, ASn[Br_{y}I_{1-y}]₃, ASn[Br_{y}Cl_{1-y}]₃, ASn[I_{y}Cl_{1-y}]₃, where y is greater than 0 and less than 1, and wherein A is a cation as described herein. y may be from 0.01 to 0.99. For instance, y may be from 0.05 to 0.95 or 0.1 to 0.9.

For instance, the crystalline A/M/X material may comprise, or consist essentially of, a perovskite compound of formula (IC) selected from CH₃NH₃Pb[Br_{y}I_{1-y}]₃, CH₃NH₃Pb[Br_{y}Cl_{1-y}]₃, CH₃NH₃Pb[I_{y}Cl_{1-y}]₃, CH₃NH₃Sn[Br_{y}I_{1-y}]₃, CH₃NH₃Sn[Br_{y}Cl_{1-y}]₃, CH₃NH₃Sn[I_{y}Cl_{1-y}]₃, CsPb[Br_{y}I_{1-y}]₃, CsPb[Br_{y}Cl_{1-y}]₃, CsPb[I_{y}Cl_{1-y}]₃, CsSn[Br_{y}I_{1-y}]₃, CsSn[Br_{y}Cl_{1-y}]₃, CsSn[I_{y}Cl_{1-y}]₃, (H₂N—C(H)═NH₂)Pb[Br_{y}I_{1-y}]₃, (H₂N—C(H)═NH₂)Pb[Br_{y}Cl_{1-y}]₃, (H₂N—C(H)═NH₂)Pb[I_{y}Cl_{1-y}]₃, (H₂N—C(H)═NH₂)Sn[Br_{y}I_{1-y}]₃, (H₂N—C(H)═NH₂)Sn[Br_{y}Cl_{1-y}]₃, and (H₂N—C(H)═NH₂)Sn[I_{y}Cl_{1-y}]₃, where y is greater than 0 and less than 1, for instance y may be from 0.01 to 0.99 or from 0.05 to 0.95 or 0.1 to 0.9.

In a preferred embodiment, the perovskite is a perovskite of the formula (ID):

[A^{I}ₓA^{II}₁₋ₓ]M[X^{I}_{y}X^{II}_{1-y}]₃ (ID)

wherein A^{I} and A^{II} are as defined above with respect to A, M is as defined above, X^{I} and X^{II} are as defined above in relation to X and wherein x and y are both greater than 0 and less than 1. In a preferred embodiment, A^{I} and A^{II} are each selected from ((CH₃NH₃)⁺, (CH₃CH₂NH₃)⁺, (CH₃CH₂CH₂NH₃)⁺, (N(CH₃)₄)⁺, (H₂N—C(H)═NH₂)⁺, (H₂N—C(CH₃)═NH₂)⁺, (H₂N—C(NH₂)═NH₂)⁺, Cs⁺ and Rb⁺, preferably A^{I} and A^{II} are (H₂N—C(H)═NH₂)⁺ and Cs⁺ respectively; M is Pb²⁺ or Sn²⁺; and X^{I} and X^{II} are each selected from Br⁻, Cl⁻ and I⁻.

For instance, the crystalline A/M/X material may comprise, or consist essentially of, a perovskite compound of formula (ID) selected from (CsₓRb₁₋ₓ)Pb(Br_{y}Cl_{1-y})₃, (CsₓRb₁₋ₓ)Pb(Br_{y}I_{1-y})₃, and (CsₓRb₁₋ₓ)Pb(Cl_{y}I_{1-y})₃, [(CH₃NH₃)ₓ(H₂N—C(H)═NH₂)₁₋ₓ]Pb[Br_{y}I_{1-y}]₃, [(CH₃NH₃)ₓ(H₂N—C(H)═NH₂)₁₋ₓ]Pb[Br_{y}Cl_{1-y}]₃, [(CH₃NH₃)ₓ(H₂N—C(H)═NH₂)₁₋ₓ]Pb[I_{y}Cl_{1-y}]₃, [(CH₃NH₃)ₓCs₁₋ₓ]Pb[Br_{y}I_{1-y}]₃, [(CH₃NH₃)ₓCs₁₋ₓ]Pb[Br_{y}Cl_{1-y}]₃, [(CH₃NH₃)ₓCs₁₋ₓ]Pb[I_{y}Cl_{1-y}]₃, [(H₂N—C(H)═NH₂)ₓCs₁₋ₓ]Pb[Br_{y}I_{1-y}]₃, [(H₂N—C(H)═NH₂)ₓCs₁₋ₓ]Pb[Br_{y}Cl_{1-y}]₃, [(H₂N—C(H)═NH₂)ₓCs₁₋ₓ]Pb[I_{y}Cl_{1-y}]₃, [(CH₃NH₃)ₓ(H₂N—C(H)═NH₂)₁₋ₓ]Sn[Br_{y}I_{1-y}]₃, [(CH₃NH₃)ₓ(H₂N—C(H)═NH₂)₁₋ₓ]Sn[Br_{y}Cl_{1-y}]₃, [(CH₃NH₃)ₓ(H₂N—C(H)═NH₂)₁₋ₓ]Sn[I_{y}Cl_{1-y}]₃, [(CH₃NH₃)ₓCs₁₋ₓ]Sn[Br_{y}I_{1-y}]₃, [(CH₃NH₃)ₓCs₁₋ₓ]Sn[Br_{y}Cl_{1-y}]₃, [(CH₃NH₃)ₓCs₁₋ₓ]Sn[I_{y}Cl_{1-y}]₃, [(H₂N—C(H)═NH₂)ₓCs₁₋ₓ]Sn[Br_{y}I_{1-y}]₃, [(H₂N—C(H)═NH₂)ₓCs₁₋ₓ]Sn[Br_{y}Cl_{1-y}]₃, and [(H₂N—C(H)═NH₂)ₓCs₁₋ₓ]Sn[I_{y}Cl_{1-y}]₃, where x and y are both greater than 0 and less than 1, for instance x and y may both be from 0.01 to 0.99 or from 0.05 to 0.95 or 0.1 to 0.9.

In one embodiment, the perovskite is a perovskite of the formula (IE):

A[M^{I}_{z}M^{II}_{1-z}]X₃ (IE)

wherein M^{I} and M^{II} are as defined above with respect to M, A and X are as defined above, and wherein z is greater than 0 and less than 1. In a preferred embodiment, A is selected from (CH₃NH₃)⁺, (CH₃CH₂NH₃)⁺, (CH₃CH₂CH₂NH₃)⁺, (N(CH₃)₄)⁺, (H₂N—C(H)═NH₂)⁺, (H₂N—C(CH₃)═NH₂)⁺, (H₂N—C(NH₂)═NH₂)⁺, Cs⁺ and Rb⁺; M^{I} is Pb²⁺ and M^{II} is Sn²⁺; and X is selected from Br⁻, Cl⁻ and I⁻.

For instance, the crystalline A/M/X material may comprise, or consist essentially of, a perovskite compound of formula (IE) selected from CH₃NH₃[Pb_{z}Sn_{1-z}]Cl₃, CH₃NH₃[Pb_{z}Sn_{1-z}]Br₃, CH₃NH₃[Pb_{z}Sn_{1-z}]I₃, Cs[Pb_{z}Sn_{1-z}]Cl₃, Cs[Pb_{z}Sn_{1-z}]Br3, Cs[Pb_{z}Sn_{1-z}]I₃, (H₂N—C(H)═NH₂)[Pb_{z}Sn_{1-z}]Cl₃, (H₂N—C(H)═NH₂)[Pb_{z}Sn_{1-z}]Br₃, and (H₂N—C(H)═NH₂)[Pb_{z}Sn_{1-z}]I₃, where z is greater than 0 and less than 1, for instance z may be from 0.01 to 0.99 or from 0.05 to 0.95 or 0.1 to 0.9.

In one embodiment, the perovskite is a perovskite of the formula (IF):

[A^{I}ₓA^{II}₁₋ₓ][M^{I}_{z}M^{II}_{1-z}]X₃ (IF)

wherein A^{I} and A^{II} are as defined above with respect to A, M^{I} and M^{II} are as defined above with respect to M, and X is as defined above and wherein x and z are both greater than 0 and less than 1. In a preferred embodiment, A^{I} and A^{II} are each selected from (CH₃NH₃)⁺, (CH₃CH₂NH₃)⁺, (CH₃CH₂CH₂NH₃)⁺, (N(CH₃)₄)⁺, (H₂N—C(H)═NH₂)⁺, (H₂N—C(CH₃)═NH₂)⁺, (H₂N—C(NH₂)═NH₂)⁺, Cs⁺ and Rb⁺; M^{II} is Pb²⁺ and M^{II} is Sn²⁺; and X is selected from Br⁻, Cl⁻ and I⁻. A^{I} and A^{II} may for instance be (H₂N—C(H)═NH₂)⁺ and Cs⁺ respectively, or they may be (CH₃NH₃)⁺ and (H₂N—C(H)═NH₂)⁺ respectively. Alternatively, they may be Cs⁺ and Rb⁺ respectively.

For instance, the crystalline A/M/X material may comprise, or consist essentially of, a perovskite compound of formula (IF) selected from [(CH₃NH₃)ₓ(H₂N—C(H)═NH₂)₁₋ₓ][Pb_{z}Sn_{1-z}]Cl₃, [(CH₃NH₃)ₓ(H₂N—C(H)═NH₂)₁₋ₓ][Pb_{z}Sn_{1-z}]Br₃, [(CH₃NH₃)ₓ(H₂N—C(H)═NH₂)₁₋ₓ][Pb_{z}Sn_{1-z}]I₃, [(CH₃NH₃)ₓCs₁₋ₓ][Pb_{z}Sn_{1-z}]Cl₃, [(CH₃NH₃)ₓCs₁₋ₓ][Pb_{z}Sn_{1-z}]Br₃, [(CH₃NH₃)ₓCs₁₋ₓ][Pb_{z}Sn_{1-z}]I₃, [(H₂N—C(H)═NH₂)ₓCs₁₋ₓ][Pb_{z}Sn_{1-z}]Cl₃, [(H₂N—C(H)═NH₂)ₓCs₁₋ₓ][Pb_{z}Sn_{1-z}]Br₃, [(H₂N—C(H)═NH₂)ₓCs₁₋ₓ][Pb_{z}Sn_{1-z}]I₃, where x and z are both greater than 0 and less than 1, for instance x and z may each be from 0.01 to 0.99 or from 0.05 to 0.95 or 0.1 to 0.9.

In one embodiment, the perovskite is a perovskite compound of the formula (IG):

A[M^{I}_{z}M^{II}_{1-z}][X^{I}_{y}X^{II}_{1-y}]₃ (IG)

wherein A is as defined above, M^{I} and M^{II} are as defined above with respect to M, and wherein X^{I} and X^{II} are as defined above in relation to X and wherein y and z are both greater than 0 and less than 1. In a preferred embodiment, A is selected from (CH₃NH₃)⁺, (CH₃CH₂NH₃)⁺, (CH₃CH₂CH₂NH₃)⁺, (N(CH₃)₄)⁺, (H₂N—C(H)═NH₂)⁺, (H₂N—C(CH₃)═NH₂)⁺, (H₂N—C(NH₂)═NH₂)⁺, Cs⁺ and Rb⁺; M^{I} is Pb²⁺ and M^{II} is Sn²⁺; and X^{I} and X^{II} are each selected from Br⁻, Cl⁻ and I⁻.

For instance, the crystalline A/M/X material may comprise, or consist essentially of, a perovskite compound of formula (IG) selected from A[Pb_{z}Sn_{1-z}][Br_{y}I_{1-y}]₃, A[Pb_{z}Sn_{1-z}][Br_{y}Cl_{1-y}]₃, A[Pb_{z}Sn_{1-z}][I_{y}Cl_{1-y}]₃, where y and z are both greater than 0 and less than 1, and wherein A is a cation as described herein. y and z may each be from 0.01 to 0.99. For instance, y and z may each be from 0.05 to 0.95 or 0.1 to 0.9.

For instance, the crystalline A/M/X material may comprise, or consist essentially of, a perovskite compound of formula (IG) selected from CH₃NH₃[Pb_{z}Sn_{1-z}][Br_{y}I_{1-y}]₃, CH₃NH₃[Pb_{z}Sn_{1-z}][Br_{y}Cl_{1-y}]₃, CH₃NH₃[Pb_{z}Sn_{1-z}][I_{y}Cl_{1-y}]₃, Cs[Pb_{z}Sn_{1-z}][Br_{y}I_{1-y}]₃, Cs[Pb_{z}Sn_{1-z}][Br_{y}Cl_{1-y}]₃, Cs[Pb_{z}Sn_{1-z}][I_{y}Cl_{1-y}]₃, (H₂N—C(H)═NH₂)[Pb_{z}Sn_{1-z}][Br_{y}I_{1-y}]₃, (H₂N—C(H)═NH₂)[Pb_{z}Sn_{1-z}][Br_{y}Cl_{1-y}]₃, and (H₂N—C(H)═NH₂)[Pb_{z}Sn_{1-z}][I_{y}Cl_{1-y}]₃, where y and z are both greater than 0 and less than 1, for instance y and z may each be from 0.01 to 0.99 or from 0.05 to 0.95 or 0.1 to 0.9.

In a preferred embodiment, the perovskite is a perovskite of the formula (IH):

[A^{I}ₓA^{II}₁₋ₓ][M^{I}_{z}M^{II}_{1-z}][X^{I}_{y}X^{II}_{1-y}]₃ (IH)

wherein A^{I} and A^{II} are as defined above with respect to A, M^{I} and M^{II} are as defined above with respect to M, X^{I} and X^{II} are as defined above in relation to X and wherein x, y and z are each greater than 0 and less than 1. In a preferred embodiment, A^{I} and A^{II} are each selected from ((CH₃NH₃)⁺, (CH₃CH₂NH₃)⁺, (CH₃CH₂CH₂NH₃)⁺, (N(CH₃)₄)⁺, (H₂N—C(H)═NH₂)⁺, (H₂N—C(CH₃)═NH₂)⁺, (H₂N—C(NH₂)═NH₂)⁺, Cs⁺ and Rb⁺; M^{I} is Pb²⁺ and Mⁿ is Sn²⁺; and X^{I} and X^{II} are each selected from Br⁻, Cl⁻ and I⁻.

For instance, the crystalline A/M/X material may comprise, or consist essentially of, a perovskite compound of formula (IH) selected from [(CH₃NH₃)ₓ(H₂N—C(H)═NH₂)₁₋ₓ][Pb_{z}Sn_{1-z}][Br_{y}I_{1-y}]₃, [(CH₃NH₃)ₓ(H₂N—C(H)═NH₂)₁₋ₓ][Pb_{z}Sn_{1-z}][Br_{y}Cl_{1-y}]₃, (CH₃NH₃)ₓ(H₂N—C(H)═NH₂)₁₋ₓ][Pb_{z}Sn_{1-z}][I_{y}Cl_{1-y}]₃, [(CH₃NH₃)ₓCs₁₋ₓ][Pb_{z}Sn_{1-z}][Br_{y}I_{1-y}]₃, [(CH₃NH₃)ₓCs₁₋ₓ][Pb_{z}Sn_{1-z}][Br_{y}Cl_{1-y}]₃, [(CH₃NH₃)ₓCs₁₋ₓ][Pb_{z}Sn_{1-z}][I_{y}Cl_{1-y}]₃, [(H₂N—C(H)═NH₂)ₓCs₁₋ₓ][Pb_{z}Sn_{1-z}][Br_{y}I_{1-y}]₃, [(H₂N—C(H)═NH₂)ₓCs₁₋ₓ][Pb_{z}Sn_{1-z}][Br_{y}Cl_{1-y}]₃, and [(H₂N—C(H)═NH₂)ₓCs₁₋ₓ][Pb_{z}Sn_{1-z}][I_{y}Cl_{1-y}]₃, where x, y and z are each greater than 0 and less than 1, for instance x, y and z may each be from 0.01 to 0.99 or from 0.05 to 0.95 or 0.1 to 0.9.

In one embodiment, a=2, b=1 and c=4. In that embodiment, the crystalline A/M/X material comprises a compound (a “2D layered perovskite”) of formula (II):

[A]₂[M][X]₄ (II)

wherein: [A] comprises one or more A cations which are monocations; [M] comprises one or more M cations which are metal or metalloid dications; and [X] comprises one or more X anions which are halide anions. In this embodiment, the A and M cations, and the X anions, are as defined above.

In another embodiment, a=2, b=1 and c=6. In that embodiment, the crystalline A/M/X material may in that case comprise a hexahalometallate of formula (III):

[A]₂[M][X]₆ (III)

wherein: [A] comprises one or more A cations which are monocations; [M] comprises one or more M cations which are metal or metalloid tetracations; and [X] comprises one or more X anions which are halide anions.

The hexahalometallate of formula (III) may in a preferred embodiment be a mixed monocation hexahalometallate. In a mixed monocation hexahalometallate, [A] comprises at least two A cations which are monocations; [M] comprises at least one M cation which is a metal or metalloid tetracation (and typically [M] comprises a single M cation which is a metal or metalloid tetracation); and [X] comprises at least one X anion which is a halide anion (and typically [X] comprises a single halide anion or two types of halide anion). In a mixed metal hexahalometallate, [A] comprises at least one monocation (and typically [A] is a single monocation or two types of monocation); [M] comprises at least two metal or metalloid tetracations (for instance Ge⁴⁺ and Sn⁴⁺); and [X] comprises at least one halide anion (and typically [X] is a single halide anion or two types of halide anion). In a mixed halide hexahalometallate, [A] comprises at least one monocation (and typically [A] is a single monocation or two types of monocation); [M] comprises at least one metal or metalloid tetracation (and typically [M] is a single metal tetra cation); and [X] comprises at least two halide anions, for instance Br⁻ and Cl⁻ or Br⁻ and I⁻.

[A] may comprise at least one A monocation selected from any suitable monocations, such as those described above for a perovskite. In the case of a hexahalometallate, each A cation is typically selected from Li⁺, Na⁺, K⁺, Rb⁺, Cs⁺, NH₄⁺ and monovalent organic cations. Monovalent organic cations are singly positively charged organic cations, which may, for instance, have a molecular weight of no greater than 500 g/mol. For instance, [A] may be a single A cation which is selected from Li⁺, Na⁺, K⁺, Rb⁺, Cs⁺, NH₄⁺ and monovalent organic cations. [A] preferably comprises at least one A cation which is a monocation selected from Rb⁺, Cs⁺, NH₄⁺ and monovalent organic cations. For instance, [A] may be a single inorganic A monocation selected from Li⁺, Na⁺, K⁺, Rb⁺, Cs⁺ and NH₄⁺. In another embodiment, [A] may be at least one monovalent organic A cation. For instance, [A] may be a single monovalent organic A cation. In one embodiment, [A] is (CH₃NH₃)⁺. In another embodiment, [A] is (H₂N—C(H)═NH₂)⁺.

Preferably, [A] comprises two or more types of A cation. [A] may be a single A monocation, or indeed two A monocations, each of which is independently selected from K⁺, Rb⁺, Cs⁺, NH₄⁺, (CH₃NH₃)⁺, (CH₃CH₂NH₃)⁺, (CH₃CH₂CH₂NH₃)⁺, (N(CH₃)₄)⁺, (N(CH₂CH₃)₄)⁺, (N(CH₂CH₂CH₃)₄)⁺, (H₂N—C(H)═NH₂)⁺ and (H₂N—C(CH₃)═NH₂)⁺.

[M] may comprise one or more M cations which are selected from suitable metal or metalloid tetracations. Metals include elements of groups 3 to 12 of the Periodic Table of the Elements and Ga, In, Tl, Sn, Pb, Bi and Po. Metalloids include Si, Ge, As, Sb, and Te. For instance, [M] may comprise at least one M cation which is a metal or metalloid tetracation selected from Ti⁴⁺, V⁴⁺, Mn⁴⁺, Fe⁴⁺, Co⁴⁺, Zr⁴⁺, Nb⁴⁺, Mo⁴⁺, Ru⁴⁺, Rh⁴⁺, Pd⁴⁺, Hf⁴⁺, Ta⁴⁺, W⁴⁺, Re⁴⁺, Os⁴⁺, Ir⁴⁺, Pt⁴⁺, Sn⁴⁺, Pb⁴⁺, Po⁴⁺, Si⁴⁺, Ge⁴⁺, and Te⁴⁺. Typically, [M] comprises at least one metal or metalloid tetracation selected from Pd⁴⁺, W⁴⁺, Re⁴⁺, Os⁴⁺, Ir⁴⁺, Pt⁴⁺, Sn⁴⁺, Pb⁴⁺, Ge⁴⁺, and Te⁴⁺. For instance, [M] may be a single metal or metalloid tetracation selected from Pd⁴⁺, W⁴⁺, Re⁴⁺, Os⁴⁺, Ir⁴⁺, Pt⁴⁺, Sn⁴⁺, Pb⁴⁺, Ge⁴⁺, and Te⁴⁺.

Typically, [M] comprises at least one M cation which is a metal or metalloid tetracation selected from Sn⁴⁺, Te⁴⁺, Ge⁴⁺ and Re⁴⁺. In one embodiment [M] comprises at least one M cation which is a metal or metalloid tetracation selected from Pb⁴⁺, Sn⁴⁺, Te⁴⁺, Ge⁴⁺ and Re⁴⁺ For instance, [M] may comprise an M cation which is at least one metal or metalloid tetracation selected from Pb⁴⁺, Sn⁴⁺, Te⁴⁺ and Ge⁴⁺. Preferably, [M] comprises at least one metal or metalloid tetracation selected from Sn⁴⁺, Te⁴⁺, and Ge⁴⁺. As discussed above, the hexahalometallate compound may be a mixed-metal or a single-metal hexahalometallate. Preferably, the hexahalometallate compound is a single-metal hexahalometallate compound. More preferably, [M] is a single metal or metalloid tetracation selected from Sn⁴⁺, Te⁴⁺, and Ge⁴⁺. For instance, [M] may be a single metal or metalloid tetracation which is Te⁴⁺. For instance, [M] may be a single metal or metalloid tetracation which is Ge⁴⁺. Most preferably, [M] is a single metal or metalloid tetracation which is Sn⁴⁺.

[X] may comprise at least one X anion which is a halide anion. [X] therefore comprises at least one halide anion selected from F⁻, Cl⁻, Br⁻ and I⁻. Typically, [X] comprises at least one halide anion selected from Cl⁻, Br⁻ and I⁻. The hexahalometallate compound may be a mixed-halide hexahalometallate or a single-halide hexahalometallate. If the hexahalometallate is mixed, [X] comprises two, three or four halide anions selected from F⁻, Cl⁻, Br⁻ and I⁻. Typically, in a mixed-halide compound, [X] comprises two halide anions selected from F⁻, Cl⁻, Br⁻ and I⁻.

In some embodiments, [A] is a single monocation and [M] is a single metal or metalloid tetracation. Thus, the crystalline A/M/X material may, for instance, comprise a hexahalometallate compound of formula (IIIA)

A₂M[X]₆ (IIIA)

wherein: A is a monocation; M is a metal or metalloid tetracation; and [X] is at least one halide anion. [X] may be one, two or three halide anions selected from F⁻, Cl⁻, Br⁻ and I⁻, and preferably selected from Cl⁻, Br⁻ and I⁻. In formula (IIIA), [X] is preferably one or two halide anions selected from Cl⁻, Br⁻ and I⁻.

The crystalline A/M/X material may, for instance, comprise, or consist essentially of, a hexahalometallate compound of formula (IIIB)

A₂MX_{6-y}X′_{y} (IIIB)

wherein: A is a monocation (i.e. the second cation); M is a metal or metalloid tetracation (i.e. the first cation); X and X′ are each independently a (different) halide anion (i.e. two second anions); and y is from 0 to 6. When y is 0 or 6, the hexahalometallate compound is a single-halide compound. When y is from 0.01 to 5.99 the compound is a mixed-halide hexahalometallate compound. When the compound is a mixed-halide compound, y may be from 0.05 to 5.95. For instance, y may be from 1.00 to 5.00.

The hexahalometallate compound may, for instance, be A₂SnF_{6-y}Cl_{y}, A₂SnF_{6-y}Br_{y}, A₂SnF_{6-y}I_{y}, A₂SnCl_{6-y}Br_{y}, A₂SnCl_{6-y}I_{y}, A₂SnBr_{6-y}I_{y}, A₂TeF_{6-y}Cl_{y}, A₂TeF_{6-y}Br_{y}, A₂TeF_{6-y}I_{y}, A₂TeCl_{6-y}Br_{y}, A₂TeCl_{6-y}I_{y}, A₂TeBr_{6-y} I_{y}, A₂GeF_{6-y}Cl_{y}, A₂GeF_{6-y}Br_{y}, A₂GeF_{6-y}I_{y}, A₂GeCl_{6-y}Br_{y}, A₂GeCl_{6-y}I_{y}, A₂GeBr_{6-y}I_{y}, A₂ReF_{6-y}Cl_{y}, A₂ReF_{6-y} Br_{y}, A₂ReF_{6-y} I_{y}, A₂ReCl_{6-y}Br_{y}, A₂ReCl_{6-y}I_{y} or A₂ReBr_{6- y}I_{y}, wherein: A is K⁺, Rb⁺, Cs⁺, (R¹NH₃)⁺, (NR²₄)⁺, or (H₂N—C(R¹)═NH₂)⁺, wherein R¹ is H, a substituted or unsubstituted C₁₋₂₀ alkyl group or a substituted or unsubstituted aryl group, and R² is a substituted or unsubstituted C₁₋₁₀ alkyl group; and y is from 0 to 6. Optionally, y is from 0.01 to 5.99. If the hexahalometallate compound is a mixed-halide compound, y is typically from 1.00 to 5.00. A may be as defined above. For instance, A may be Cs⁺, NH₄⁺, (CH₃NH₃)⁺, (CH₃CH₂NH₃)⁺, (N(CH₃)₄)⁺, (N(CH₂CH₃)₄)⁺, (H₂N—C(H)═NH₂)⁺ or (H₂N—C(CH₃)═NH₂)⁺, for instance Cs⁺, NH₄⁺, or (CH₃NH₃)⁺.

The hexahalometallate compound may typically be A₂SnF_{6-y} Cl_{y}, A₂SnF_{6-y} Br_{y}, A₂SnF_{6-y} I_{y}, A₂SnCl_{6-y}Br_{y}, A₂SnCl_{6-y} I_{y}, or A₂SnBr_{6-y}I_{y}, wherein: A is K⁺, Rb⁺, Cs⁺, (R¹NH₃)⁺, (NR²₄)⁺, or (H₂N—C(R¹)═NH₂)⁺, or A is as defined herein, wherein R¹ is H, a substituted or unsubstituted C₁₋₂₀ alkyl group or a substituted or unsubstituted aryl group, or R² is a substituted or unsubstituted C₁₋₁₀ alkyl group; and y is from 0 to 6.

In another embodiment, the hexahalometallate compound is A₂GeF_{6-y}Cl_{y}, A₂GeF_{6-y}Br_{y}, A₂GeF_{6-y}I_{y}, A₂GeCl_{6-y}Br_{y}, A₂GeCl_{6-y}I_{y}, or A₂GeBr_{6-y}I_{y}, wherein: A is K⁺, Rb⁺, Cs⁺, (R¹NH₃)⁺, (NR²₄)⁺, or (H₂N—C(R′)═NH₂)⁺, or A is as defined herein, wherein R¹ is H, a substituted or unsubstituted C₁₋₂₀ alkyl group or a substituted or unsubstituted aryl group, and R² is a substituted or unsubstituted C₁₋₁₀ alkyl group; and y is from 0 to 6.

The hexahalometallate compound may, for instance, be A₂TeF_{6-y}Cl_{y}, A₂TeF_{6-y}Br_{y}, A₂TeF_{6-y}I_{y}, A₂TeCl_{6-y}Br_{y}, A₂TeCl_{6-y}I_{y}, or A₂TeBr_{6-y}I_{y}, wherein: A is K⁺, Rb⁺, Cs⁺, (R¹NH₃)⁺, (NR²₄)⁺, or (H₂N—C(R′)═NH₂)⁺, or A is as defined herein, wherein R¹ is H, a substituted or unsubstituted C₁₋₂₀ alkyl group or a substituted or unsubstituted aryl group, and R² is a substituted or unsubstituted C₁₋₁₀ alkyl group; and y is from 0 to 6 or y is as defined herein.

Often, y will be from 1.50 to 2.50. For instance, y may be from 1.80 to 2.20. This may occur if the compound is produced using two equivalents of AX′ and one equivalent of MX₄, as discussed below.

In some embodiments, all of the ions are single anions or cations. Thus, the crystalline A/M/X material may comprise, or consist essentially of, a hexahalometallate compound of formula (IIIC)

A₂MX₆ (IIIC)

wherein: A is a monocation; M is a metal or metalloid tetracation; and X is a halide anion. A, M and X may be as defined herein.

The hexahalometallate compound may be AzSnF₆, A₂SnCl₆, A₂SnBr₆, A₂SnI₆, A₂TeF₆, A₂TeCl₆, A₂TeBr₆, A₂TeI₆, A₂GeF₆, A₂GeCl₆, A₂GeBr₆, A₂GeI₆, A₂ReF₆, A₂ReC16, A₂ReBr₆ or AzReI₆, wherein: A is K⁺, Rb⁺, Cs⁺, (R¹NH₃)⁺, (NR²₄)⁺, or (H₂N—C(R′)═NH₂)⁺, wherein R¹ is H, a substituted or unsubstituted C₁₋₂₀ alkyl group or a substituted or unsubstituted aryl group, and R² is a substituted or unsubstituted C₁₋₁₀ alkyl group. A may be as defined herein. Preferably, the hexahalometallate compound is Cs₂SnI₆, Cs₂SnBr₆, Cs₂SnBr_{6-y} I_{y}, Cs₂SnCl_{6-y}I_{y}, Cs₂SnCl_{6-y} Br_{y}, (CH₃NH₃)₂SnI₆, (CH₃NH₃)₂SnBr₆, (CH₃NH₃)₂SnBr_{6-y} I_{y}, (CH₃NH₃)₂SnCl_{6-y}I_{y}, (CH₃NH₃)₂SnCl_{6-y} Br_{y}, (H₂N—C(H)═NH₂)₂Sn16, (H₂N—C(H)═NH₂)₂SnBr₆, (H₂N—C(H)═NH₂)₂SnBr_{6-y} I_{y}, (H₂N—C(H)═NH₂)₂SnCl_{6-y}I_{y} or (H₂N—C(H)═NH₂)₂SnCl_{6-y} Br_{y} wherein y is from 0.01 to 5.99. For example, the hexahalometallate compound may be (CH₃NH₃)₂SnI₆, (CH₃NH₃)₂SnBr₆, (CH₃NH₃)₂SnCl₆, (H₂N—C(H)═NH₂)₂SnI₆, (H₂N—C(H)═NH₂)₂SnBr₆ or (H₂N—C(H)═NH₂)₂SnCl₆. The hexahalometallate compound may be Cs₂SnI₆, Cs₂SnBr₆, Cs₂SnCl_{6-y}Br_{y}, (CH₃NH₃)₂SnI₆, (CH₃NH₃)₂SnBr₆, or (H₂N—C(H)═NH₂)₂SnI₆.

The crystalline A/M/X material may comprise a bismuth or antimony halogenometallate. For instance, the crystalline A/M/X material may comprise a halogenometallate compound comprising: (i) one or more monocations ([A]) or one or more dications ([B]); (ii) one or more metal or metalloid trications ([M]); and (iii) one or more halide anions ([X]). The compound may be a compound of formula BBiX₅, B₂BiX₇ or B₃BiX₉ where B is (H₃NCH₂NH₃)²⁺, (H₃N(CH₂)₂NH₃)²⁺, (H₃N(CH₂)₃NH₃)²⁺, (H₃N(CH₂)₄NH₃)²⁺, (H₃N(CH₂)₅NH₃)²⁺, (H₃N(CH₂)₆NH₃)²⁺, (H₃N(CH₂)₇NH₃)²⁺, (H₃N(CH₂)₈NH₃)²⁺ or (H₃N—C₆H₄—NH₃)²⁺ and X is I⁻, Br⁻ or Cl⁻, preferably I⁻.

In yet further embodiments, the crystalline A/M/X materials may be double perovskites. Such compounds are defined in WO 2017/037448, the entire contents of which is incorporated herein by reference. Typically, the compound is a double perovskite compound of formula (IV):

[A]₂[B⁺][B³⁺][X]₆ (IV);

wherein: [A] comprises one or more A cations which are monocations, as defined herein; [B⁺] and [B³⁺] are equivalent to [M] where M comprises one or more M cations which are monocations and one or more M cations which are trications; and [X] comprises one or more X anions which are halide anions.

The one or more M cations which are monocations comprised in [B⁺] are typically selected from metal and metalloid monocations. Preferably, the one or more M cations which are monocations are selected from Li⁺, Na⁺, K⁺, Rb⁺, Cs⁺, Cu⁺, Ag⁺, Au⁺ and Hg⁺. More preferably, the one or more M cations which are monocations are selected from Cu⁺, Ag⁺ and Au⁺. Most preferably, the one or more M cations which are monocations are selected from Ag⁺ and Au⁺. For instance, [B⁺] may be one monocation which is Ag⁺ or [B⁺] may be one monocation which is Au⁺.

The one or more M cations which are trications comprised in [B³⁺] are typically selected from metal and metalloid trications. Preferably, the one or more M cations which are trications are selected from Bi³⁺, Sb³⁺, Cr³⁺, Fe³⁺, Co³⁺, Ga³⁺, As³⁺, Ru³⁺, Rh³⁺, In³⁺, Ir³⁺ and Au³⁺. More preferably, the one or more M cations which are trications are selected from Bi³⁺ and Sb³⁺. For instance, [B³⁺] may be one trication which is Bi³⁺ or [B³⁺] may be one trication which is Sb³⁺. Bismuth has relatively low toxicity compared with heavy metals such as lead. In some embodiments, the one or more M cations which are monocations (in [B⁺]) are selected from Cu⁺, Ag⁺ and Au⁺ and the one or more M cations which are trications (in [B³⁺]) are selected from Bi³⁺ and Sb³⁺.

An exemplary double perovskite is Cs₂BiAgBr₆.

Typically, where the compound is a double perovskite it is a compound of formula (IVa):

A₂B⁺B³⁺[X]₆ (IVa);

wherein: the A cation is as defined herein; B⁺ is an M cation which is a monocation as defined herein; B³⁺ is an M cation which is a trication as defined herein; and [X] comprises one or more X anions which are halide anions, for instance two or more halide anions, preferably a single halide anion.

In yet another embodiment, the compound may be a layered double perovskite compound of formula (V):

[A]₄[B⁺][B³⁺][X]₈ (V);

wherein: [A], [B⁺], [B³⁺] and [X] are as defined above. In some embodiments, the layered double perovskite compound is a double perovskite compound of formula (Va):

A₄B⁺B³⁺[X]₈ (Va);

wherein: the A cation is as defined herein; B⁺ is an M cation which is a monocation as defined herein; B³⁺ is an M cation which is a trication as defined herein; and [X] comprises one or more X anions which are halide anions, for instance two or more halide anions, preferably a single halide anion or two kinds of halide anion.

In yet another embodiment, the compound may be a compound of formula (VI):

[A]₄[M][X]₆ (VI);

wherein: [A], [M] and [X] are as defined above (in relation to, for instance, compounds of formula (I) or (II)). However, preferably the compound is not a compound of formula (VI). Where the compound is a compound of formula (VI), the compound may preferably be a compound of formula (VIA)

[A^{I}A^{II}]₄[M][X]₆ (VIA);

that is, a compound wherein [A] comprises two types of A monoacation. In other preferred embodiments, the compound of formula (VI) may be a compound of formula (VIB):

[A]₄[M][X^{I}X^{II}]₆ (VIB);

that is, a compound of formula (VI) wherein [X] comprises two types of X anion. In yet other preferred embodiments, the compound of formula (VI) may be a compound of formula (VIC):

[A^{I}A^{II}]₄[M][X^{I}X^{II}]₆ (VIC);

that is, a compound of formula (VI) wherein [A] comprises two types of A monoacation and [X] comprises two types of X anion. In formulae (VIa), (VIb) and (VIc), each of: [A], [M] and [X] are as defined above (in relation to, for instance, compounds of formula (I) or (II)).

In another embodiment, a=1, b=1 and c=4. In that embodiment, the crystalline A/M/X material may in that case comprise a compound of formula (VII):

[A][M][X]₄ (VII)

wherein: [A] comprises one or more A cations which are monocations; [M] comprises one or more M cations which are metal or metalloid trications; and [X] comprises one or more X anions which are halide anions. The A monocations and M trications are as defined herein. An exemplary compound of formula (VII) is AgBiI₄.

It should be understood that the invention also encompasses processes for producing variants of the above-described structures (I), (II), (III), (IV), (V), (VI) and (VII) where one or more of the relevant a, b and c values are non-integer values.

Preferably, the compound of formula [A]ₐ[M]_{b}[X]_{c} is a compound of formula [A][M][X]₃, a compound of formula [A]₄[M][X]₆ or a compound of formula [A]₂[M][X]₆. For example, in preferred embodiments the compound of formula [A]ₐ[M]_{b}[X]_{c} is a compound of formula (I), for instance a compound of formula (IA), (IB), (IC), (ID), (IE), (IF), (IG), (IH), (IIIA), or a compound of formula (IIIB), (IIIC), (VIA), (VIB), or (VIC). Generally, the compound of formula [A]ₐ[M]_{b}[X]_{c} is a compound of formula (I), for instance a compound of formula (IA), (IB), (IC), (ID), (IE), (IF), (IG) or (IH).

In some embodiments, the compound of formula [A]ₐ[M]_{b}[X]_{c} is a compound wherein [A] comprises two or more different A cations. For examples, [A] may contain two types of cation or three types of A cation. In some embodiments, the compound of formula [A]ₐ[M]_{b}[X]_{c} is a compound wherein [X] comprises two or more different X anions. For example, [X] may contain two types of anion, e.g. halide anions. In some embodiments, the compound of formula [A]ₐ[M]_{b}[X]_{c} is a compound wherein [M] comprises two or more different M cations. For example, [X] may contain two types of anion, e.g. Sn²⁺ and Pb²⁺.

In one aspect of each of these embodiments, the compound of formula [A]ₐ[M]_{b}[X]_{c} is a compound wherein [A] comprises two or more different A cations and wherein [X] comprises two or more different X anions. For example, [A] may contain two types of A cation and [X] may contain two types of X anion (e.g. two types of halide anion). [A] may contain three types of A cation and [X] may contain two types of X anion (e.g. two types of halide anion).

In one aspect of each of these embodiments, the compound of formula [A]ₐ[M]_{b}[X]_{c} is a compound wherein [A] comprises two or more different A cations and wherein [M] comprises two or more different M cations. For example, [A] may contain two types of A cation and [M] may contain two types of M cation (e.g. Sn²⁺ and Pb²⁺).

In one aspect of each of these embodiments, the compound of formula [A]ₐ[M]_{b}[X]_{c} is a compound wherein [X] comprises two or more different X anions and wherein [M] comprises two or more different M cations. For example, [X] may contain two types of X anion (e.g. two types of halide anion) and [M] may contain two types of M cation (e.g. Sn²⁺ and Pb²⁺).

In one aspect of each of these embodiments, the compound of formula [A]ₐ[M]_{b}[X]_{c} is a compound wherein [A] comprises two or more different A cations and wherein [X] comprises two or more different X anions and wherein [M] comprises two or more different M cations. For example, [A] may contain two types of A cation, [X] may contain two types of X anion (e.g. two types of halide anion) and [M] may contain two types of M cation (e.g. Sn²⁺ and Pb²⁺).

### Process 1

The present invention also relates to a first process for producing an ionic liquid-modified film of a crystalline A/M/X material, wherein the crystalline A/M/X material comprises a compound of formula: [A]ₐ[M]_{b}[X]_{c}, wherein: [A] comprises one or more A cations; [M] comprises one or more M cations which are metal or metalloid cations; [X] comprises one or more X anions; wherein a is a number from 1 to 6; b is a number from 1 to 6; and c is a number from 1 to 18, the process comprising:
disposing a film-forming solution on a substrate, wherein the film-forming solution comprises a solvent, the one or more A cations as described herein, the one or more M cations as described herein, the one or more X anions as described herein, and an ionic liquid, wherein the ionic liquid comprises an organic cation and a counter-anion as described herein.

Typically, the ionic liquid is present in the film-forming solution in an amount of less than or equal to 50 mol %, less than or equal to 10 mol %, or less than or equal to 2.5 mol % with respect to the number of moles of the one or more M cations in the solution, preferably in an amount of from 0.01 to 5 mol %, or from 0.02 to 2.5 mol %, more preferably in an amount of from 0.05 to 2.0 mol %, and even more preferably in an amount of from 0.1 to 1.5 mol %, with respect to the number of moles of the one or more M cations in the solution. For instance, the ionic liquid may be present in the film-forming solution in an amount of less than 1.0 mol % with respect to the number of moles of the one or more M cations in the solution, preferably wherein the ionic liquid is present in an amount of from 0.1 mol % to 0.9 mol % with respect to the number of moles of the one or more M cations in the solution, more preferably from 0.2 mol % to 0.8 mol %, from 0.2 mol % to 0.7 mol % or less than 0.5 mol %, or for instance from 0.2 mol % to 0.5 mol %.

Suitable solvents are known to the skilled person. For instance, the solvent may comprise one or more organic solvents, for instance one or more organic polar solvents, for instance one or more organic polar aprotic solvents. For instance, the solvent may comprise dimethyl sulfoxide (DMSO), dimehtylformamide (DMF), N-methyl-2-pyrrolidinone (NMP), γ-butyrolactone (GBL), N,N-dimethylacetamide (DMAC), 2-methoxyethanol (2ME), acetonitrile (ACN) or mixtures thereof.

The process of the present invention may comprise a step of forming the film-forming solution by dissolving the ionic liquid, at least one M precursor, at least one A precursor and optionally at least one X precursor in the solvent.

The ionic liquid may be any ionic liquid comprising an organic cation and counter-anion as described herein.

As is discussed in more detail below, an M precursor is a compound comprising one or more M cations present in [M] as described herein. Where [M] (that is, [M] in the compound of formula [A]ₐ[M]_{b}[X]_{c}) comprises only one type of M cation, only one M precursor is necessary in the process of the invention.

As is discussed in more detail below, an A precursor is a compound comprising one or more A cations present in [A]. Where [A] (that is, [A] in the compound of formula [A]ₐ[M]_{b}[X]_{c}) comprises only one type of A cation, only one A precursor is necessary in the process of the invention.

As regards the source of X anions in the process of the invention, it may not be necessary to provide a separate X precursor in the process of the invention. This is because in some embodiments, the A precursor (or where the process involves a plurality of A precursors, at least one of them) and/or the M precursor (or where the process involves a plurality of M precursors, at least one of them) is a salt comprising one or more X anions, for instance a halide salt. In a preferred embodiment, the A precursor (or where present the plurality of A precursors) and the M precursor (or where present the plurality of M precursors) together comprise each of the X cations present in [X].

The M precursor typically comprises one or more counter-anions. Thus, typically, the film-forming solution comprises one or more counter-anions. Many such counter-anions are known to the skilled person. The one or more M cations and the one or more counter anions may both be from a first precursor compound, which is dissolved in the solvent as described herein to form the film-forming solution.

The counter-anion may be a halide anion, a thiocyanate anion (SCN⁻), a tetrafluoroborate anion (BF₄⁻) or an organic anion. Preferably, the counter-anion as described herein is a halide anion or an organic anion. The film-forming solution may comprise two or more counter-anions, e.g. two or more halide anions.

Typically, the counter-anion is an anion of formula RCOO⁻, ROCOO⁻, RSO₃⁻, ROP(O)(OH)O⁻ or RO⁻, wherein R is H, substituted or unsubstituted C₁₋₁₀ alkyl, substituted or unsubstituted C₂₋₁₀ alkenyl, substituted or unsubstituted C₂₋₁₀ alkynyl, substituted or unsubstituted C₃₋₁₀ cycloalkyl, substituted or unsubstituted C₃₋₁₀ heterocyclyl or substituted or unsubstituted aryl. For instance R may be H, substituted or unsubstituted C₁₋₁₀ alkyl, substituted or unsubstituted C₃₋₁₀ cycloalkyl or substituted or unsubstituted aryl. Typically R is H substituted or unsubstituted C₁₋₆ alkyl or substituted or unsubstituted aryl. For instance, R may be H, unsubstituted C₁₋₆ alkyl or unsubstituted aryl. Thus, R may be selected from H, methyl, ethyl, propyl, butyl, pentyl, hexyl, cyclopentyl, cyclohexyl and phenyl. Often, (one or more) counter-anions are selected from halide anions (e.g. F⁻, Cl⁻, Br⁻ and I⁻) and anions of formula RCOO⁻, wherein R is H or methyl.

Typically, the counter-anion is F⁻, Cl⁻, Br⁻, I⁻, formate or acetate. Preferably, the counter-anion is Cl⁻, Br⁻, I⁻ or F⁻. More preferably, the counter-anion is Cl⁻, Br⁻ or I⁻.

Typically, the M precursor is a compound of formula MY₂, MY₃, or MY₄, wherein M is a metal or metalloid cation as described herein, and Y is said counter-anion.

Thus, the M precursor may be a compound of formula MY₂, wherein M is Ca²⁺, Sr²⁺, Cd²⁺, Cu²⁺, Ni²⁺, Mn²⁺, Fe²⁺, Co²⁺, Pd²⁺, Ge²⁺, Sn²⁺, Pb²⁺, Yb²⁺ or Eu²⁺ and Y is F⁻, Cl⁻, Br⁻, I⁻, formate or acetate. Preferably M is Cu²⁺, Pb²⁺, Ge²⁺ or Sn²⁺ and Y is Cl⁻, Br⁻, I⁻, formate or acetate, preferably Cl⁻, Br⁻ or I⁻.

Typically, the M precursor is lead (II) acetate, lead (II) formate, lead (II) fluoride, lead (II) chloride, lead (II) bromide, lead (II) iodide, tin (II) acetate, tin (II) formate, tin (II) fluoride, tin (II) chloride, tin (II) bromide, tin (II) iodide, germanium (II) acetate, germanium (II) formate, germanium (II) fluoride, germanium (II) chloride, germanium (II) bromide or germanium (II) iodide. In some cases, the M precursor comprises lead (II) acetate. In some cases, the M precursor comprises lead (II) iodide.

The M precursor is typically a compound of formula MY₂. Preferably, the M precursor is a compound of formula SnI₂, SnBr₂, SnCl₂, PbI₂, PbBr₂ or PbCl₂.

The M precursor may be a compound of formula MY₃, wherein M is Bi³⁺ or Sb³⁺ and Y is F⁻, Cl⁻, Br⁻, I⁻, SCN⁻, BF₄⁻, formate or acetate. Preferably M is Bi³⁺ and Y is Cl⁻, Br⁻ or I⁻. In that case, the A/M/X material typically comprises a bismuth or antimony halogenometallate.

The M precursor may be a compound of formula MY₄, wherein M is Pd⁴⁺, W⁴⁺, Re⁴⁺, Os⁴⁺, Ir⁴⁺, Pt⁴⁺, Sn⁴⁺, Pb⁴⁺, Ge⁴⁺ or Te⁴⁺ and Y is F⁻, Cl⁻, Br⁻, I⁻, SCN⁻, BF₄⁻, formate or acetate. Preferably M is Sn⁴⁺, Pb⁴⁺ or Ge⁴⁺ and Cl⁻, Br⁻ or I⁻. In that case, the A/M/X material typically comprises a hexahalometallate.

Typically, the total concentration of [M] cations in the film-forming solution is between 0.01 and 5 M, for instance between 0.1 and 2.5 M, 0.25 and 2.0 M, preferably between 0.5 and 1.5 M.

The A cations and X anions may both be from the same precursor compound or compounds, which are dissolved in the solvent as described herein to form the film-forming solution. Preferably, the A/X precursor compound is a compound of formula [A][X] wherein: [A] comprises the one or more A cations as described herein; and [X] comprises the one or more X anions as described herein. The A/X precursor compound is typically a compound of formula AX, wherein X is a halide anion and the A cation is as defined herein. When more than one A cation or more than one X anion is present in the compound of formula [A]ₐ[M]_{b}[X]_{c}, more than one compound of formula AX may be dissolved in the film-forming solution.

The A/X precursor compound (or compounds) may, for example, be selected from CH₃NH₃C₁, CH₃NH₃Br, CH₃NH₃I, CH₃CH₂NH₃C₁, CH₃CH₂NH₃Br, CH₃CH₂NH₃I, CH₃CH₂CH₂NH₃C₁, CH₃CH₂CH₂NH₃Br, CH₃CH₂CH₂NH₃I, N(CH₃)₄C₁, N(CH₃)₄Br, N(CH₃)₄I, (H₂N—C(H)═NH₂)Cl, (H₂N—C(H)═NH₂)Br, (H₂N—C(H)═NH₂)I, (H₂N—C(CH₃)═NH₂)C₁, (H₂N—C(CH₃)═NH₂)Br, (H₂N—C(CH₃)═NH₂)I, (H₂N—C(NH₂)═NH₂)C₁, (H₂N—C(NH₂)═NH₂)Br, (H₂N—C(NH₂)═NH₂)I, CsCl, CsBr, CsI, RbCl, RbBr and RbI.

Typically, the total concentration of [A] cations in the film-forming solution is between 0.01 and 5 M, for instance between 0.1 and 2.5 M, 0.25 and 2.0 M, preferably between 0.75 and 1.5 M.

Typically, the total concentration of X anions depends on the total concentration of A and/or M cations. For instance, when an A/X precursor compound and/or an M precursor compound comprising one or more X anions are used, the total concentration of X anions will depend on the total amount of A/X precursor compound and/or an M precursor compound present, as described above.

Typically, the film-forming solution is disposed on the substrate by solution phase deposition, for instance gravure coating, slot dye coating, screen printing, ink jet printing, doctor blade coating, spray coating, roll-to-roll (R2R) processing, or spin-coating. Typically, disposing the film-forming composition on the substrate comprises a step of spin-coating the film-forming solution on the substrate.

Typically, the spin coating is performed at a speed of at least 1000 RPM, for instance at least 2000 RPM, at least 3000 RPM or at least 4000 RPM, for example between 1000 and 10000 RPM, between 2000 and 8000 RPM, between 2500 and 7500 RPM, preferably about 5000 RPM. Typically, the spin coating is performed for a time of at least one second, at least 5 seconds or at least 10 seconds, for example from 1 second to 1 minute, from 10 seconds to 50 seconds, preferably about 20 to 40 seconds.

The process may further comprise using an anti-solvent to facilitate precipitation of the crystalline A/M/X material. Typically, the antisolvent is dropped onto the film-forming solution either during disposing the film-forming solution on the substrate or after the film-forming solution has been disposed on the substrate. For instance, the antisolvent may be dropped onto the film-forming solution during the spin-coating. Typically, the antisolvent is selected from toluene, chlorobenzene, chloroform, dichlorobenzene, isopropyl alcohol, tetrahydrofuran, benzene, xylene, anisole and mixtures thereof.

Typically, the process further comprises removing the solvent, and optionally the anti-solvent, to form the layer comprising the crystalline A/M/X material. Removing the solvent (and optionally the anti-solvent) may comprise heating the solvent, or allowing the solvent to evaporate.

The solvent (and optionally the anti-solvent) is usually removed by heating (annealing) the film-forming solution treated substrate. For instance, the film-forming solution treated substrate may be heated to a temperature of from 30° C. to 400° C., for instance from 50° C. to 200° C. Preferably, the film-forming solution treated is heated to a temperature of from 50° C. to 200° C. for a time of from 5 to 200 minutes, preferably from 10 to 100 minutes.

### Process 2

The present invention also relates to a second process for producing an ionic liquid-modified film of a crystalline A/M/X material, which crystalline A/M/X material comprises a compound of formula: [A]ₐ[M]_{b}[X]_{c}, wherein: [A] comprises one or more A cations; [M] comprises one or more M cations which are metal or metalloid cations; [X] comprises one or more X anions; wherein a is a number from 1 to 6; b is a number from 1 to 6; and c is a number from 1 to 18, the process comprising:
a) disposing a first solution on a substrate wherein the first solution comprises a solvent and one or more M cations, and optionally removing the solvent, to produce a treated substrate;
b) contacting the treated substrate with a second solution comprising a solvent and one or more A cations or with vapour comprising one or more A cations,

wherein: one or more X anions are present in one or both of: (i) the first solution employed in step (a), and (ii) the second solution or vapour employed in step (b); and the first solution employed in step (a) further comprises an ionic liquid or step (b) further comprises contacting the treated substrate with an ionic liquid, wherein the ionic liquid comprises an organic cation and a counter-anion.

The crystalline A/M/X material may be any crystalline A/M/X material described herein.

The first solution employed in step (a) may further comprise the ionic liquid. For instance, the first solution may comprise a solvent, one or more M cations, optionally one or more X anions and the ionic liquid.

Alternatively, step (b) may further comprise contacting the treated substrate with the ionic liquid. For instance, step (b) may comprise contacting the treated substrate with a second solution wherein the second solution further comprises the ionic liquid. The second solution may therefore comprise a solvent, one or more A cations, optionally one or more X anions and the ionic liquid.

In one embodiment, the process comprises:
a) disposing a first solution on a substrate wherein the first solution comprises a solvent, one or more M cations, one or more X anions and the ionic liquid, and optionally removing the solvent, to produce a treated substrate;
b) contacting the treated substrate with a second solution comprising a solvent, one or more A cations and one or more X anions.

In another embodiment, the process comprises:
a) disposing a first solution on a substrate wherein the first solution comprises a solvent, one or more M cations and one or more X anions, and optionally removing the solvent, to produce a treated substrate;
b) contacting the treated substrate with a second solution comprising a solvent, one or more A cations, one or more X anions and the ionic liquid.

The solvent in steps (a) and (b) may be any solvent as described above for the first process of the invention.

The process may further comprise a step of forming the first solution by dissolving at least one M precursor as described herein, optionally one or more X precursors as described herein and optionally the ionic liquid in a solvent.

When step (b) comprises contacting the treating substrate with a second solution comprising a solvent and one or more A cations, the process may further comprise a step of forming the second solution by dissolving at least one A precursor as described herein, optionally one or more X precursors as described herein and optionally the ionic liquid in a solvent.

As regards the source of X anions in the process of the invention, it may not be necessary to provide a separate X precursor in the process of the invention. This is because in some embodiments, the A precursor (or where the process involves a plurality of A precursors, at least one of them) and/or the M precursor (or where the process involves a plurality of M precursors, at least one of them) is a salt comprising one or more X anions, for instance a halide salt. In a preferred embodiment, the A precursor (or where present the plurality of A precursors) and the M precursor (or where present the plurality of M precursors) together comprise each of the X cations present in [X].

The first and second solutions may be disposed on the substrate by any of the methods described herein. Typically, the first and second solutions are disposed on the substrate by solution phase deposition, for instance gravure coating, slot dye coating, screen printing, ink jet printing, doctor blade coating, spray coating, roll-to-roll (R2R) processing, or spin-coating. Typically, the process comprises a step of disposing the first solution on the substrate by spin-coating and disposing the second solution on the substrate by spin-coating.

An anti-solvent may be used as described above when disposing either or both of the first and second solutions on the substrate.

Typically, the spin coating is performed at a speed of at least 1000 RPM, for instance at least 2000 RPM, at least 3000 RPM or at least 4000 RPM, for example between 1000 and 10000 RPM, between 2000 and 8000 RPM, between 2500 and 7500 RPM, preferably about 5000 RPM. Typically, the spin coating is performed for a time of at least one second, at least 5 seconds or at least 10 seconds, for example from 1 second to 1 minute, from 10 seconds to 50 seconds, preferably about 20 to 40 seconds.

Step (b) may comprise contacting the treated substrate with vapour comprising one or more A cations. For instance, step (b) may comprise contacting the treated substrate with said vapour comprising one or more A cations and with vapour comprising the ionic liquid.

Thus, the process may comprise:
a) disposing a first solution on a substrate wherein the first solution comprises a solvent, one or more M cations, one or more X anions and the ionic liquid, and optionally removing the solvent, to produce a treated substrate;
b) contacting the treated substrate with vapour comprising one or more A cations and one or more X anions.

Alternatively, the process may comprise:
a) disposing a first solution on a substrate wherein the first solution comprises a solvent, one or more M cations and one or more X anions, and optionally removing the solvent, to produce a treated substrate;
b) contacting the treated substrate with vapour comprising one or more A cations, one or more X anions and the ionic liquid.

Typically, step (b) comprises:
b1) vapourising a composition, or compositions, which comprise the one or more A cations and the ionic liquid, and
b2) depositing the resulting vapour on the treated substrate.

For instance, step (b1) may comprise vapourising a composition, or compositions, which comprise the one or more A cations, one or more X anions and the ionic liquid. Said composition or compositions may comprise, consist essentially of or consist of the A cation precursor, optionally one or more X anion precursors and the ionic liquid. Hence, the process may comprise a step of preparing a composition or compositions by mixing one or more A cation precursors, the ionic liquid and optionally one or more X anion precursors.

Removing the solvent may comprise heating the solvent, or allowing the solvent to evaporate. Thus, typically, the process comprises annealing the substrate.

The solvent is usually removed by heating (annealing) the first solution-treated substrate. For instance, the film-forming solution treated substrate may be heated to a temperature of from 30° C. to 400° C., for instance from 50° C. to 200° C. Preferably, the film-forming solution treated is heated to a temperature of from 50° C. to 200° C. for a time of from 5 to 200 minutes, preferably from 10 to 100 minutes.

An additional step of removing the solvent may also be performed after step b) as described above when the treated substrate is contacted with a second solution comprising a solvent, one or more A cations, optionally one or more X anions and optionally the ionic liquid.

In the first and second processes described above, the substrate may comprise a first charge-transporting material, as described herein. Typically, the first charge-transporting material is disposed on a first electrode, as described herein.

Thus, the substrate may comprise the following layers in the following order:
First electrode (typically comprises a transparent conducting oxide);
Layer of a charge transporting material (typically an p-type material as described herein, but this may alternatively be a n-type material);

Often, the first charge-transporting material is a hole-transporting (p-type) material as described herein. Typically, the first electrode is a transparent electrode, for instance an electrode comprising a transparent conducing oxide as described herein.

### Process 3

The invention further relates to a process for producing an ionic liquid-modified film of a crystalline A/M/X material, wherein the crystalline A/M/X material comprises a compound of formula: [A]ₐ[M]_{b}[X]_{c} wherein: [A] comprises one or more A cations; [M] comprises one or more M cations which are metal or metalloid cations; [X] comprises one or more X anions; a is a number from 1 to 6; b is a number from 1 to 6; and c is a number from 1 to 18; which process comprises treating a film of the crystalline A/M/X material with an ionic liquid which is a salt comprising an organic cation and a counter anion.

The step of treating the film of the crystalline A/M/X material with the ionic liquid may comprise disposing the ionic liquid on the film of the crystalline A/M/X material using any technique known to the skilled person or any technique as described herein. For instance, the ionic liquid may be disposed on the film of the crystalline A/M/X material by vapour deposition or solution deposition, for instance by gravure coating, slot dye coating, screen printing, ink jet printing, doctor blade coating, spray coating, roll-to-roll (R2R) processing, or spin-coating. Typically the ionic liquid is disposed on the film of the crystalline A/M/X material by spin coating.

The ionic liquid may be any ionic liquid as described herein, i.e. may be an ionic liquid comprising any organic cation and counter-anion as described herein. The crystalline A/M/X material may be any crystalline A/M/X material as described herein.

Typically, the film of the crystalline A/M/X material is disposed on a substrate. The substrate may be any substrate as described herein.

The process may further comprise a step of depositing the crystalline A/M/X material on a substrate. For instance, the crystalline A/M/X material may be deposited by vapour deposition, or by any of the solution-based techniques as described herein. In one embodiment, the process comprises depositing the crystalline A/M/X material by vapour deposition, then depositing the ionic liquid on the film of the crystalline A/M/X material by vapour deposition or solution deposition, as described herein. In another embodiment, the process comprises depositing the crystalline A/M/X material by any of the solution-based techniques as described herein, then depositing the ionic liquid on the film of the crystalline A/M/X material by vapour deposition or solution deposition, as described herein.

### Process for Producing an Optoelectronic Device

The present invention also relates process for producing an optoelectronic device, which process comprises producing, on a substrate, an ionic liquid-modified film of a crystalline A/M/X material, by any process as described herein. The ionic liquid may be any ionic liquid as described herein, i.e. may be an ionic liquid comprising any organic cation and counter-anion as described herein. The crystalline A/M/X material may be any crystalline A/M/X material as described herein. The substrate may be any substrate as described herein.

Typically, the substrate comprises a first charge-transporting material disposed on a first electrode which is a transparent electrode. Typically, the first electrode comprises a transparent conducting oxide, for instance fluorine doped tin oxide (FTO), aluminium doped zinc oxide (AZO) or indium doped tin oxide (ITO). Typically, the first charge-transporting material is a hole transporting (p-type) material as described herein. Preferably, the first charge-transporting material comprises nickel oxide, for instance the first charge-transporting material may be a compact layer of nickel oxide.

The process may comprise a step of forming the substrate by disposing the first charge-transporting material on the first electrode. Typically, the first charge-transporting material is disposed on the first electrode by spin coating a solution comprising a solvent and a first charge-transporting material or first-charge transporting material precursor onto the first electrode. The process of forming the substrate may comprise a step of removing the solvent using any method as described herein, to produce a treated substrate. Typically, the solvent is then removed by heating the solution treated first electrode. For instance, the solution treated first electrode may be heated to a temperature of from 30° C. to 400° C., for instance from 50° C. to 200° C. Preferably, the solution treated first electrode is heated to a temperature of from 50° C. to 200° C. for a time of from 5 to 200 minutes, preferably from 10 to 100 minutes.

Typically, the first charge transporting material is nickel oxide, therefore the first charge-transporting material is disposed on the first electrode by spin-coating a solution comprising a nickel oxide precursor onto the first electrode. The substrate may optionally be sintered.

Sintering typically involves a step of heating the substrate to an elevated temperature, for instance a temperature of at least 100° C., at least 200° C., at least 300° C. or at least 400° C. for a period of from 10 to 100 minutes, typically from 20 to 60 minutes.

Alternatively the nickel oxide layer can be deposited via vacuum deposition techniques such as sputter coating.

Typically, the layer comprising a crystalline A/M/X material is disposed directly on the layer of the first charge-transporting material (preferably a compact layer of nickel oxide).

The process may further comprise: disposing a second charge-transporting material on the ionic liquid-modified film of a crystalline A/M/X material, and disposing a second electrode on the second charge-transporting material.

Typically the first charge transporting material is a hole-transporting (p-type) material as described herein and the second charge transporting material is an electron-transporting (n-type) material as described herein. Alternatively, the first charge transporting material may be an electron-transporting (n-type) material as described herein and the second charge transporting material is a hole-transporting (p-type) material as described herein. For instance the first charge-transporting material may comprise nickel oxide, and the second charge transporting material may be an organic electron-transporting (n-type) material, preferably PCBM.

Typically, the first electrode comprises a transparent conducting oxide and the second electrode comprises an elemental metal.

Typically, the second electrode comprises, or consists essentially of, a metal for instance an elemental metal. Examples of metals which the second electrode material may comprise, or consist essentially of, include silver, gold, copper, aluminium, platinum, palladium, or tungsten. The second electrode may be disposed by vacuum evaporation. The thickness of the layer of a second electrode material is typically from 1 to 250 nm, preferably from 5 nm to 100 nm.

The optoelectronic device produced by the process may comprise any additional layers, as described herein, for instance additional electron-transporting (n-type) layers or interface modifying layers.

The present invention also relates to an ionic liquid-modified film of a crystalline A/M/X material which is obtainable by any process as described herein. The present invention also relates to an ionic liquid-modified film of a crystalline A/M/X material which is obtained by any process as described herein.

The present invention also relates to optoelectronic device which
(a) comprises an ionic liquid-modified film of a crystalline A/M/X material as described herein; or
(b) is obtainable by a process as described herein.

### EXAMPLES

The advantages of the invention will hereafter be described with reference to some specific examples.

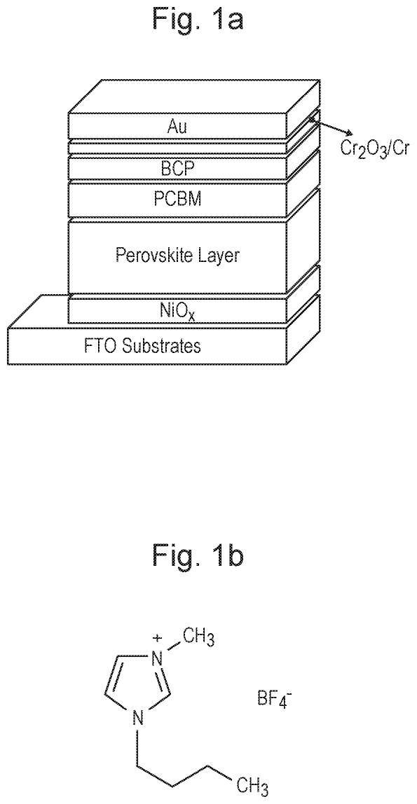

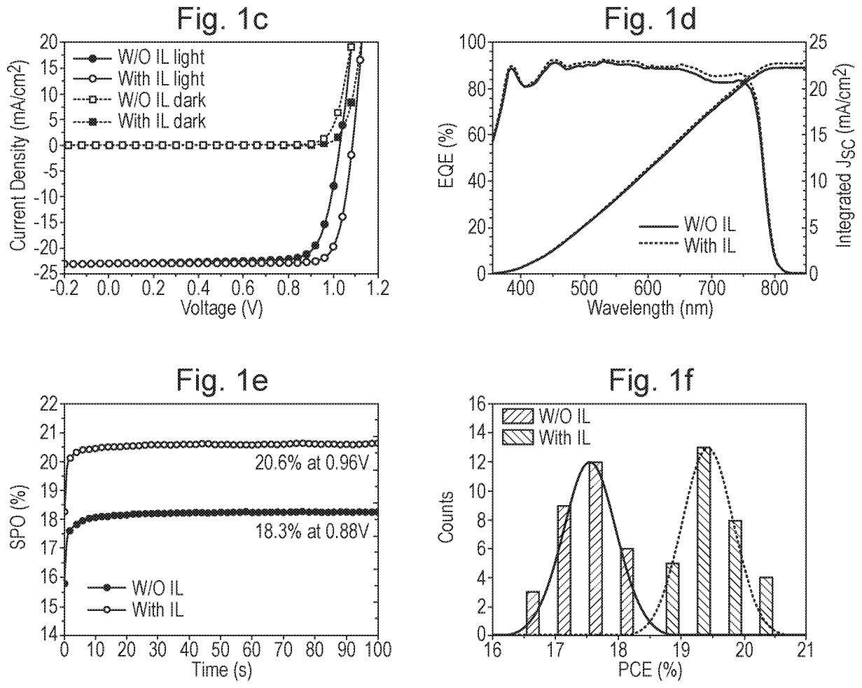

Ionic liquids (ILs), salts which are molten at room temperature, have been previously incorporated into negative-intrinsic-positive (n-i-p) perovskite solar cells and shown to deliver improvements to performance (Yang, D. et al. Surface optimization to eliminate hysteresis for record efficiency planar perovskite solar cells. Energy Environ. Sci. 9, 3071-3078, (2016)). The mechanism driving the improvements has been interpreted to be due to an advantageous shift in the energy level alignment at the n-type charge extraction layer, perovskite interface. Here we incorporate an “ionic liquid doped” triple cation perovskite absorber of (FA_{0.83}MA_{0.17})_{0.95}Cs_{0.05}Pb(I_{0.9}Br_{0.1})₃⁷, where FA is formamidinium and MA is methylammonium, into p-i-n planar perovskite solar cells, employing NiO and [6,6]-phenyl-C₆₁-butyric acid methyl ester (PCBM) as the p- and n-type charge extraction layers, respectively (FIG. 1a). We focus our investigation on the impact of adding ILs into the perovskite active layer, starting with 1-butyl-3-methylimidazolium tetrafluoroborate (BMIMBF₄), the chemical structure of which we show in FIG. 1b.

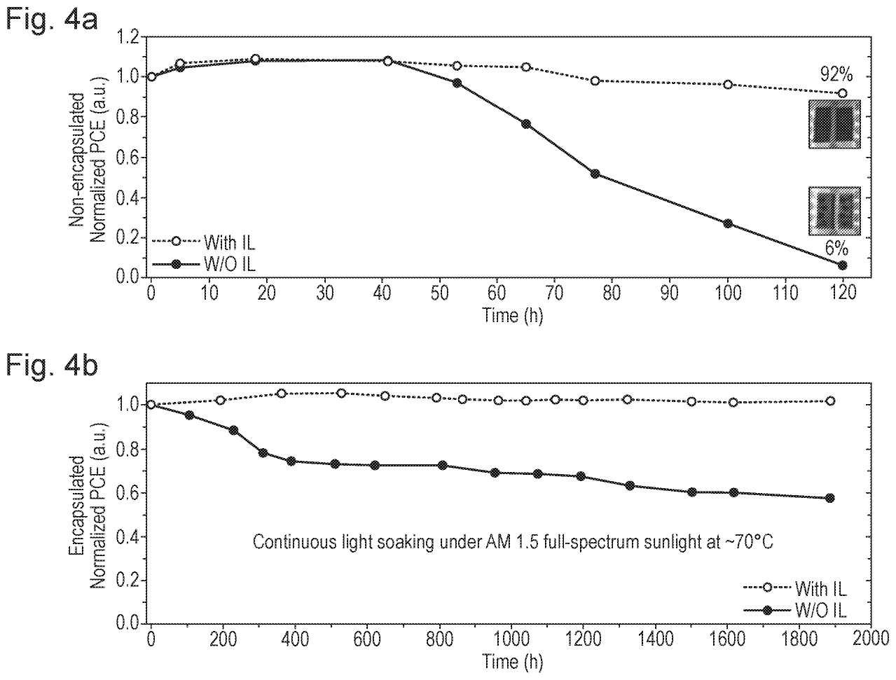

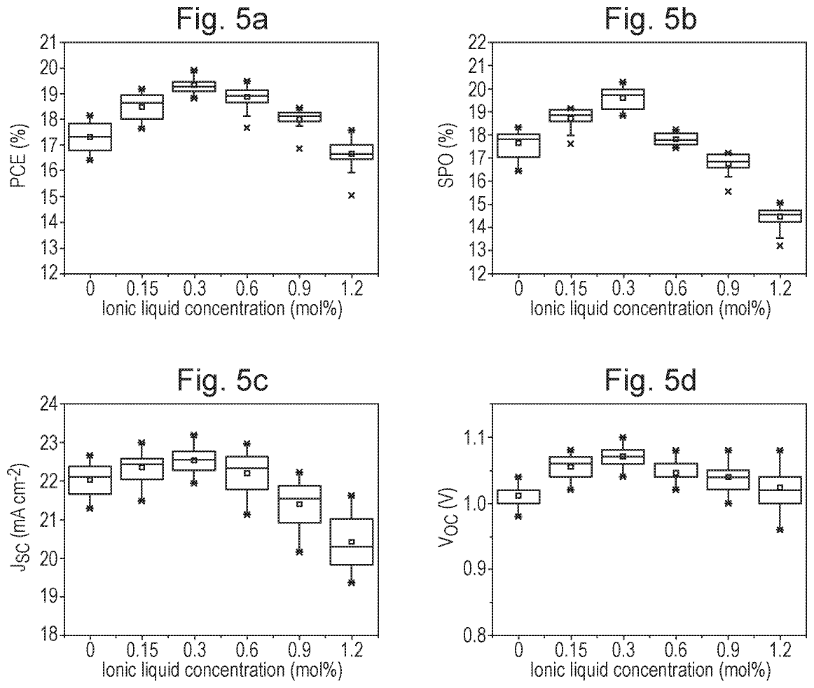

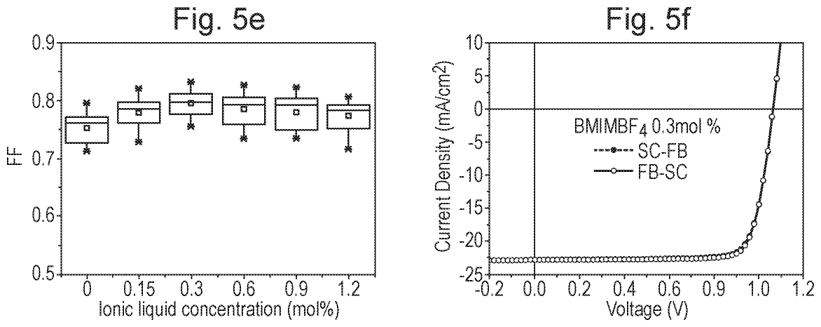

We show the impact of incrementally “doping” the perovskite with BMIMBF₄ upon the device performance in FIG. 5. We present the current-voltage (J-V) curves and the device performance parameters of the perovskite solar cells with and without the IL in FIG. 1c and Table 1.

TABLE 1
Device parameters of solar cells based on
(FA_{0.83}MA_{0.17})_{0.95}Cs_{0.05}Pb(I_{0.9}Br_{0.1})₃ perovskite without
IL and with the BMIMBF₄ IL at an optimized concentration of 0.3 mol %.

| | | | | | |
|---|---|---|---|---|---|
| | J_{SC} | V_{OC} | | PCE | SPO |
| Device | (mA cm⁻²) | (V) | FF | (%) | (%) |

W/O IL

| | | | | | |
|---|---|---|---|---|---|
| Average | 22.1 ± 0.4 | 1.01 ± 0.02 | 0.75 ± 0.03 | 17.5 ± 0.5 | 17.6 ± 0.5 |
| Champion | 22.4 | 1.02 | 0.79 | 18.1 | 18.3 |

With IL

| | | | | | |
|---|---|---|---|---|---|
| Average | 22.5 ± 0.4 | 1.06 ± 0.02 | 0.79 ± 0.03 | 19.5 ± 0.5 | 19.7 ± 0.4 |
| Champion | 22.7 | 1.08 | 0.83 | 20.3 | 20.6 |

The average device parameters with standard deviation are obtained based on 30 cells for each condition.

We observe that with the addition of a small amount of IL (0.15 to 0.9 mol % with respect to the Pb), the devices exhibit enhanced efficiency. For the champion device with 0.3 mol % IL, we measure an open-circuit voltage (V_{OC}) of 1.08 V, a short-circuit current (J_{SC}) of 22.7 mA cm⁻² and a very high fill factor (FF) of 0.83, yielding a PCE of 20.3%. For the control device, we measure a lower overall PCE of 18.1%, due to a lower V_{OC} of 1.02 V and FF of 0.79. We verify that J_{SC}s derived from the J-V curves are well matched with the external quantum efficiency (EQE) measurements, integrated over the solar spectrum, which we present in FIG. 1d. Our devices exhibit negligible hysteresis from the J-V curves (FIG. 5f), but importantly for perovskite solar cells we also show the stabilized, or steady-state power output (SPO), by measuring the current at a fixed maximum power point voltage over 100s²². We determine SPOs of 18.3% and 20.6% for the device without and with IL, respectively (FIG. 1e), and provide histograms of the PCEs of 30 devices from three different batches in FIG. 1f, which show excellent device reproducibility.

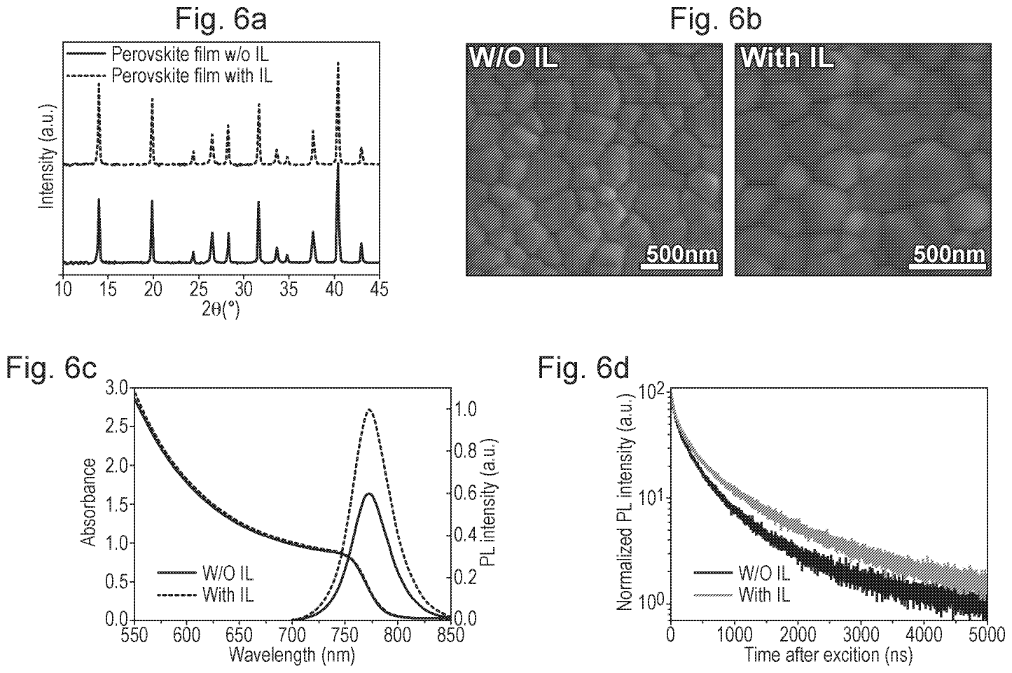

In order to understand why the addition of BMIMBF₄ has improved the device performance, we perform a range of characterizations. We first observe that with the addition of BMIMBF₄, the X-ray diffraction (XRD) peak positions remain unaltered, consistent with neither [BMIM]⁺ nor [BF₄]⁻ incorporating into and perturbing the ABX₃ perovskite crystal lattice (FIG. 6a). However, we do notice a slight increased intensity of the main (100) diffraction, which suggests enhanced texturing or crystallinity of the perovskite film with IL, which is also consistent with our observation of slightly enlarged grains in the scanning electron microcopy (SEM) images, which we show in FIG. 6b. We do not observe any impact upon the absorption spectra with the addition of IL. We do however observe improved photoluminescence (PL) intensity and increased PL lifetime for the IL containing perovskite film, which we show in FIG. 6d, which is consistent with reduced defect density within the perovskite film with the incorporation of IL.

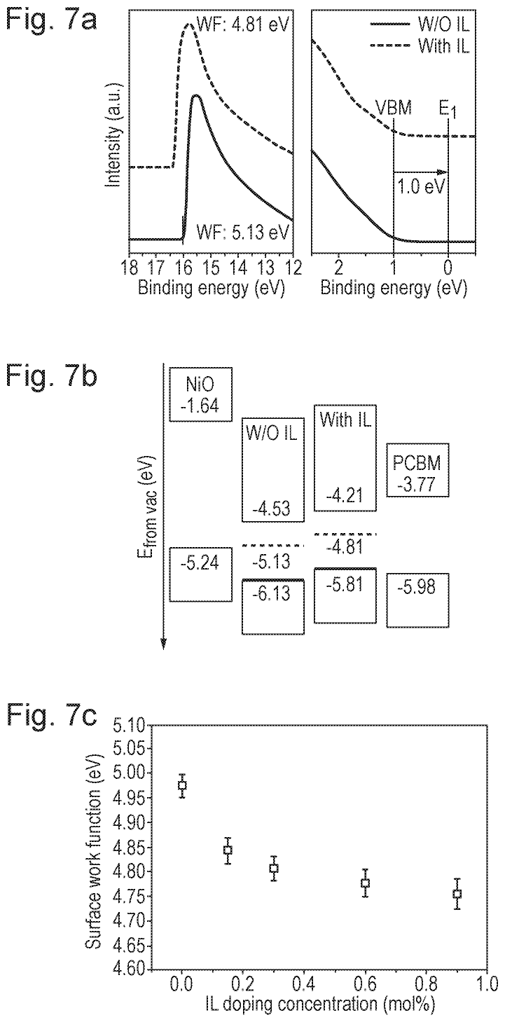

We perform ultraviolet photoelectron spectroscopy (UPS) and X-ray photoelectron spectroscopy (XPS) to investigate any changes to the surface electronic properties of the perovskite films. From the UPS spectra, we observe a decrease of 320 meV in the work-function (WF) of perovskite film from 5.13 to 4.81 eV with respect to vacuum, after the addition of IL (FIG. 7a). We do not observe a change in the relative Fermi level position with respect to the valance band offset. Therefore, the reduced work function indicates that the energy levels of the perovskite absorber have moved closer to vacuum, when processed with the IL. We further preform Kelvin Probe measurements, which also reveal a consistent trend of a decreasing WF with increased IL concentration (FIG. 7c). The change on the energy level structure could result from a shift in the relative energy alignment of the buried heterojunction between the perovskite absorber and the NiO hole-extraction layer, or a shift in energy level alignment at the topmost perovskite surface, which in a complete device will subsequently contact the PCBM electron acceptor. These shifts could either drive a change in V_{OC}, if a voltage loss exists due to energetic misalignment at these heterojunctions, or an increase or reduction of a charge extraction barrier at a perovskite-to-charge-extraction-layer interface. In light of the increase in both V_{OC} and FF, which we observe in the solar cells, this energetic shift is most likely leading to an improved energetic alignment, with smaller voltage losses, at one or both of the heterojunctions (n-type to perovskite and p-type to perovskite) and improved charge extraction.

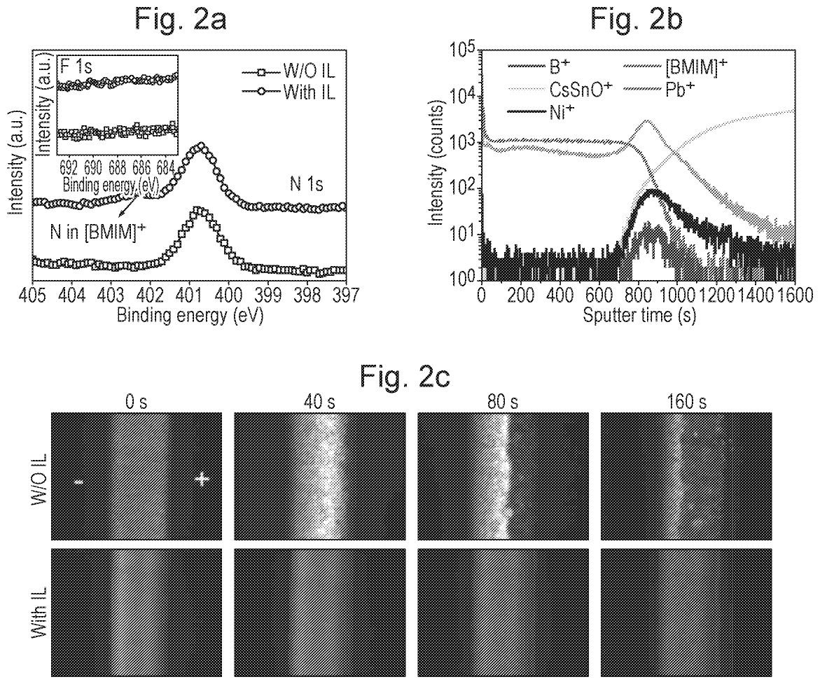

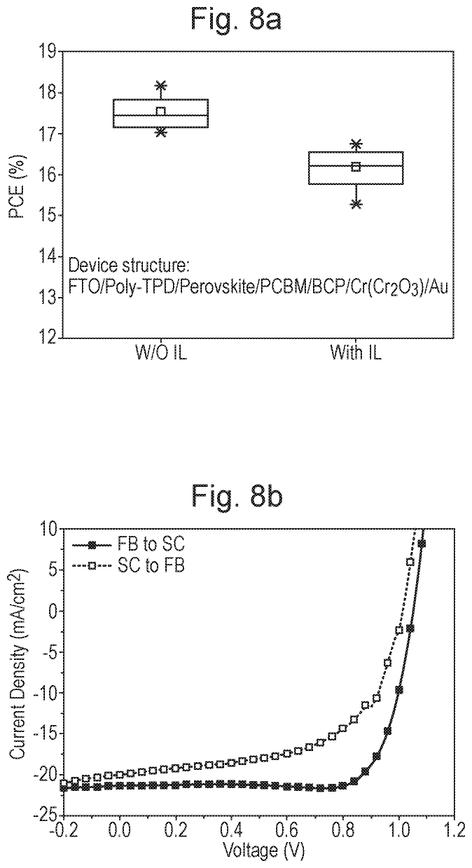

From XPS spectra of the IL doped perovskite film which we show in FIG. 2a, we detect the nitrogen signal of [BMIM]⁺ but no elemental signal of [BF₄]⁻ at the surface, which is consistent with the energetic shifts which we observe being due to the organic cation modifying the surface dipole of the perovskite film. We perform time-of-flight secondary ion mass spectrometry (ToF-SIMS) to probe the chemical composition throughout the film, and present the results in FIG. 2b. We discover that, in the as-crystallised perovskite film with the IL, the [BF₄]⁻ ions are mainly located at the buried interface, while the [BMIM]⁺ ions are existing throughout the bulk perovskite film. It is therefore likely that there is an accumulation of ion pairs of [BMIM]⁺ and [BF₄]⁻, at the perovskite-NiO interface. We note that if we substitute the NiO for an organic hole-conductor, poly[N,N′-bis(4-butylphenyl)-N,N′-bis(phenyl)benzidine](poly-TPD), we measure decreased efficiency and the emergence of hysteresis from devices with IL (FIG. 8). This indicates that the mechanism driving the V_{OC}, FF and efficiency enhancements in the NiO-based cells which we present here, is likely related to the improved interaction between perovskite and NiO at the interface (Nie, W. et al. Critical Role of Interface and Crystallinity on the Performance and Photostability of Perovskite Solar Cell on Nickel Oxide. Adv. Mater. 30, 1703879, (2018)), facilitated by processing with the IL.

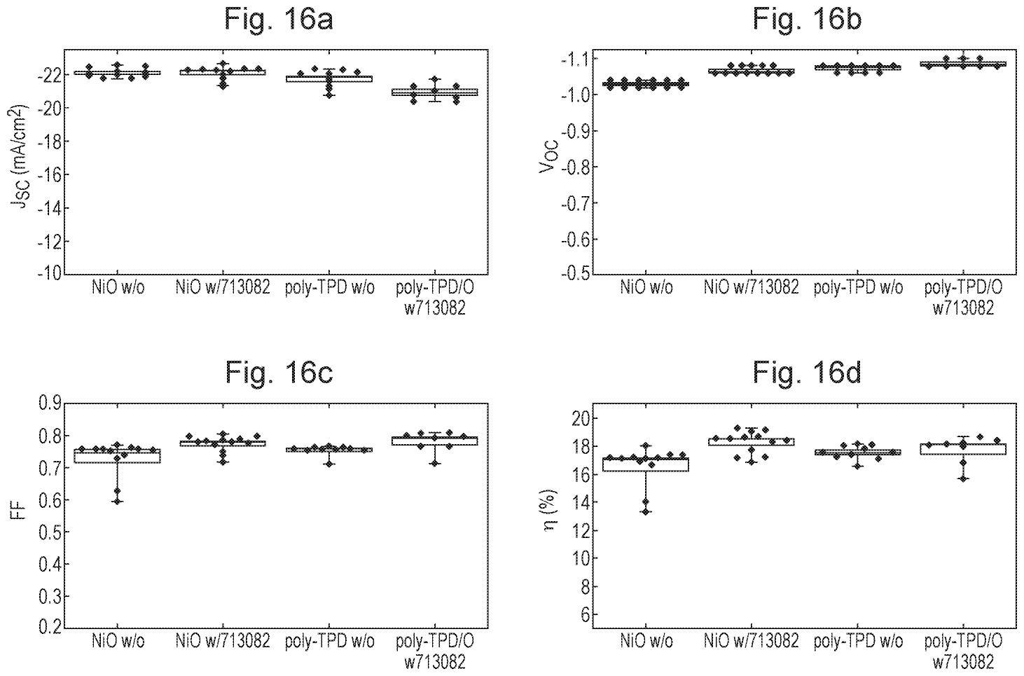

Performance in devices with a polyTPD charge transporting layer can be improved by employing ionic liquids. FIG. 16 shows device parameters of (FA_{0.83}MA_{0.17})_{0.95}Cs_{0.05}Pb(I_{0.9}Br_{0.1})₃ perovskite solar cells fabricated on NiO and polyTPD p-type layers with or without the 1-butyl-1-methylpiperidinium tetrafluoroborate ionic liquid (referred to by its Sigma Aldrich number code 713082) added to the perovskite layer. For this ionic liquid enhancements in short-circuit current (J_{SC}), fill factor (FF), open-circuit voltage (V_{OC}) and power conversion efficiency may be achieved with either a NiO layer or a polyTPD layer.

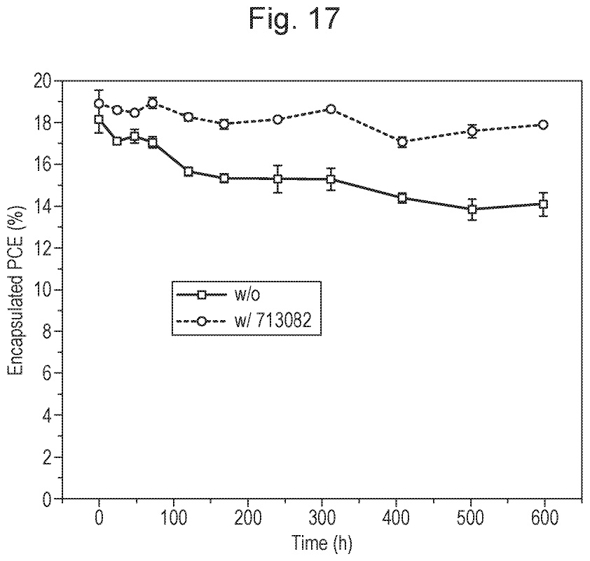

FIG. 17 shows the power conversion efficiency of (FA_{0.83}MA_{0.17})_{0.95}Cs_{0.05}Pb(I_{0.9}Br_{0.1})₃ perovskite solar cells encapsulated with a glass cover slip and thermally stressed at 85° C. in a nitrogen atmosphere, measured over time and fabricated on polyTPD p-type layers with or without the 1-butyl-1-methylpiperidinium tetrafluoroborate ionic liquid (referred to by its Sigma Aldrich number code 713082) added to the perovskite layer. FIG. 17 shows that the presence of 1-butyl-1-methylpiperidinium tetrafluoroborate improves the stability of the device, allowing higher PCEs to be maintained for longer periods.

We study “in-plane” electronic devices to determine if there are any field- or ion-induced changes in the IL containing perovskite films (Leijtens, T. et al. Mapping electric field-induced switchable poling and structural degradation in hybrid lead halide perovskite thin films. Adv. Energy Mater. 5, 1500962, (2015); Xiao, Z. et al. Giant switchable photovoltaic effect in organometal trihalide perovskite devices. Nat. Mater. 14, 193-198, (2014)). We microscopically characterize the PL of perovskite films in-between two in-plane electrodes, with a constant electrical bias applied between the electrodes (Li, C. et al. Real-time observation of iodide ion migration in methylammonium lead halide perovskites. Small 13, 1701711, (2017)). In the series of images of PL of the films as a function of time, which we show in FIG. 2c, we observe clear luminescence quenching from the positive toward the negative electrode for the control films. Our interpretation is that the PL is suppressed by the migration of ions, where some regions of the film accumulate a high density of defects and/or the stoichiometry of the absorber layer deviates considerably at different positions across the channel between the electrodes (Leijtens, T. et al. Mapping electric field-induced switchable poling and structural degradation in hybrid lead halide perovskite thin films. Adv. Energy Mater. 5, 1500962, (2015)). We observe a stark contrast for the perovskite film processed with the IL: the PL is close to unchanging throughout the entire measurement time. Unexpectedly, our observations indicate significantly suppression of ion migration, by doping the perovskite films with IL.

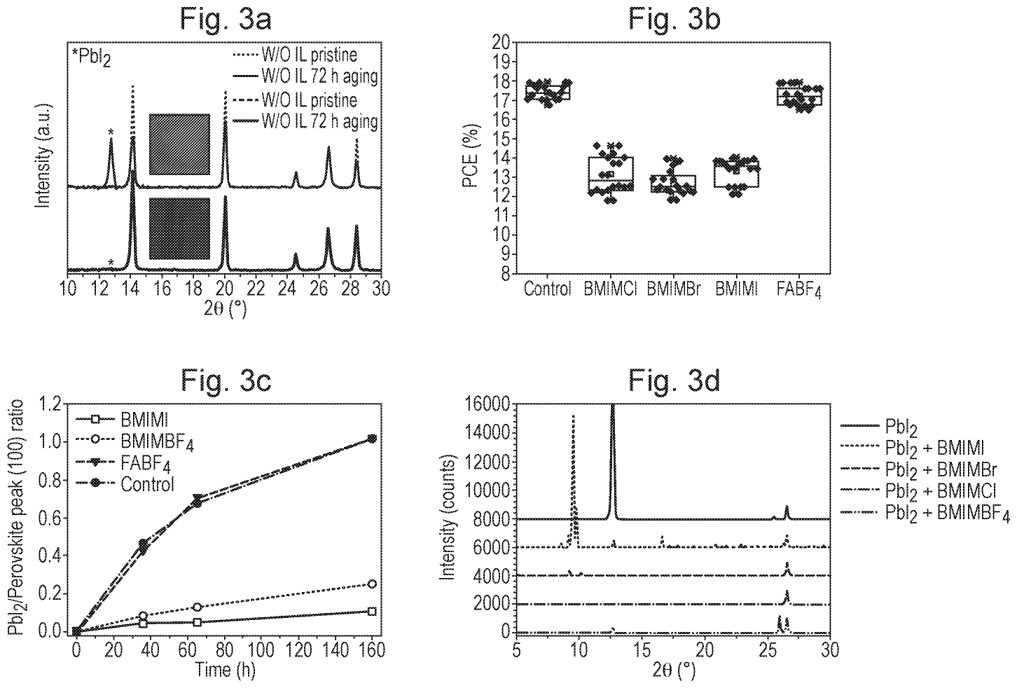

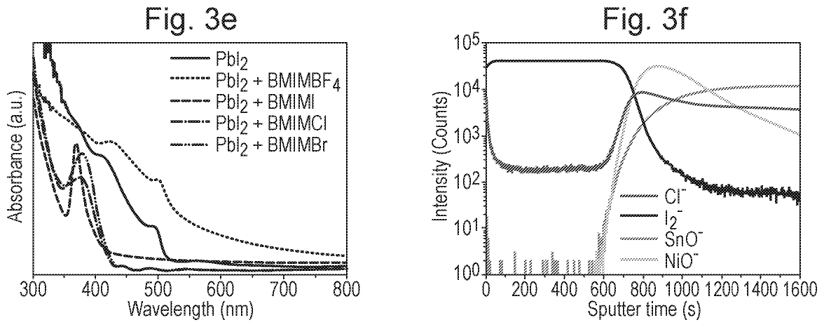

Since we have observed evidence for the suppression of ionic motion, we now investigate the stability of the perovskite to light exposure at elevated temperatures. We interrogate the stability of bare perovskite films exposed to simulated AM1.5 full spectrum sunlight, at a temperature of ˜60° C., in ambient air. For the control film, we observe an obvious colour change from black to yellow-grey after 72 h of light-soaking, which is due to a fractional decomposition to PbI₂, as we infer from XRD measurements (FIG. 3a). We expect this to happen, since in the presence of light and oxygen, superoxide is generated, which has been observed to rapidly decompose MAPbI₃ (Bryant, D. et al. Light and oxygen induced degradation limits the operational stability of methylammonium lead triiodide perovskite solar cells. Energy Environ. Sci. 9, 1655-1660, (2016); Aristidou, N. et al. Fast oxygen diffusion and iodide defects mediate oxygen-induced degradation of perovskite solar cells. Nat. Commun. 8, 15218, (2017)). In contrast, for the perovskite film processed with the IL, we observe no discoloration and negligible PbI₂ in the post-aged perovskite films.

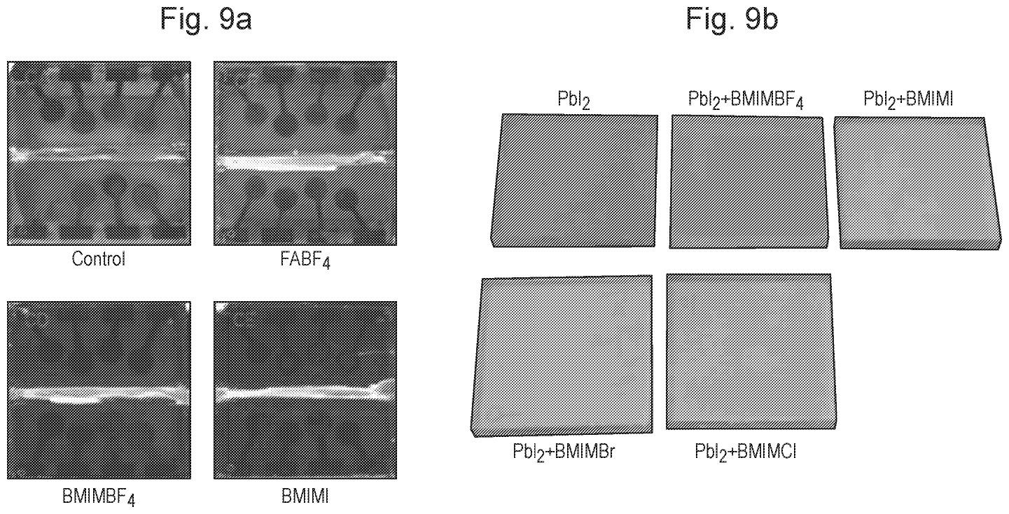

In order to understand which components of the IL, [BMIM]⁺ or [BF₄]⁻, are important for improving the efficiency of the solar cells and stability of the perovskite absorber layer, we assess the impact of a range of different ILs. We firstly characterize solar cells with the addition of FABF₄ and compare to BMIMBF₄, respectively. We observe comparable device performance to the control, with the FABF₄ addition (FIG. 3b), in contrast to the obvious improvement in the device efficiency on BMIMBF₄. However, we observe no improvement in the film stability, which we show in FIG. 3c and FIG. 9a. By replacing the [BF₄]⁻ anion, with halide anions, e.g. BMIMI, we do replicate the stability improvement of the perovskite films (FIG. 3c and FIG. 9a). However, we measure significantly decreased device efficiency with the addition of BMIM halides (FIG. 3b). This indicates that both [BMIM]⁺ and [BF₄]⁻ are required to improve both the efficiency of the device and stability of the film.

In order to elucidate the differences between the addition of BMIMBF₄, and BMIMX (X=halide), we investigate the interaction between PbI₂ and the BMIM-based ILs with different anions. In FIG. 9b we show photographs of films of PbI₂ and 1:1 molar ration of PbI₂:IL, which we spin-coated and dried in the glovebox at 100° C. We observe optically transparent films, for all the PbI₂:BMIMX films, consistent with lead halide-immidazolium salt complex formation (Zhang, Y. et al. A strategy to produce high efficiency, high stability perovskite solar cells using functionalized ionic liquid-dopants. Adv. Mater. 29, 1702157, (2017)). However, the PbI₂:BMIMBF4 films retain yellow coloration. We confirm our visual observation with the XRD patterns and UV-Vis absorption spectra, which we show in FIGS. 3d and 3e, where we also observe that the presence of all the used BMIM ILs, greatly suppress the emergence of crystalline PbI₂.

As a further probe of the difference between the ILs with the halide anions, as compared to [BF₄]⁻, we interrogate the compositional distribution of halide throughout the film (we can only probe Cl here, since I and Br are already present in the perovskite). According to the ToF-SIMS results of the perovskite film with BMIMCl, which we show in FIG. 3f, the Cl⁻ is distributed throughout the thickness of the film, in contrast to the [BF₄]⁻ which we only detect at the perovskite/NiO interface. This indicates that if PbI₂:BMIMX complexes form within the IL doped perovskite films, they are likely to exist throughout the bulk of the perovskite film.

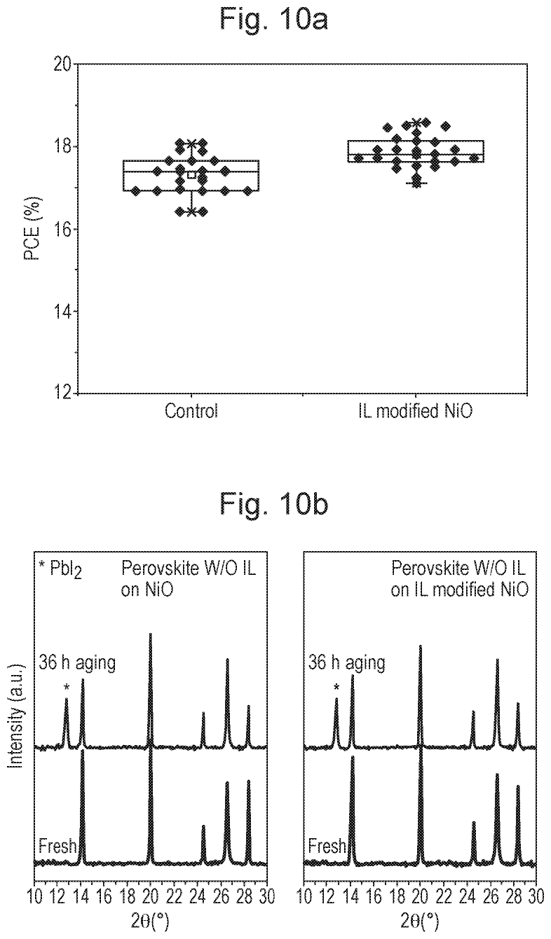

For completeness, we investigate if the BMIMBF₄ needs to be added to the perovskite solution, or if it can be preprocessed on the substrate prior to processing of the perovskite film. For this latter approach, we observe some improvement in the device efficiency but little positive influence upon the intrinsic stability of the perovskite active layer (FIG. 10). Therefore, we conclude that the improvement on the film stability mainly origins from the presence of the [BMIM]⁺ organic cations in the perovskite active layer, with the [BF₄]⁻ being important so that the introduced IL does not negatively impact the film properties and the device performance of the ensuing solar cells. We assume that in the as-crystallised films, the large [BMIM]⁺ ions are excluded from the perovskite crystals and hence accumulate at the surface and grain boundaries of the perovskite film. We postulate that the [BMIM]⁺ cation, which is hydrophobic and the presence of which appears to inhibit PbI₂ crystalisation, will bind to surface sites which would have otherwise been susceptible to degradation via oxygen or moisture adsorption and subsequent reactions under light and heat (Sun, Q. et al. Role of microstructure in oxygen induced photodegradation of methylammonium lead triiodide perovskite films. Adv. Energy Mater. 7, 1700977, (2017)), and hence suppress the degradation of the perovskite active layer. However, as in the case for the halide containing ILs, we observe significantly reduced PCEs with devices processed with BMIMX. We speculate that the readily formed large band-gap complexes of PbI₂:BMIMX disrupt the perovskite lattice or introduce surface strain, and hence introduce electronic defects in the perovskite active layer and inhibited the charge extraction of the resulting devices (Zhang, Y. et al. A strategy to produce high efficiency, high stability perovskite solar cells using functionalized ionic liquid-dopants. Adv. Mater. 29, 1702157, (2017)).

We now proceed to investigate the stability of complete perovskite solar cells under combined light and heat stress. We first test non-encapsulated devices under full spectrum sunlight at ˜60° C. We show the normalized PCEs as a function of aging time in FIG. 4a. For both devices, we observe no degradation in the device performance during the first 40 h. In contrast to our previous best-reported stability (Wang, Z. et al. Efficient ambient-air-stable solar cells with 2D-3D heterostructured butylammonium-caesium-formamidinium lead halide perovskites. Nat. Energy 2, 17135, (2017)), and that of others studying n-i-p perovskite solar cells (Hou, Y. et al. A generic interface to reduce the efficiency-stability-cost gap of perovskite solar cells. Science 358, 1192-1197, (2017)), here we do not observe an early time light induced degradation or “burn-in”. This is already a key step forward, and we assign this primarily to the use of p-i-n device structure comprised of NiO hole-conductor and Cr (Cr₂O₃)/Au top electrode (Nie, W. et al. Critical Role of Interface and Crystallinity on the Performance and Photostability of Perovskite Solar Cell on Nickel Oxide. Adv. Mater. 30, 1703879, (2018); Kaltenbrunner, M. et al. Flexible high power-per-weight perovskite solar cells with chromium oxide-metal contacts for improved stability in air. Nat. Mater. 14, 1032-1039, (2015)). However, for the control devices, we do observe degradation after 40 h and the PCE quickly decreases to ˜6% of its original value after a further 80 h of aging. In contrast, the device with the IL retains ˜92% of its initial performance under the same aging condition. As insets, we show photographs of the aged devices, where we observe obvious color fading of the control device in the regions beyond the electrode protected area, while the device with the IL shows no visible color change. It may be the case, that the ˜8% efficiency drop of the IL containing device under the aging conditions is related to the degradation of the charge extraction layers or interfaces, most likely PCBM and bathocuproine (BCP), rather than the perovskite absorber itself.

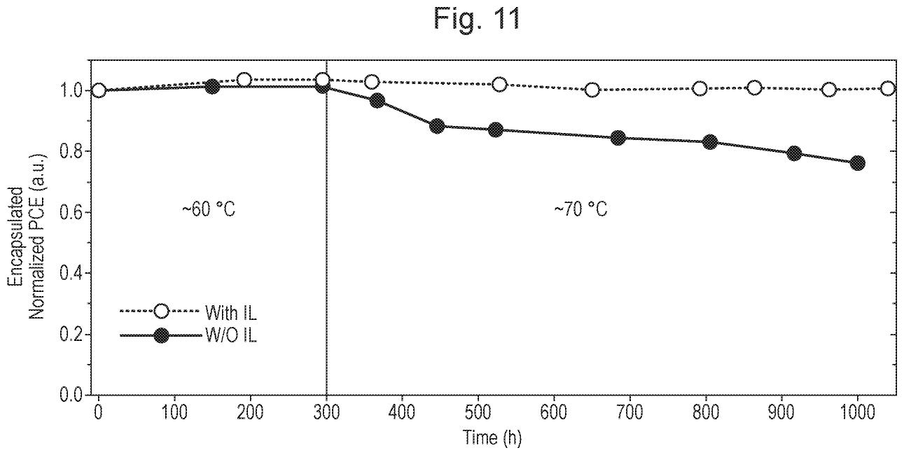

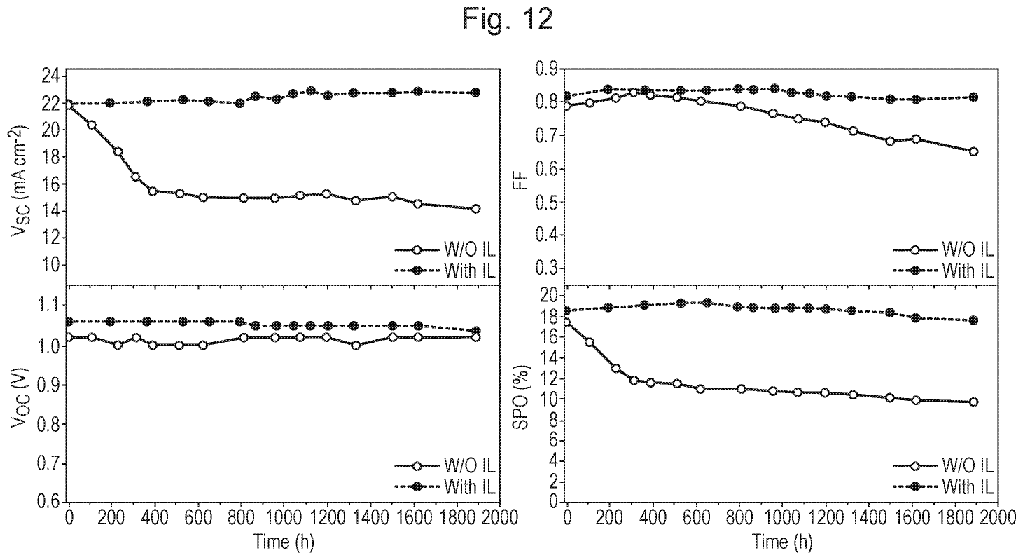

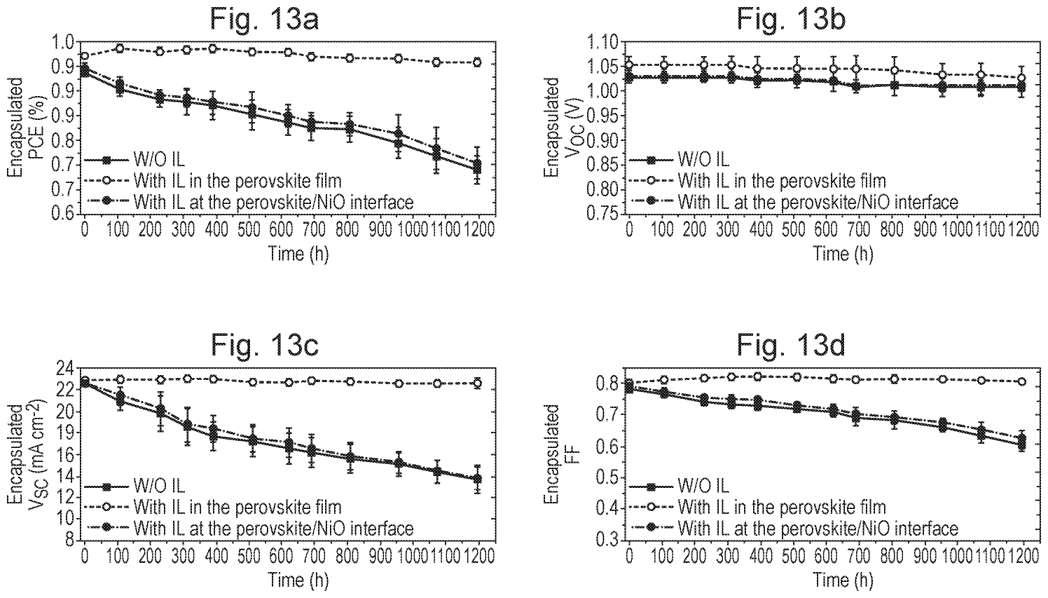

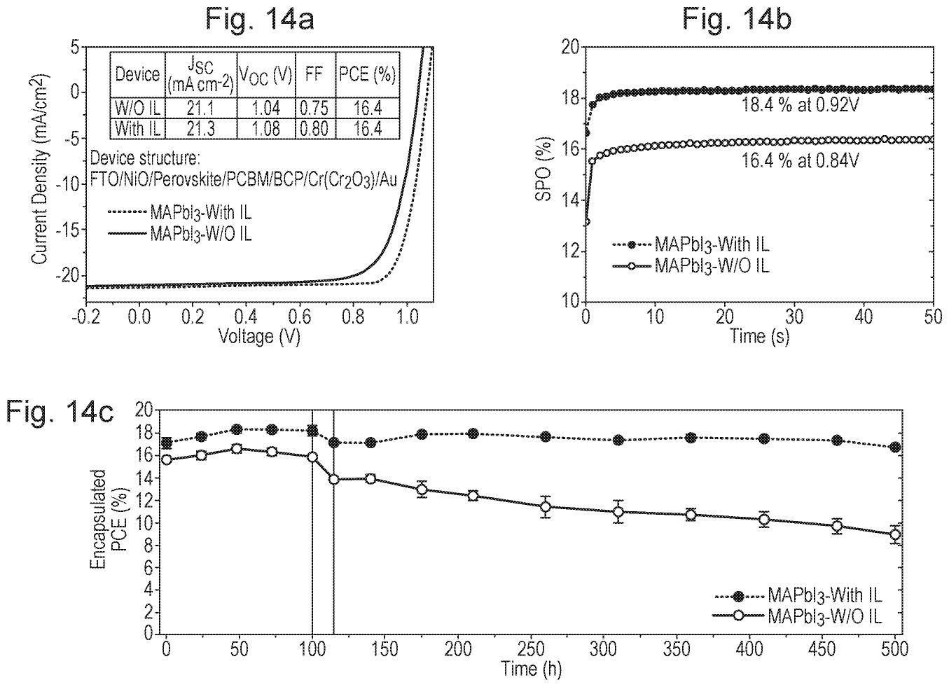

In order to probe the longer-term stability of our devices, we proceed to encapsulate the cells with a glass coverslip and a UV-curable epoxy-resin. We observe that the temperature is a critical factor that affects the device stability. For both the control and IL containing devices, we observe no degradation of the encapsulated cells during the first 300 h, while we keep the temperature of aging box at ˜60° C. When we allow the temperature to increase to ˜70° C., we observe an accelerated degradation for the control device, while for the device with the IL we observe sustained high efficiency (FIG. 11). We carry out the stressing test under this rigorous condition at ˜70° C. and present the stability performance in FIG. 4b. We measure the efficiency of the control device to degrade to 75% of its original value within the first 500 h and to 55% of the initial performance after 1,885 h aging. Remarkably, for the IL containing device, we observe negligible degradation in the J-V derived efficiency and less than 5% degradation in the SPO over the entire 1,885 h aging test (we show the SPO degradation in FIG. 12). We show a 1,200 h stability test result under the same aging condition from a set of ten different cells of each type, without any IL, with the IL at the interface and with the IL in the perovskite active layer (FIG. 13). We consistently observe the same trend with very little degradation in the IL doped cells. We do however observe degradation in the cells where the NiO is pre-coated with IL prior to perovskite film deposition. Therefore it appears essential that the IL is within the perovskite absorber layer. We demonstrate the applicability of the IL doping strategy on the traditionally unstable perovskite, MAPbI₃, in p-i-n devices with the same structure. We summarize the device parameters of perovskite solar cells based on MAPbI₃ with and without the IL in Table 2. These cells also show a remarkable improvement in stability with less than 10% degradation after 500 h of aging at 60° C. under full-spectrum light soaking (FIG. 14).

TABLE 2
Device parameters of solar cells based on MAPbI₃, perovskite without IL
and with the BMIMBF₄ IL at an optimized concentration of 0.3 mol %.

| | | | | | |
|---|---|---|---|---|---|
| | J_{SC} | V_{OC} | | PCE | SPO |
| Device | (mA cm⁻²) | (V) | FF | (%) | (%) |

W/O IL

| | | | | | |
|---|---|---|---|---|---|
| Average | 20.6 ± 0.4 | 1.03 ± 0.02 | 0.71 ± 0.03 | 15.7 ± 0.4 | 15.6 ± 0.4 |
| Champion | 21.1 | 1.04 | 0.75 | 16.4 | 16.4 |

With IL

| | | | | | |
|---|---|---|---|---|---|
| Average | 21.0 ± 0.4 | 1.06 ± 0.02 | 0.78 ± 0.03 | 17.7 ± 0.4 | 17.6 ± 0.4 |
| Champion | 21.3 | 1.08 | 0.80 | 18.4 | 18.4 |

The average device parameters with standard deviation are obtained based on 10 cells for each condition.

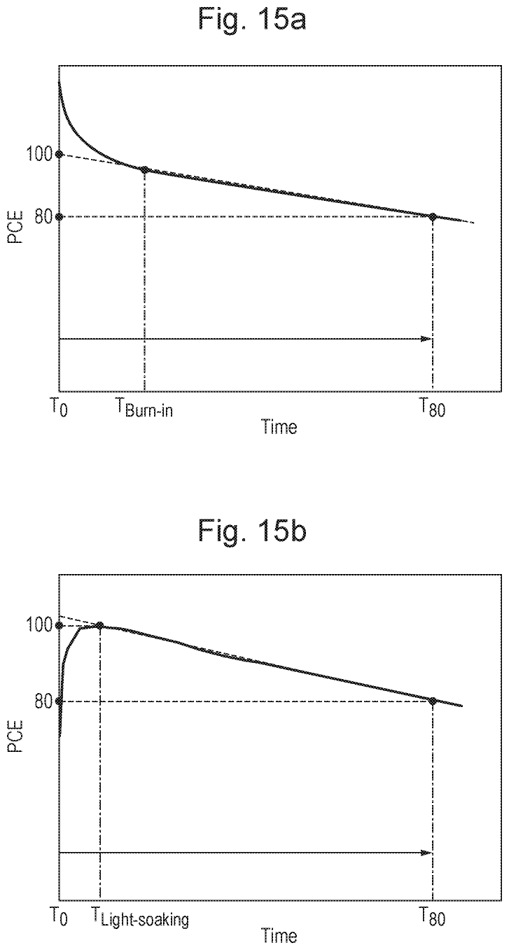

Via fitting the degradation data of the best-performing (FA_{0.83}MA_{0.17})_{0.95}Cs_{0.05}Pb(I_{0.9}Br_{0.1})₃ device from the peak efficiency at ˜500 hours and beyond to a straight line, we determine a total lifetime to 80% of the peak performance (T₈₀). We illustrate our methods for determining Tso in detail in FIG. 15. We estimate a T₈₀ of J-V derived efficiency of ˜12,400 h for the most stable device with the IL, and the T₈₀ of the SPO to be 4,900 h. This is more than 3 times longer than our previous best-reported stability for n-i-p solar cells (Wang, Z. et al. Efficient ambient-air-stable solar cells with 2D-3D heterostructured butylammonium-caesium-formamidinium lead halide perovskites. Nat. Energy 2, 17135, (2017)), which were aged at a lower temperature of ˜50 to 60° C. and exhibited an early time burn-in. We would expect that an additional degradation acceleration factor due to a 10 to 20° C. increase in aging temperature here, is in the region of 2 to 4-fold (2-fold per 10° C. increase in temperature) (Ross, J., R. G. Crystalline-silicon reliability lessons for thin-film modules. Proc. 18th IEEE Photovoltaic Specialists Conf., 1114-1020, (1985)). We therefore estimate that the cells we present here are in the region of one order of magnitude (6 to 12-fold) more stable than our previous best-performing devices, and in addition do not exhibit any light-induced degradation burn-in.

In order to put our results into broader context, we tabulate long-term performance stability results from previous literature reports in Table 3, specifying the device structure, the aging conditions, degradation factors, starting efficiency and the estimated T₈₀ lifetime. In comparison with the next longest Tso lifetime reported in the literature (Christians, J. A. et al. Tailored interfaces of unencapsulated perovskite solar cells for >1,000 hour operational stability. Nat. Energy 3, 68-74, (2018)), our cells here are stressed at ˜40° C. higher temperature, with the presence of more intense UV light in the light source and deliver around 2-fold longer T₈₀ lifetime. Using the same approximate 2-fold acceleration factor per 10° C., this indicates a 16 fold improvement in stability, with respect to those previously reported results. We note, that all the results which we show in Table 3 are measured under slightly different conditions (light source, atmosphere, encapsulation, electric bias conditions, temperature, etc.), which we tabulate in the table, where the information was available. Ultimately standardized measurements conditions, with which to fairly compare between experimental results in different labs, would be greatly beneficial to the community (Snaith, H. J. & Hacke, P. Enabling reliability assessments of pre-commercial perovskite photovoltaics with lessons learned from industrial standards. Nat. Energy 3, 459-465, (2018)).

TABLE 3
Summary of the long-term light stability performance of perovskite solar cells in literature reports.

| | | | | | | |
|---|---|---|---|---|---|---|
| | | | | Bias | | |
| | Light | | Initial | conditions | T₈₀ | |
| Device | Source & | Temp | PCE | & Time | lifetime | |
| Structure | Environment | (° C.) | (%) | (hrs) | (hrs) | Ref |

Mesoporous structure:

| | | | | | | |
|---|---|---|---|---|---|---|
| FTO/c-TiO₂/Li-doped meso | White LED lamp | ~85 | ~17 | MPP | ~1,700 | [2] |
| TiO₂ + perovskite/PTAA/Au | Nitrogen | | | 500 | | |
| FTO/c-TiO₂/Li-doped meso | White LED array | ~60 | ~20 | MPP | ~5,700 | [3] |
| TiO₂ + perovskite/CuSCN/r- | Nitrogen | | | 1,000 | | |
| GO/Au | | | | | | |
| FTO/meso-TiO₂/meso-ZrO₂/ | N/A | N/A | ~11 | N/A | N/A | [4] |
| perovskite/carbon | Ambient air | | | 1,008 | | |

Planar n-i-p structure:

| | | | | | | |
|---|---|---|---|---|---|---|
| FTO/BaSnO₃:La/perovskite/ | Metal-halide lamp | N/A | ~14 | Open-circuit | N/A | [5] |
| NiO/FTO | Ambient air, sealed | | | 1,000 | | |
| FTO/SnO₂/PCBM/perovskite/ | Xenon lamp | ~50 to 60 | ~17 | Open-circuit | ~3,900 | [6] |
| Spiro-OMeTAD/Au | Ambient air, sealed | | | 2,400 | | |
| ITO/TiO₂—Cl/perovskite/ | Xenon lamp^{†} | RT | ~20 | MPP | ~1,600 | [7] |
| Spiro-OMeTAD/Au | Nitrogen | | | 500 | | |
| ITO/C₆₀-SAM/SnOₓ/PCBM/ | White LED | RT | ~20 | Open-circuit | ~1,600 | [8] |
| perovskite/polymer/Ta—WOₓ/Au | Nitrogen | | | 1,000 | | |
| FTO/SnO₂/perovskite/EH44/ | Sulphur plasma lamp | RT | ~16 | MPP | ~6,500 | [9] |
| MoOₓ/Al | Inert atmosphere | | | 1500 | | |

Planar p-i-n structure:

| | | | | | | |
|---|---|---|---|---|---|---|
| FTO/LiMgNiO/perovskite/ | Xenon lamp^{†} | ~25 | ~18 | N/A | ~2,800 | [10] |
| PCBM/Nb—TiO₂/Ag | N/A | | | 1,000 | | |
| ITO/NiO/perovskite/PCBM/ | Sulphur plasma lamp | ~35 | ~13 | MPP | ~2,000 | [11] |
| SnO₂/ZTO/ITO/LiF/Ag | Ambient air^{‡} | | | 1,000 | | |
| ITO/PEDOT:PSS/2D | Xenon lamp | N/A | ~12 | Open-circuit | N/A | [12] |
| perovskite/PCBM/Al | Ambient air, sealed | | | 2,250 | | |
| FTO/NiO/perovskite/ | Xenon lamp | ~70 | ~19 | Open-circuit | ~12,000 | This |
| PCBM/BCP/Cr(Cr₂O₃)/Au | Ambient air, sealed | | | 1,885 | | work |

^{†}420 nm cut-off UV-filter was used during the stability test.
^{‡}The ITO electrode here acts as an encapsulation layer for the solar cells.
[2] Saliba, M. et al. Cesium-containing triple cation perovskite solar cells: improved stability, reproducibility and high efficiency. Energy Environ. Sci. 9, 1989-1997, (2016).
[3] Arora, N. et al. Perovskite solar cells with CuSCN hole extraction layers yield stabilized efficiencies greater than 20%. Science 358, 768-771, (2017).
[4] Mei, A. et al. A hole-conductor-free, fully printable mesoscopic perovskite solar cell with high stability. Science 345, 295-298, (2014).
[5] Shin, S. S. et al. Colloidally prepared La-doped BaSnO3 electrodes for efficient, photostable perovskite solar cells. Science 356, 167-171, (2017).
[6] Wang, Z. et al. Efficient ambient-air-stable solar cells with 2D-3D hetero structured butylammonium-caesium-formamidinium lead halide perovskites. Nat. Energy 2, 17135, (2017).
[7] Tan, H. et al. Efficient and stable solution-processed planar perovskite solar cells via contact passivation. Science 355, 722-726, (2017).
[8] Hou, Y. et al. A generic interface to reduce the efficiency-stability-cost gap of perovskite solar cells. Science 358, 1192-1197, (2017).
[9] Christians, J. A. et al. Tailored interfaces of unencapsulated perovskite solar cells for >1,000 hour operational stability. Nat. Energy 3, 68-74, (2018).
[10] Wu, Y. et al. Perovskite solar cells with 18.21% efficiency and area over 1 cm2 fabricated by heterojunction engineering. Nat. Energy 1, 16148, (2016).
[11] Bush, K. A. et al. 23.6%-efficient monolithic perovskite/silicon tandem solar cells with improved stability. Nat. Energy 2, 17009, (2017).
[12] Tsai, H. et al. High-efficiency two-dimensional Ruddlesden - Popper perovskite solar cells. Nature 536, 312-316, (2016).

In summary, we have found that by introducing ionic liquids into the perovskite absorber layer, we have cohesively suppressed the ion migration and improved the film stability under combined light and heat in ambient air. Beyond expectations, a combination of BMIMBF₄-containing perovskite and the p-i-n planar device structure, delivers not just an improvement in efficiency, but also almost “non-degrading” solar cells when stressed under full spectrum sunlight at elevated temperature. This represents a key step towards the commercial upscale and deployment of the perovskite PV technology.

### METHODS

Materials. All the organic cation salts were purchased from Dyesol. Lead iodide (PbI₂, 99.99%, trace metals basis) was purchased from TCI Chemicals and lead bromide (PbBr₂, ≥98%) from Sigma-Aldrich. Cesium iodide (CsI, 99.9%) was purchased from Alfa-Aesar. PCBM (>99.5%) was purchased from Solenne. Unless otherwise stated, all other materials and solvents were purchased from Sigma-Aldrich. All the materials were used as received without further purification.

Substrates preparation. FTO-coated glass (Pilkington TEC 7, 7Ω/□ sheet resistivity) was etched with zinc powder and 2 M HCl to desired pattern. The substrates were cleaned with 2% solution of Hellmanex cuvette cleaning detergent, then subsequently washed with deionized water, and ethanol, and dried with dry nitrogen. The substrates were treated with UV-Ozone for 10 min before use. The Poly-TPD coated substrates were fabricated based on the reported recipe (Wang, J. T.-W. et al. Efficient perovskite solar cells by metal ion doping. Energy Environ. Sci. 9, 2892-2901, (2016)). The NiO precursor (0.1 M) was prepared by dissolving nickel acetylacetonate (95%, Sigma-Aldrich) in anhydrous ethanol, and HCl (37%) (1% v/v) was used as the stabilizer. The precursor solution was stirred overnight at room temperature, filtered (0.45 μm, PTFE) and then spincoated on cleaned FTO substrates at 4000 r.p.m for 40 s. The films were dried at 180° C. for 10 min and then sintered at 400° C. for 45 min to obtain compact p-type layer of NiO. For the IL treated substrates, a 3 mg/ml IL solution in ethanol was spincoated on the NiO substrates at 6000 r.p.m, following annealing at 100° C. for 10 min in the glovebox. The relative humidity during the spincoating and annealing of NiO films ranged from 40-50% in our cleanroom.

Preparation of perovskite precursor. We prepared the (FA_{0.83}MA_{0.17})_{0.95}Cs_{0.05}Pb(I_{0.9}Br_{0.1})₃ triple cation perovskite precursor solution (1.3 M) by dissolving formamidinium iodide (FAI, 176.6 mg) and methylammonium iodide (MAI, 33.1 mg), CsI, (16.9 mg), PbI₂ (509.4 mg) and PbBr₂ (71.6 mg) in a 1 ml mixed anhydrous solvent of N,N-dimethylformamide (DMF), dimethyl sulfoxide (DMSO) and N-methyl-2-pyrrolidinone (NMP). The ratio of the solvents was fixed at 4/0.9/0.1 in volume (DMF/DMSO/NMP). In parallel, we prepared the ionic liquids containing perovskite precursor solution (1.5 mol % with respect to the Pb) by dissolving the same components in the mixed solvent with different ionic liquids. The perovskite precursor solution was stirred overnight in the glovebox and filtered (0.45 μm, PTFE) before use. The IL-containing solution with desired concentration was prepared by mixing the precursor without and with IL at different ratio. The precursor solutions for MAPbI₃ perovskite (1.4 M) without and with 0.3 mol % BMIMBF₄ were prepared by dissolving PbI₂ and MAI with a molar ratio of 1:1 in anhydrous DMF/DMSO (4:1, volume ratio). The perovskite precursor solution was stirred overnight in the glovebox and filtered (0.45 μm, PTFE) before use.

Device Fabrication. The perovskite films were deposited in the glovebox using a solvent quenching method (Jeon, N. J. et al. Solvent engineering for high-performance inorganic-organic hybrid perovskite solar cells. Nat. Mater. 13, 897, (2014)) with anisole as the anti-solvent. In detail, 100 μl perovskite precursor solution was dropped on the NiO coated FTO substrates (2.8×2.8 cm) and spincoated at 1300 r.p.m for 5 s (5 s ramp) and 5000 r.p.m for 30 s (5 s ramp). 250 μl anhydrous anisole was quickly dropped on the substrates 5 s before the end of the program. The samples were immediately put on a pre-heated hot plate and annealed at 100° C. for 1 h. For MAPbI₃ devices, the precursor solution was spincoated at 4000 r.p.m for 30 s. 250 μl anhydrous anisole was dropped on the substrates 10 s before the end of the program. The films were annealed at 80° C. for 5 min We spincoated the PCBM solution with a concentration of 20 mg/ml in chlorobenzene/1,2-dichlorobenzene (3/1, v/v) on top of the perovskite films at a speed of 1800 r.p.m for 30 s. The samples were then annealed at 100° C. for 10 min After cooling down to room temperature, we dynamically spincoated BCP solution (0.5 mg/ml in isopropanol) on top of the PCBM at a speed of 4000 r.p.m for 20 s. We then took out the samples from the glovebox and finished the devices by thermally evaporating Cr203/Cr (3.5 nm) and Au electrode (100 nm) under a vacuum of 6×10⁻⁶ torr with a thermal evaporator (Nano 36, Kurt J. Lesker) outside.

Solar cell characterization. The current density-voltage (J-V) curves were measured in air with a Keithley 2400 source meter under AM1.5 sunlight at 100 mW cm⁻² irradiance generated using an ABET Class AAB sun 2,000 simulator. The light intensity was calibrated using a National Renewable Energy Laboratories (NREL) calibrated KG 5 filtered silicon reference cell with the mismatch factor less than 1%. All devices were masked with a 0.0919 cm⁻² metal aperture to define the active area and to eliminate edge effects. The J-V curves were measured at a scan rate of 200 mV s⁻¹ (voltage step of 20 mV and delay time of 100 ms) from 1.2 to −0.2 V and then back again (from −0.2 to 1.2 V). A stabilization time of 2 s at forward bias of 1.2 V under illumination was done prior to scanning.

External quantum efficiency (EQE) measurement. EQE measurements were performed using custom-built Fourier transform photocurrent spectroscopy based on the Bruker Vertex 80v Fourier transform spectrometer. A Newport AAA sun simulator was used as the light source and the light intensity was calibrated with a Newport-calibrated reference silicon photodiode. Film characterizations. The morphologies of the perovskite films on NiO coated FTO substrates were characterized using a SEM (Hitachi S-4300) at an accelerating voltage of 3-5 kV. The diffraction patterns were measured from samples of perovskite films on NiO coated FTO substrates using a Panalytical X'PERT Pro X-ray diffractometer. UV-Vis absorption spectra were measured using a Varian Carry 300 Bio (Agilent Technologies). Steady-state and time-resolved PL spectra were acquired using a Fluorescence lifetime spectrometer (FLuo Time 300, PicoQuant). The samples were excited using a 507 nm laser (LDH-P-C-510, PicoQuant) with pulse duration of 117 ps, fluence of ˜30 nJ cm⁻² per pulse and a repetition rate of 1 MHz. The PL data was collected using a high-resolution monochromator and hybrid photomultiplier detector assembly (PMA Hybrid 40, PicoQuant GmbH). The samples were prepared on thin insulating amorphous TiO₂-coated glass substrates to avoid the impact of morphology and structure change of perovskite films on the PL measurements. UPS and XPS measurements.

Photoemission experiments were carried out using a Scienta ESCA 200 spectrometer in ultrahigh vacuum with a base pressure of 1×10⁻¹⁰ mbar. The measurement chamber is equipped with a monochromatic Al (K alpha) x-ray source providing photons with 1486.6 eV for XPS and a standard He-discharge lamp with HeI 21.22 eV for UPS. The XPS experimental condition was set so that the full width at half maximum of the clean Au 4f_{7/2} line (at the binding energy of 84.00 eV) was 0.65 eV. The total energy resolution UPS measurement is about 80 meV as extracted from the width of the Fermi level (at the binding energy of 0.00 eV) of clean gold foil. All spectra were measured at a photoelectron takeoff angle of 0° (normal emission). The work function of film was extracted from the edge of the secondary electron cutoff of the UPS spectra by applying a bias of −3 V to the sample.

Kelvin Probe measurement. We used a vibrating Kelvin Probe (probe diameter=2 mm) (KP Technology, UK) to determine the surface work function. The perovskite films without and with IL doping at different concentrations were fabricated on FTO/NiO substrates follow the deposition recipe as the films in the solar cells. The measurements were carried out in ambient on different spots and different samples of each condition, and provide the average value with the standard error.

ToF-SIMS measurement. The compositional depth profiling of perovskite films was obtained using a ToF-SIMS 5 system from ION-TOF. Bi³⁺ ions were used as primary ions and positive ions were detected. Sputtering were performed using Cs⁺ sputtering ions with 1 keV ion energy, 80 nA ion current and a 300×300 μm² raster size. An area of 100×100 μm² was analyzed using Bi³⁺ ions with 25 keV acceleration and total current of 0.5 pA. Ion migration characterization. For the PL imaging experiments under electric field, perovskite films were deposited with planar Au electrode with the channel width of ˜150 μm. The characterization method was performed following previous report based on a home-build PL imaging microscope. Based on a commercial microscopy (Microscope Axio Imager. A2m), sample was illuminated by a LED illuminator using an excitation filter and dicroic mirror (HC 440 SP, AHF analysentechnik AG) allowing an excitation at 440 nm. The excitation power could be controlled and was set to ˜34 mW cm⁻² in the focus plane using an infinity-corrected objective (10×/0.25 HD, Zeiss). The PL light was filtered (HC-BS 484, AHF analysentechnik AG) to suppress residual excited light and directed to the microscope with the same objective lens. PL signal was imaged with a CCD camera (Pco. Pixelfly, PCO AG) with the exposure time of 200 ms. The perovskite film was placed in the focal plane of the objective lens. The PL changing process was recorded with a constant 10 V voltage being applied between the Au electrodes (Keithley 236 Source Measure Unit).

Device and film stability test. The perovskite solar cells were simply encapsulated with a cover glass (LT-Cover, Lumtec) and UV adhesive (LT-U001, Lumtec) in a nitrogen-filled glovebox. All of the non-encapsulated perovskite films on NiO/FTO substrates, encapsulated and non-encapsulated devices were aged using an Atlas SUNTEST XLS+(1,700 W air-colled Xenon lamp) light-soaking chamber under simulated full-spectrum AM1.5 sunlight with 76 mW cm⁻² irradiance. All devices were aged under open-circuit conditions, and were taken out from the chamber and tested at different time intervals under a separate solar simulator (AM1.5, 100 mW cm⁻²) for J-V characterizations. No additional ultraviolet filter was used during the whole aging process. The chamber was air-cooled with the temperature controlled in the range of 60-70° C. as measured by a black standard temperature control unit. The relative humidity in the laboratory was monitored in the range of 40-60% during the entire aging test.

1. An optoelectronic device comprising:
(a) a layer comprising a crystalline A/M/X material, wherein the crystalline A/M/X material comprises a compound of formula:
[A]ₐ[M]_{b}[X]_{c}
wherein:
[A] comprises one or more A cations;
[M] comprises one or more M cations which are metal or metalloid cations;
[X] comprises one or more X anions;
a is a number from 1 to 6;
b is a number from 1 to 6; and
c is a number from 1 to 18; and
(b) an ionic liquid which is a salt comprising an organic cation and a counter anion, wherein the organic cation is present within the layer comprising the crystalline A/M/X material.

2-3. (canceled)

4. An optoelectronic device according to claim 1 wherein the crystalline A/M/X material is a polycrystalline A/M/X material comprising crystallites of the A/M/X material and grain boundaries between the crystallites, wherein the organic cation is present at grain boundaries between the crystallites.

5. An optoelectronic device according to claim 1 wherein the optoelectronic device further comprises a layer comprising a charge-transporting material, wherein the layer comprising the crystalline A/M/X material is disposed on the layer comprising the charge-transporting material.

6. An optoelectronic device according to claim 5 wherein the charge-transporting material is a hole-transporting (p-type) material.

7. (canceled)

8. An optoelectronic device according to claim 6 wherein the hole-transporting material is a solid state inorganic hole transporting material, preferably wherein the solid state inorganic hole transporting material comprises an oxide of nickel, vanadium, copper or molybdenum, particularly preferably wherein the solid state inorganic hole transporting material comprises nickel oxide.

9. An optoelectronic device according to claim 5 wherein the counter-anion is present (a) within the layer comprising the crystalline A/M/X material, (b) between the layer comprising the crystalline A/M/X material and the layer comprising the charge-transporting material, and/or (c) within the layer comprising the charge-transporting material.

10-11. (canceled)

12. An optoelectronic device according to claim 1 wherein some or all of the counter-anion is not present within the crystalline A/M/X material, and preferably wherein at least some of the counter-anion is present on an outer surface of the crystalline A/M/X material.

13. An optoelectronic device according to claim 1 wherein the counter-anion is a polyatomic anion, preferably wherein the polyatomic anion is a non-coordinating anion.

14. (canceled)

15. An optoelectronic device according to claim 1 wherein the organic cation is an unsubstituted or substituted imidazolium cation, preferably wherein the unsubstituted or substituted imidazolium cation is an imidazolium cation of formula I: 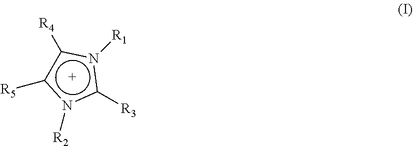
wherein each of R₁, R₂, R₃, R₄ and R₅ is independently selected from hydrogen, unsubstituted or substituted C₁₋₁₀ alkyl, unsubstituted or substituted C₂₋₁₀ alkenyl, unsubstituted or substituted C₂₋₁₀ alkynyl, unsubstituted or substituted C₆₋₁₂ aryl, unsubstituted or substituted C₃₋₁₀ cycloalkyl, unsubstituted or substituted C₃₋₁₀ cycloalkenyl, amino, unsubstituted or substituted (C₁₋₆ alkyl)amino and unsubstituted or substituted di(C₁₋₆ alkyl)amino;
preferably wherein each of R₁, R₂, R₃, R₄ and R₅ is independently selected from hydrogen, unsubstituted or substituted C₁₋₁₀ alkyl, unsubstituted C₂₋₁₀ alkenyl, unsubstituted C₂₋₁₀ alkynyl, unsubstituted C₆₋₁₂ aryl, unsubstituted C₃₋₁₀ cycloalkyl, unsubstituted C₃₋₁₀ cycloalkenyl, amino, unsubstituted (C₁₋₆ alkyl)amino and unsubstituted di(C₁₋₆ alkyl)amino;
more preferably wherein R₃, R₄ and R₅ are hydrogen and wherein each of R₁ and R₂ is independently selected from unsubstituted C₁₋₁₀ alkyl and C₁₋₁₀ alkyl substituted with a phenyl group.

16. An optoelectronic device according to claim 15 wherein the organic cation is an imidazolium cation of formula I and the counter anion is BF₄⁻, preferably wherein the organic cation is 1-butyl-3-methylimidazolium and the counter anion is BF₄⁻.

17. (canceled)

18. An optoelectronic device according to claim 1 wherein the organic cation is an unsubstituted or substituted pyridinium cation, an unsubstituted or substituted piperidinium cation or an unsubstituted or substituted pyrrolidinium cation,
preferably wherein: the unsubstituted or substituted pyridinium cation is a pyridinium cation of formula II: 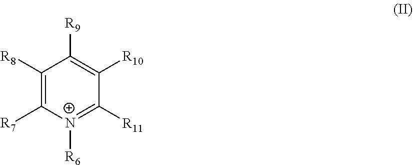
wherein each of R₆, R₇, R₈, R₉, R₁₀ and R₁₁ is independently selected from hydrogen, unsubstituted or substituted C₁₋₁₀ alkyl, unsubstituted or substituted C₂₋₁₀ alkenyl, unsubstituted or substituted C₂₋₁₀ alkynyl, unsubstituted or substituted C₆₋₁₂ aryl, unsubstituted or substituted C₃₋₁₀ cycloalkyl, unsubstituted or substituted C₃₋₁₀ cycloalkenyl, amino, unsubstituted or substituted (C₁₋₆ alkyl)amino and unsubstituted or substituted di(C₁₋₆ alkyl)amino;
preferably wherein each of R₆, R₇, R₈, R₉, R₁₀ and R₁₁ is independently selected from hydrogen, unsubstituted or substituted C₁₋₁₀ alkyl, unsubstituted C₂₋₁₀ alkenyl, unsubstituted C₂₋₁₀ alkynyl, unsubstituted C₆₋₁₂ aryl, unsubstituted C₃₋₁₀ cycloalkyl, unsubstituted C₃₋₁₀ cycloalkenyl, amino, unsubstituted (C₁₋₆ alkyl)amino and unsubstituted di(C₁₋₆ alkyl)amino;
more preferably wherein R₇, R₈, R₁₀ and R₁₁ are hydrogen and wherein each of R₆ and R₉ is independently selected from unsubstituted C₁₋₁₀ alkyl and C₁₋₁₀ alkyl substituted with a phenyl group;
the unsubstituted or substituted piperidinium cation is a piperidinium cation of formula III: 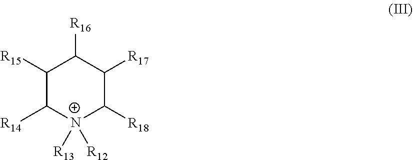
wherein each of R₁₂, R₁₃, R₁₄, R₁₅, R₁₆, R₁₇ and R₁₈ is independently selected from hydrogen, unsubstituted or substituted C₁₋₁₀ alkyl, unsubstituted or substituted C₂₋₁₀ alkenyl, unsubstituted or substituted C₂₋₁₀ alkynyl, unsubstituted or substituted C₆₋₁₂ aryl, unsubstituted or substituted C₃₋₁₀ cycloalkyl, unsubstituted or substituted C₃₋₁₀ cycloalkenyl, amino, unsubstituted or substituted (C₁₋₆ alkyl)amino and unsubstituted or substituted di(C₁₋₆ alkyl)amino;
preferably wherein each of R₁₂, R₁₃, R₁₄, R₁₅, R₁₆, R₁₇ and R₁₈ is independently selected from hydrogen, unsubstituted or substituted C₁₋₁₀ alkyl, unsubstituted C₂₋₁₀ alkenyl, unsubstituted C₂₋₁₀ alkynyl, unsubstituted C₆₋₁₂ aryl, unsubstituted C₃₋₁₀ cycloalkyl, unsubstituted C₃₋₁₀ cycloalkenyl, amino, unsubstituted (C₁₋₆ alkyl)amino and unsubstituted di(C₁₋₆ alkyl)amino;
more preferably wherein R₁₄, R₁₅, R₁₆, R₁₇ and R₁₈ are hydrogen and wherein each of R₁₂ and R₁₃ is independently selected from unsubstituted C₁₋₁₀ alkyl and C₁₋₁₀ alkyl substituted with a phenyl group; and/or
the unsubstituted or substituted pyrrolidinium cation is a pyrrolidinium cation of formula IV: 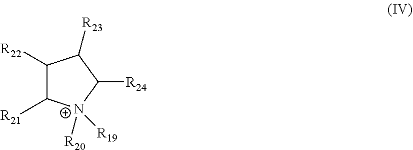
wherein each of R₁₉, R₂₀, R₂₁, R₂₂, R₂₃ and R₂₄ is independently selected from hydrogen, unsubstituted or substituted C₁₋₁₀ alkyl, unsubstituted or substituted C₂₋₁₀ alkenyl, unsubstituted or substituted C₂₋₁₀ alkynyl, unsubstituted or substituted C₆₋₁₂ aryl, unsubstituted or substituted C₃₋₁₀ cycloalkyl, unsubstituted or substituted C₃₋₁₀ cycloalkenyl, amino, unsubstituted or substituted (C₁₋₆ alkyl)amino and unsubstituted or substituted di(C₁₋₆ alkyl)amino;
preferably wherein each of R₁₉, R₂₀, R₂₁, R₂₂, R₂₃ and R₂₄ is independently selected from hydrogen, unsubstituted or substituted C₁₋₁₀ alkyl, unsubstituted C₂₋₁₀ alkenyl, unsubstituted C₂₋₁₀ alkynyl, unsubstituted C₆₋₁₂ aryl, unsubstituted C₃₋₁₀ cycloalkyl, unsubstituted C₃₋₁₀ cycloalkenyl, amino, unsubstituted (C₁₋₆ alkyl)amino and unsubstituted di(C₁₋₆ alkyl)amino;
more preferably wherein R₂₁, R₂₂, R₂₃ and R₂₄ are hydrogen and wherein each of R₁₉ and R₂₀ is independently selected from unsubstituted C₁₋₁₀ alkyl and C₁₋₁₀ alkyl substituted with a phenyl group.

19-20. (canceled)

21. An optoelectronic device according to claim 1 wherein the ionic liquid is present in an amount of less than 1.0 mol % with respect to the number of moles of the one or more metal or metalloid cations M in the crystalline A/M/X material, preferably wherein the ionic liquid is present in an amount of from 0.1 mol % to 0.9 mol % with respect to the number of moles of the one or more metal or metalloid cations M in the crystalline A/M/X material, more preferably from 0.2 mol % to 0.8 mol %, from 0.2 mol % to 0.7 mol % or less than 0.5 mol %, or for instance from 0.2 mol % to 0.5 mol %.

22-24. (canceled)

25. An optoelectronic device according to claim 1
wherein each A cation is selected from:
an alkali metal cation;
a cation of the formula [R₁R₂R₃R₄N]⁺, wherein each of R₁, R₂, R₃, R₄ is independently selected from hydrogen, unsubstituted or substituted C₁₋₂₀ alkyl, and unsubstituted or substituted C₆₋₁₂ aryl, and at least one of R₁, R₂, R₃ and R₄ is not hydrogen; and
a cation of the formula [R₅R₆N═CH—NR₇R₈]⁺, wherein each of R₅, R₆, R₇ and R₈ is independently selected from hydrogen, unsubstituted or substituted C₁₋₂₀ alkyl, and unsubstituted or substituted C₆₋₁₂ aryl; and C₁₋₁₀ alkylamammonium, C₂₋₁₀ alkenylammonium, C₁₋₁₀ alkyliminium, C₃₋₁₀ cycloalkylammonium and C₃₋₁₀ cycloalkyliminium, each of which is unsubstituted or substituted with one or more substituents selected from amino, C₁₋₆ alkylamino, imino, C₁₋₆ alkylimino, C₁₋₆ alkyl, C₂₋₆ alkenyl, C₃₋₆ cycloalkyl and C₆₋₁₂ aryl;
preferably wherein each A cation is selected from Cs⁺, Rb⁺, methylammonium, ethylammonium, propylammonium, butylammonium, pentylammoium, hexylammonium, septylammonium, octylammonium, formamidinium and guanidinium; or
wherein [A] comprises Cs⁺ and formamidinium.

26-27. (canceled)

28. An optoelectronic device according to claim 1, wherein each metal or metalloid M cation is selected from Ca²⁺, Sr²⁺, Cd²⁺, Cu²⁺, Ni²⁺, Mn²⁺, Fe²⁺, Co²⁺, Pd²⁺, Ge²⁺, Sn²⁺, Pb²⁺, Yb²⁺ and Eu²⁺, preferably Sn²⁺, Pb²⁺, Cu²⁺, Ge²⁺, and Ni²⁺; preferably Sn²⁺ and Pb²⁺; particularly preferably Pb²⁺.

29. (canceled)

30. An optoelectronic device according to claim 6 wherein the optoelectronic device further comprises:
a first electrode comprising a transparent conducting oxide, wherein the layer comprising the hole-transporting material is disposed between the layer comprising the crystalline A/M/X material and the first electrode;
a layer comprising an electron-transporting (n-type) material; and
a second electrode which comprises a metal in elemental form, wherein the layer comprising the electron-transporting material is disposed between the layer comprising the crystalline A/M/X material and the second electrode.

31. An optoelectronic device according to claim 1 which is a photovoltaic device, preferably wherein the photovoltaic device is a positive-intrinsic-negative (p-i-n) planar heterojunction photovoltaic device.

32. A process for producing an ionic liquid-modified film of a crystalline A/M/X material, wherein the crystalline A/M/X material comprises a compound of formula:
[A]ₐ[M]_{b}[X]_{c}
wherein:
[A] comprises one or more A cations;
[M] comprises one or more M cations which are metal or metalloid cations;
[X] comprises one or more X anions;
wherein
a is a number from 1 to 6;
b is a number from 1 to 6; and
c is a number from 1 to 18,
and where;
(A) the process comprises:
disposing a film-forming solution on a substrate, wherein the film-forming solution comprises a solvent, the one or more A cations, the one or more M cations, the one or more X anions, and an ionic liquid, wherein the ionic liquid comprises an organic cation and a counter-anion;
or
(B) the process comprises:
(a) disposing a first solution on a substrate wherein the first solution comprises a solvent and one ore more M cations, and optionally removing the solvent, to produce a treated substrate;
(b) contracting the treated substrate with a second solution comprising a solvent and one or more A cations or with vapour comprising one or more A cations,
wherein:
one or more X anions are present in one or both of: (i) the first solution employed in step (a), and (ii) the second solution or vapour employed in step (b); and
the first solution employed in step (a) further comprises an ionic liquid or step (b) further comprises contacting the treated substrate with an ionic liquid, wherein the ionic liquid comprises an organic cation and a counter-anion;
or
(C) the process comprises: treating a film of the crystalline A/M/X material with an ionic liquid which is a salt comprising an organic cation and a counter anion, optionally wherein the film of the crystalline A/M/X material is disposed on a substate.

33-45. (canceled)

46. A process according to claim 32 wherein the substrate comprises a first charge-transporting material which is optionally disposed on a first electrode, which first charge-transporting material is preferably a hole-transporting (p-type) material, and the first electrode is preferably a transparent electrode.

47. A process according to claim 46 which is for producing an optoelectronic device, wherein the substrate comprises said first charge-transporting material disposed on a first electrode, and the process further comprises:
disposing a second charge-transporting material on the ionic liquid-modified film of a crystalline A/M/X material, and
disposing a second electrode on the second charge-transporting material,
wherein the first charge transporting material is a hole-transporting (p-type) material and the second charge transporting material is a electron transporting (n-type) material, or the first charge transporting material is a hole-transporting (p-type) material,
preferably wherein the first electrode comprises a transparent conducting oxide and the second electrode comprises elemental metal.

48-49. (canceled)

50. An optoelectronic device which
is obtainable by a process as defined in claim 47.
